(19) United States
(12) Patent Application Publication
(10) Pub. No.: US 2025/0386508 A1
(43) Pub. Date: Dec. 18, 2025

(54) SEMICONDUCTOR DEVICE, FABRICATION METHOD THEREOF, AND MEMORY SYSTEM

(71) Applicant: Yangtze Memory Technologies Co., Ltd., Wuhan (CN)

(72) Inventors: Zongliang Huo, Wuhan (CN); Qianbing Xu, Wuhan (CN); Zhengliang Xia, Wuhan (CN); Sizhe Li, Wuhan (CN); Jing Gao, Wuhan (CN); Wenbin Zhou, Wuhan (CN)

(21) Appl. No.: 19/240,365

(22) Filed: Jun. 17, 2025

Related U.S. Application Data
(63) Continuation of application No. PCT/CN2025/083235, filed on Mar. 18, 2025.
(60) Provisional application No. 63/661,018, filed on Jun. 17, 2024.

(30) Foreign Application Priority Data
Sep. 20, 2024 (CN) 202411319696.4
Sep. 20, 2024 (CN) 202411320221.7
Sep. 20, 2024 (CN) 202411321182.2

(51) Int. Cl. H10B 43/27; H10B 43/35; H10B 43/40

(52) U.S. Cl. CPC H10B 43/27; H10B 43/35; H10B 43/40

(57) ABSTRACT

Examples of the present disclosure provide a memory device, a method of manufacturing thereof and a memory system. The memory device includes: a plurality of first deck structures stacked together, where the first deck structure includes first conductive layers and first dielectric layers arranged alternately along a first direction; a first conductive structure extending along the first direction and connected with one first conductive layer of each of at least two first deck structures of the plurality of first deck structures; a plurality of channel structures extending through the plurality of first deck structures; and at least one semiconductor layer, where one semiconductor layer is connected with the channel structure in at least one of the plurality of first deck structures.

### CROSS REFERENCE TO RELATED APPLICATIONS

This application is a continuation of International Application No. PCT/CN2025/083235, filed on Mar. 18, 2025, which claims the benefit of priorities of U.S. Provisional Application No. 63/661,018, filed on Jun. 17, 2024, Chinese Application No. 202411319696.4, filed on Sep. 20, 2024, Chinese Application No. 202411321182.2 filed on Sep. 20, 2024, and Chinese Application No. 202411320221.7, filed on Sep. 20, 2024, all of which are incorporated herein by reference in their entireties.

### TECHNICAL FIELD

Examples of the present disclosure relate to the field of semiconductor technology, and in particular, to a memory device, a method of manufacturing thereof, and a memory system.

### BACKGROUND

Memory devices, such as Not-And (NAND) flash memory, have become mainstream products in the storage market due to their high storage density, controllable production cost, suitable program and erase speed and data retention characteristics.

### SUMMARY

An example of the present disclosure provides a memory device, including: a plurality of first deck structures stacked together, where the first deck structure includes first conductive layers and first dielectric layers arranged alternately along a first direction; a first conductive structure extending along the first direction and connected with one first conductive layer of each of at least two first deck structures of the plurality of first deck structures; a plurality of channel structures extending through the plurality of first deck structures; and at least one semiconductor layer, where one semiconductor layer is connected with the channel structure in at least one of the plurality of first deck structures.

In some examples, a cross-sectional shape of the plurality of first deck structures along the first direction includes a step-like shape; each step in the step-like shape corresponds to the first conductive layer and the first dielectric layer adjacent to each other; and the first conductive structure extends along the first direction in the first deck structure and is connected with at least two steps where one first conductive layer of the at least two first deck structures is located.

In some examples, the memory device further includes a second deck structure including isolation layers and second dielectric layers arranged alternately along the first direction; the first conductive structure includes a first lead-out portion and a plurality of first connection portions; the first lead-out portion extends along the first direction in the second deck structure and is connected with each of the plurality of first connection portions; and each of the plurality of first connection portions is located in the isolation layer and is connected to one first conductive layer of a corresponding one of the at least two first deck structures.

In some examples, the first conductive structure is connected with one first conductive layer of each of the plurality of first deck structures.

In some examples, each of the first conductive layers connected with the same first conductive structure in different ones of the first deck structures has the same distance from the semiconductor layer connected with the channel structure in a corresponding one of the first deck structures.

In some examples, the first conductive layers connected with the same first conductive structure in two different ones of the first deck structures have different distances from the semiconductor layer connected with the channel structure in a corresponding one of the first deck structures.

In some examples, the memory device further includes a peripheral circuit including a string driver; and the first conductive layers of the at least two first deck structures are connected with each other through the first conductive structure and are connected with the same string driver.

In some examples, in the first direction, a region where the string driver is arranged is aligned with a region where the first conductive structure is arranged.

In some examples, the memory device has a first number of first deck structures, the first deck structure has a second number of first conductive layers, the memory device has a third number of string drivers, and the third number is less than or equal to a product of the first number and the second number.

In some examples, the plurality of first deck structures are arranged in a first region, the first conductive structures are all arranged in a second region, and the second region is located in the middle of the first region.

In some examples, the plurality of first deck structures are arranged in a first region, the first conductive structures are all arranged in a second region, and the second region is located on at least one of two sides of the first region perpendicular to the first direction.

In some examples, one semiconductor layer of the at least one semiconductor layer is located between two adjacent first deck structures and is connected with the channel structure of each of the two adjacent first deck structures.

In some examples, there are at least one second conductive layer and a plurality of second conductive structures; one second conductive layer is connected with the channel structure of at least one of the plurality of first deck structures, and includes a plurality of bit lines spaced apart along the second direction and extending along the third direction; both the second direction and the third direction are perpendicular to the first direction; and the second conductive structures extend along the first direction in the first deck structure and are connected with one bit line of the at least one second conductive layer.

In some examples, the plurality of first deck structures are arranged in a first region, the plurality of second conductive structures are all arranged in a third region, and the third region is located on at least one of two sides of the first region along the third direction.

In some examples, the memory device further includes a plurality of third conductive structures; the first conductive layers in the first deck structure include a top select gate layer and a gate layer; the top select gate layer is located at one end of two ends of a corresponding first deck structure along the first direction away from the semiconductor layer connected with the channel structure in the corresponding first deck structure; the third conductive structure extends along the first direction in the first deck structure and is connected with the top select gate layer included in at least one of the plurality of first deck structures; and the first conductive structure is connected with one gate layer of each of at least two first deck structures of the plurality of first deck structures.

In some examples, the plurality of first deck structures are arranged in a first region, the first conductive structures are all arranged in a second region, the third conductive structures are all arranged in a fourth region, and the fourth region is located between the first region and the second region.

In some examples, the third conductive structure includes a second lead-out portion, a second connection portion and a contact portion; the second lead-out portion extends along the first direction and is connected with the second connection portion; the second connection portion extends along the second direction and is connected with the contact portion; the contact portion extends along the first direction and is connected with the top select gate layer; and the second direction is perpendicular to the first direction.

In some examples, the plurality of first deck structures stacked together constitute a memory plane; the memory device includes at least two memory planes; two memory planes of the at least two memory planes are arranged in parallel along a second direction; the second direction is perpendicular to the first direction; and the first conductive structure is located between the two memory planes and is connected with one first conductive layer of each of different ones of the first deck structures in at least one memory plane.

In some examples, the memory device further includes a peripheral circuit; the peripheral circuit includes a plurality of string drivers; and the first conductive layers of different memory planes at the same position along the first direction are connected with each other and connected with the same one of the string drivers.

An example of the present disclosure further provides a memory system, including: the memory device provided in the example of the present disclosure.

An example of the present disclosure further provides a method of manufacturing a memory device, including: forming a plurality of first deck structures stacked together, where the first deck structure includes first conductive layers and first dielectric layers arranged alternately along a first direction; forming a first conductive structure, where the first conductive structure extends along the first direction and is connected with one first conductive layer of each of at least two first deck structures of the plurality of first deck structures; forming a plurality of channel structures extending through the plurality of first deck structures; and forming at least one semiconductor layer, where one semiconductor layer is connected with the channel structure in at least one of the plurality of first deck structures.

In some examples, forming the plurality of first deck structures stacked together includes: providing a semiconductor structure, where the semiconductor structure includes a plurality of semiconductor units each including at least a deck layer, and the deck layer includes isolation material layers and dielectric layers arranged alternately along the first direction; dividing the semiconductor structure along at least one of the second direction or the third direction to form a plurality of semiconductor units separated from each other, where the second direction and the third direction intersect with each other and are both perpendicular to the first direction; stacking the plurality of semiconductor units along the first direction to form the plurality of semiconductor units stacked together; and replacing the isolation material layers in the plurality of semiconductor units stacked together with the first conductive layers to form a plurality of first deck structures stacked together.

In some examples, the semiconductor unit further includes a semiconductor layer located on a first side and a second conductive layer located on a second side; the first side and the second side are located on two opposite sides of the deck layer respectively along the first direction; the second conductive layer includes a plurality of bit lines spaced apart along the second direction and extending along the third direction; and stacking the plurality of semiconductor units along the first direction includes: stacking every two semiconductor units of the plurality of semiconductor units to form a plurality of semiconductor unit groups, where the two semiconductor units in each semiconductor unit group are stacked in a direction toward respective first sides; and stacking the plurality of semiconductor unit groups along the first direction.

In some examples, the method further includes: before stacking every two semiconductor units of the plurality of semiconductor units, removing the semiconductor layer corresponding to one of the two semiconductor units, where a remaining semiconductor layer forms the semiconductor layer connected with both of the two semiconductor units.

In some examples, the method further includes: forming a semiconductor layer and a second conductive layer on two opposite sides of each semiconductor unit respectively along the first direction, where the second conductive layer includes a plurality of bit lines spaced apart along a second direction and extending along a third direction, and stacking the plurality of semiconductor units along the first direction includes: stacking the plurality of semiconductor units formed with the semiconductor layer and the second conductive layer along the first direction.

In some examples, the semiconductor unit further includes a semiconductor layer located on a first side and a second conductive layer located on a second side; the first side and the second side are located on two opposite sides of the deck layer respectively along the first direction; the second conductive layer includes a plurality of bit lines spaced apart along the second direction and extending along the third direction; and stacking the plurality of semiconductor units along the first direction includes: stacking two semiconductor units adjacent to each other along the first direction in the plurality of semiconductor units in a direction toward different sides of respective semiconductor units.

In some examples, stacking the plurality of semiconductor units along the first direction includes: stacking the plurality of semiconductor units along the first direction by using a bonding process.

In some examples, the method further includes: when the isolation material layers in the plurality of semiconductor units stacked together are replaced with the first conductive layers, replacing each isolation material layer in a portion of the plurality of semiconductor units with the first conductive layer, where a portion of a deck structure where the isolation material layers are replaced forms a first deck structure; a portion of a deck structure where the isolation material layers are not replaced forms a second deck structure; a dielectric layer corresponding to the first deck structure is a first dielectric layer; a dielectric layer corresponding to the second deck structure is a second dielectric layer; and forming the first conductive structure includes: forming the first conductive structure in the second deck structure.

In some examples, the method further includes: forming a plurality of second conductive structures extending along the first direction in the first deck structure and connected with one bit line of at least one second conductive layer.

In some examples, the first conductive layers in the first deck structure include a top select gate layer and a gate layer; the method further includes: forming a third conductive structure extending along the first direction in the first deck structure and connected with one top select gate layer of at least one of the plurality of first deck structures; the first conductive structure is connected with one gate layer of each of at least two first deck structures of the plurality of first deck structures.

In some examples, forming the plurality of first deck structures stacked together includes: forming a plurality of first deck structures stacked together in sequence; the first deck structure includes first conductive layers and dielectric layers that are arranged alternately; the method further includes: forming the semiconductor layer and a second conductive layer alternately between two sides of the plurality of first deck structures along the first direction and between every two adjacent ones of the first deck structures.

An example of the present disclosure provides a memory device, a manufacturing method thereof and a memory system, where the memory device includes: a plurality of first deck structures stacked together, where the first deck structure includes first conductive layers and first dielectric layers arranged alternately along a first direction; a first conductive structure extending along the first direction and connected with one first conductive layer of each of at least two first deck structures of the plurality of first deck structures; a plurality of channel structures extending through the plurality of first deck structures; and at least one semiconductor layer, where one semiconductor layer is connected with the channel structure in at least one of the plurality of first deck structures. In the example of the present disclosure, the first conductive structure which serves as a lead-out structure of the first conductive layer is connected with one first conductive layer of each of at least two first deck structures in the plurality of first deck structures, e.g., the first conductive structure is connected with the plurality of first conductive layers corresponding to the plurality of first deck structures, so that the plurality of first conductive layers may share the first conductive structure. On one hand, the total number of the first conductive structures and the driving circuits thereof may be reduced, and the size of the memory device may be reduced; on the other hand, the sharing of the first conductive structures extending along the first direction provides a good technical support for the stacking of the plurality of first deck structures along the first direction, thereby providing a technical basis for storage density improvement due to the multi-deck stacking.

An example of the present disclosure further provides a memory device, including: a plurality of first deck structures stacked together, where the first deck structure includes first conductive layers and first dielectric layers arranged alternately along a first direction; a plurality of channel structures extending through the plurality of first deck structures; at least one semiconductor layer, where the semiconductor layer is connected with the channel structure in at least one of the plurality of first deck structures; and at least one second conductive layer, where one second conductive layer is located between two adjacent first deck structures and is connected with the channel structure in at least one of the plurality of first deck structures, where one semiconductor layer and one second conductive layer that are connected with the channel structure in the same first deck structure are arranged on two sides of the first deck structure respectively along the first direction.

In some examples, the second conductive layer includes a plurality of bit lines spaced apart along the second direction and extending along the third direction; the second direction and the third direction intersect with each other and are both perpendicular to the first direction; and a plurality of second conductive structures extending along the first direction in the first deck structure and connected with one bit line of the at least one second conductive layer.

In some examples, different bit lines connected with different first deck structures through which the same channel structure extends are all connected with the same second conductive structure.

In some examples, at least one of the plurality of second conductive layers is located between two adjacent first deck structures and is connected with the channel structure of each of the two adjacent first deck structures.

In some examples, the memory device further includes a peripheral circuit; the peripheral circuit includes a page buffer; and the plurality of second conductive structures are connected with the same page buffer.

In some examples, different bit lines connected with different first deck structures through which the same channel structure extends are connected with different second conductive structures.

In some examples, the second conductive layers corresponding to different first deck structures have different sizes along the third direction; and different second conductive structures connected with the second conductive layers corresponding to different first deck structures are arranged in sequence along the third direction.

In some examples, the memory device further includes a peripheral circuit; the peripheral circuit includes a plurality of page buffers; the second conductive structures connected with the bit lines of the same second conductive layer are connected with the same page buffer of the plurality of page buffers; and the second conductive structures connected with the bit lines of different second conductive layers are connected with different page buffers of the plurality of page buffers.

In some examples, the plurality of first deck structures stacked together constitute one memory module; the memory device includes at least two memory modules; two memory modules of the at least two memory modules are stacked together along the first direction; the memory device further includes a fourth conductive structure; different bit lines corresponding to different first deck structures through which the same channel structure extends are all connected with different second conductive structures; and the plurality of second conductive structures corresponding to the first deck structures specified in different memory modules through which the same channel structure extends are connected with each other through the fourth conductive structure.

In some examples, the plurality of first deck structures are all arranged in a first region, the plurality of second conductive structures are all arranged in a third region, and the third region is located on at least one of two sides of the first region along the third direction.

In some examples, at least one of the plurality of semiconductor layers is located between two adjacent first deck structures and is connected with the channel structure of each of the two adjacent first deck structures.

In some examples, the two adjacent first deck structures of the plurality of first deck structures form a deck group; the memory device includes a plurality of semiconductor layers; the plurality of semiconductor layers are located between the two adjacent first deck structures of the deck group, respectively; and the plurality of semiconductor layers are connected with each other.

In some examples, the memory device further includes a plurality of first conductive structures extending along the first direction and connected with one first conductive layer of each of at least two first deck structures of the plurality of first deck structures.

In some examples, the memory device further includes a plurality of third conductive structures; the first conductive layers in the first deck structure include a top select gate layer and a gate layer; the top select gate layer is located at one end of two ends of a corresponding first deck structure along the first direction away from the semiconductor layer connected with the channel structure in the corresponding first deck structure; the third conductive structure extends along the first direction in the first deck structure and is connected with the top select gate layer included in at least one of the plurality of first deck structures; and the first conductive structure is connected with one gate layer of each of at least two first deck structures of the plurality of first deck structures.

An example of the present disclosure further provides a memory device, including: a plurality of first deck structures stacked together, where the first deck structure includes first conductive layers and first dielectric layers arranged alternately along a first direction; the first conductive layers in the first deck structure include a top select gate layer and a gate layer; the top select gate layer is located at one end of two ends of a corresponding first deck structure along the first direction away from a semiconductor layer connected with a channel structure in the corresponding first deck structure; a plurality of channel structures extending through the plurality of first deck structures; at least one semiconductor layer, where one semiconductor layer is connected with the channel structure in at least one of the plurality of first deck structures; and a plurality of third conductive structures extending along the first direction in the first deck structure and connected with the top select gate layer included in at least one of the plurality of first deck structures.

In some examples, the memory device further includes a top select gate isolation structure, where the top select gate isolation structure divides the top select gate layer into a plurality of top select gate sub-layers; and different top select gate sub-layers included in the same top select gate layer are connected with different third conductive structures.

In some examples, different top select gate layers included in different first deck structures are connected with different third conductive structures.

In some examples, the memory device further includes a plurality of second conductive layers and a plurality of second conductive structures; one second conductive layer is connected with the channel structure of at least one of the plurality of first deck structures; one second conductive layer includes a plurality of bit lines, and each bit line is connected with all channel structures of a column of the channel structures; and the second conductive structures extend along the first direction in the first deck structure and are connected with one bit line of the at least one second conductive layer.

In some examples, different bit lines corresponding to different first deck structures through which the same channel structure extends are all connected with different second conductive structures; and different top select gate layers included in different first deck structures are connected with the same third conductive structure.

In some examples, the plurality of first deck structures stacked together constitute one memory plane; the memory device includes at least two memory planes; two memory planes of the at least two memory modules are arranged in parallel along a second direction; the second direction is perpendicular to the first direction; the memory device further includes a plurality of first conductive structures; the plurality of first conductive structures are located between the two memory planes, and the first conductive structures are connected with one gate layer of each of different first deck structures in at least one memory plane.

In some examples, the memory device further includes a peripheral circuit; the peripheral circuit includes a plurality of string drivers; and the first conductive layers of different memory planes at the same position in a stacking direction of the first deck structures are connected with each other and connected with the same one of the string drivers.

In some examples, different bit lines corresponding to different first deck structures through which the same channel structure extends are all connected with different second conductive structures; different top select gate layers included in different first deck structures of the same memory plane are connected with the same third conductive structure; and different top select gate layers included in the first deck structures of different memory planes at the same position in the first direction are connected with different third conductive structures.

In some examples, the plurality of first deck structures stacked together form one memory module; the memory device includes at least two memory modules; the at least two first memory modules are stacked together along the first direction; the memory device further includes a plurality of first conductive structures; and the plurality of first conductive structures are connected with one gate layer of each deck structure of the two memory modules.

In some examples, the memory device further includes a fourth conductive structure; different bit lines corresponding to different first deck structures through which the same channel structure extends in the same memory module are all connected with different second conductive structures; two bit lines corresponding to two first deck structures specified in different memory modules are connected with each other through the fourth conductive structure; different top select gate layers included in different first deck structures in the same memory module are connected with the same third conductive structure; and two top select gate layers included in two first deck structures in different memory modules are connected with different third conductive structures.

In some examples, different bit lines corresponding to different first deck structures through which the same channel structure extends in the same memory module are all connected with the same second conductive structure; different bit lines corresponding to two first deck structures in different memory modules are all connected with different second conductive structures; different top select gate layers included in different first deck structures in the same memory module are connected with different third conductive structures; and two top select gate layers included in two first deck structures in different memory modules are connected with the same third conductive structure.

In some examples, the plurality of first deck structures are arranged in a first region, the plurality of first conductive structures are all arranged in a second region, the plurality of third conductive structures are all arranged in a fourth region, and the fourth region is located between the first region and the second region.

In some examples, the third conductive structure includes a second lead-out portion, a second connection portion and a contact portion; the second lead-out portion extends along the first direction and is connected with the second connection portion; the second connection portion extends along a direction perpendicular to the first direction and is connected with the contact portion; and the contact portion extends along the first direction and is connected with the top select gate layer.

In some examples, each first deck structure includes a plurality of top select gate layers; a cross-sectional shape of the plurality of top select gate layers along the first direction includes a step-like shape; each step in the step-like shape corresponds to one top select gate layer; and one contact portion is connected to a step where one top select gate layer is located.

In some examples, one semiconductor layer of the at least one semiconductor layer is located between two adjacent first deck structures and is connected with the channel structure in each of the two adjacent first deck structures.

In some examples, the memory device further includes a plurality of first conductive structures; the first conductive structures extend along the first direction and are connected with one gate layer of each of at least two first deck structures of the plurality of first deck structures.

An example of the present disclosure further provides a memory device, including: a plurality of first deck structures stacked together, where the first deck structure includes first conductive layers and first dielectric layers arranged alternately along a first direction; a plurality of channel structures extending through the plurality of first deck structures; at least one semiconductor layer, where the semiconductor layer is connected with the channel structure in at least one of the plurality of first deck structures; and at least one second conductive layer, where one second conductive layer is located between two adjacent first deck structures and is connected with the channel structure in at least one of the plurality of first deck structures, and one semiconductor layer and one second conductive layer that are connected with the channel structure in the same first deck structure are arranged on two sides of the first deck structure respectively along the first direction. In the example of the present disclosure, the memory device includes a plurality of first deck structures stacked together, one semiconductor layer (for example, a source layer) and one second conductive layer (for example, a bit-line layer) that are connected with the channel structures in the same first deck structure are arranged on two sides of the first deck structure respectively along the first direction, and one second conductive layer is located between two adjacent first deck structures, e.g., the second conductive layer is arranged between two adjacent first deck structures. The position of the second conductive structure is arranged to facilitate connection of the channel structures in two first deck structures adjacent to the second conductive structure, which may achieve sharing of the bit-line layers, provide a good technical support for the multi-deck stacking, and provide a technical basis for storage density improvement due to the multi-deck stacking.

An example of the present disclosure provides a memory device, including: a plurality of first deck structures stacked together, where the first deck structure includes first conductive layers and first dielectric layers arranged alternately along a first direction; a plurality of first conductive structures, where each of the first conductive structures is connected with one first conductive layer of each of at least two first deck structures of the plurality of first deck structures; a plurality of channel structures, where each of the channel structures extends through the plurality of first deck structures; at least one semiconductor layer and at least one second conductive layer, where one semiconductor layer and one second conductive layer are located on two sides of one first deck structure respectively along the first direction and are both connected with the channel structure in one first deck structure, each second conductive layer includes a plurality of bit lines spaced apart along a second direction and extending along a third direction, and the second direction and the third direction intersect with each other and are both perpendicular to the first direction; and a plurality of second conductive structures, where each of the second conductive structures is connected with one bit line of the at least one second conductive layer.

In some examples, different bit lines corresponding to different first deck structures through which the same channel structure extends are all connected with the same second conductive structure.

In some examples, at least one second conductive layer is located between two adjacent first deck structures and is connected with the channel structure in each of the two adjacent first deck structures.

In some examples, the memory device further includes a peripheral circuit; the peripheral circuit includes a page buffer; and the plurality of second conductive structures are connected with the same page buffer.

In some examples, different bit lines corresponding to different first deck structures through which the same channel structure extends are all connected with different second conductive structures.

In some examples, the second conductive layers corresponding to different first deck structures have different sizes along the third direction; and different second bit lines connected with the second conductive layers corresponding to different first deck structures are arranged in sequence along the third direction.

In some examples, the memory device further includes a peripheral circuit; the peripheral circuit includes a plurality of page buffers; the second conductive structures connected with the bit lines of the same second conductive layer are connected with the same page buffer of the plurality of page buffers; and the second conductive structures connected with the bit lines of different second conductive layers are connected with different page buffers of the plurality of page buffers.

In some examples, at least one semiconductor layer is located between two adjacent first deck structures and is connected with the channel structure in each of the two adjacent first deck structures.

In some examples, the two adjacent first deck structures of the plurality of first deck structures form a deck group; the memory device includes a plurality of semiconductor layers; the plurality of semiconductor layers are located between the two adjacent first deck structures of the deck group, respectively; and the plurality of semiconductor layers are connected with each other.

In some examples, a cross-sectional shape of the plurality of first deck structures along the first direction includes a step-like shape; each step in the step-like shape corresponds to the first conductive layer and the first dielectric layer adjacent to each other; and the first conductive structure extends along the first direction in the first deck structure and is connected to at least two steps where one first conductive layer of the at least two first deck structures is located.

In some examples, the memory device further includes a second deck structure including isolation layers and second dielectric layers that are arranged alternately; the first conductive structure includes a first lead-out portion and a plurality of first connection portions; the first lead-out portion extends along the first direction in the second deck structure and is connected with each of the plurality of first connection portions; and each of the plurality of first connection portions is located in the isolation layer and is connected to one first conductive layer of a corresponding one of the at least two first deck structures.

In some examples, the first conductive structure is connected with one first conductive layer in each of the first deck structures that has the same distance from the semiconductor layers connected with the channel structure of a corresponding one of the first deck structures.

In some examples, the first conductive structure is connected with one first conductive layer in each of the first deck structures that has different distances from the semiconductor layers connected with the channel structure of a corresponding one of the first deck structures.

In some examples, the memory device further includes a peripheral circuit; the peripheral circuit includes a plurality of string drivers; and the first conductive layers of the at least two first deck structures are connected with each other through the first conductive structure and are connected with the same one of the string drivers.

In some examples, the memory device further includes a plurality of third conductive structures; the first conductive layer in the first deck structure include a top select gate layer and a gate layer; the top select gate layer is located at one end of two ends of a corresponding first deck structure along the first direction away from the semiconductor layer connected with the channel structure in the corresponding first deck structure; the third conductive structure extends along the first direction in the first deck structure and is connected with the top select gate layer included in at least one of the plurality of first deck structures; the first conductive structure is connected with one gate layer of each of at least two first deck structures of the plurality of first deck structures.

In some examples, the memory device further includes a top select gate isolation structure, where the top select gate isolation structure divides the top select gate layer into a plurality of top select gate sub-layers; and different top select gate sub-layers included in the same top select gate layer are connected with different third conductive structures.

In some examples, different top select gate layers included in different first deck structures are connected with different third conductive structures; and different bit lines corresponding to different first deck structures through which the same channel structure extends are all connected with the same second conductive structure.

In some examples, different bit lines corresponding to different first deck structures through which the same channel structure extends are all connected with different second conductive structures; different top select gate layers included in different first deck structures are connected with the same third conductive structure.

In some examples, the plurality of first deck structures stacked together constitute one memory plane; the memory device includes a first memory plane and a second memory plane; the first memory plane and the second memory plane are arranged in parallel along a second direction; the memory device further includes a plurality of string drivers; the plurality of first conductive structures are located between the first memory plane and the second memory plane, and the first conductive structure is connected with one gate layer of each of different first deck structures in at least one memory plane; and the first conductive layers of the first memory plane and the second memory plane at the same position in the first direction are connected with each other and connected with the same one of the string drivers.

In some examples, different bit lines corresponding to different first deck structures through which the same channel structure extends are all connected with different second conductive structures; different top select gate layers included in different first deck structures of the same memory plane are connected with the same third conductive structure; and different top select gate layers included in the first deck structures of different memory planes at the same position in the first direction are connected with different third conductive structures.

In some examples, the plurality of first deck structures stacked together constitute one memory module; the memory device includes a first memory module and a second memory block; the first memory module and the second memory block are stacked together along the first direction; and the plurality of first conductive structures are connected with one gate layer of each of first deck structures in the first memory module and the second memory block.

In some examples, different bit lines corresponding to different first deck structures through which the same channel structure extends in the same memory module are all connected with different second conductive structures; two bit lines corresponding to two first deck structures specified in different memory modules are connected with each other; different top select gate layers included in different first deck structures in the same memory module are connected with the same third conductive structure; and two top select gate layers included in two first deck structures in different memory modules are connected with different third conductive structures.

In some examples, different bit lines corresponding to different first deck structures through which the same channel structure extends in the same memory module are all connected with the same second conductive structure; different bit lines corresponding to two first deck structures in different memory modules are all connected with different second conductive structures; different top select gate layers included in different first deck structures in the same memory module are connected with different third conductive structures; and two top select gate layers included in two first deck structures in different memory modules are connected with the same third conductive structure.

In some examples, the plurality of first deck structures are arranged in a first region, the plurality of first conductive structures are all arranged in a second region, the plurality of second conductive structures are all arranged in a third region, and the plurality of third conductive structures are all arranged in a fourth region; the second region is located in the middle of the first region, or the second region is located on at least one of two sides of the first region along a direction perpendicular to the stacking direction; the third region is located on at least one of two sides of the first region along the third direction; and the fourth region is located between the first region and the second region.

An example of the present disclosure further provides a method of controlling a memory device, the memory device includes the memory device provided by the example of the present disclosure, the channel structure is divided into a plurality of sub-channel structures by the semiconductor layer and a second conductive layer; the first conductive layers in the first deck structure include a top select gate layer and a gate layer; the top select gate layer is located at one end of two ends of a corresponding first deck structure along the first direction away from a semiconductor layer connected with a channel structure in the corresponding first deck structure; and the method of controlling the memory device includes:

In a process of performing a read operation, applying a first voltage to at least one of a top select gate of an unselected sub-channel structure of the plurality of sub-channel structures or a bit line coupled to the top select gate of the unselected sub-channel structure of the plurality of sub-channel structures, applying a second voltage to a top select gate of a selected sub-channel structure of the plurality of sub-channel structures and a bit line coupled to the top select gate of the selected sub-channel structure of the plurality of sub-channel structures, applying a pass voltage to all unselected gate layers, and applying a read voltage to the selected gate layer.

In some examples, the first voltage includes a turn-off voltage, the second voltage includes a first turn-on voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the turn-off voltage to the top select gate of the unselected sub-channel structure, and applying the first turn-on voltage to the top select gate of the selected sub-channel structure.

In some examples, the first voltage includes a program inhibit voltage, the second voltage includes a program enable voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the program inhibit voltage to the bit line coupled to the unselected sub-channel structure, applying the program enable voltage to the bit line coupled to the selected sub-channel structure, and applying a first turn-on voltage to all the top select gate layers.

In some examples, the first conductive layers in the first deck structure further include a bottom select gate layer located at one end of two ends of a corresponding first deck structure along the first direction close to the semiconductor layer connected with the channel structure in the corresponding first deck structure; and the method further includes: in the process of performing the read operation, applying a second turn-on voltage to all the bottom select gate layers.

An example of the present disclosure further provides a method of controlling a memory device, the memory device includes the memory device provided by an example of the present disclosure, the channel structure is divided into a plurality of sub-channel structures by the plurality of first deck structures; the first conductive layers in the first deck structure include a top select gate layer and a gate layer; the top select gate layer is located at one end of two ends of a corresponding first deck structure along the first direction away from the semiconductor layer connected with the channel structure in the corresponding first deck structure; and the method of controlling the memory device includes:

In a process of performing a program operation, applying a first voltage to at least one of a top select gate of an unselected sub-channel structure of the plurality of sub-channel structures or a bit line coupled to the top select gate of the unselected sub-channel structure of the plurality of sub-channel structures, applying a second voltage to a top select gate of a selected sub-channel structure of the plurality of sub-channel structures and a bit line coupled to the top select gate of the selected sub-channel structure of the plurality of sub-channel structures, applying a pass voltage to all unselected gate layers, and applying a program voltage to the selected gate layer.

In some examples, the first voltage includes a turn-off voltage, the second voltage includes a turn-on voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the turn-off voltage to the top select gate of the unselected sub-channel structure, and applying the turn-on voltage to the top select gate of the selected sub-channel structure.

In some examples, the first voltage includes a program inhibit voltage, the second voltage includes a program enable voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the program inhibit voltage to the bit line coupled to the unselected sub-channel structure, applying the program enable voltage to the bit line coupled to the selected sub-channel structure, and applying a turn-on voltage to all the top select gate layers.

In some examples, the first conductive layers in the first deck structure further include a bottom select gate layer located at one end of two ends of a corresponding first deck structure along the first direction close to the semiconductor layer connected with the channel structure in the corresponding first deck structure; and the method further includes: in the process of performing the program operation, applying a turn-off voltage to all the bottom select gate layers.

The example of the present disclosure provides a memory device and a method of controlling thereof, and the memory device includes: a plurality of first deck structures stacked together, where the first deck structure includes first conductive layers and first dielectric layers arranged alternately along a first direction; a plurality of first conductive structures, where each of the first conductive structures is connected with one first conductive layer of each of at least two first deck structures of the plurality of first deck structures; a plurality of channel structures, where each of the channel structures extends through the plurality of first deck structures; at least one semiconductor layer and at least one second conductive layer, where one semiconductor layer and one second conductive layer are located on two sides of one first deck structure respectively along the first direction and are both connected with the channel structure in one first deck structure, and each second conductive layer includes a plurality of bit lines spaced apart along a second direction and extending along a third direction; and a plurality of second conductive structures, where each of the second conductive structures is connected with one bit line of the at least one second conductive layer.

In the example of the present disclosure, the memory device includes a plurality of first deck structures, and two sides of each deck structure along the first direction are arranged with a second conductive layer and a semiconductor layer respectively. As such, the problem of reduced channel saturation current due to too many gate layers can be improved. Meanwhile, the first conductive structure which serves as a lead-out structure of the first conductive layer is connected with one first conductive layer of each of at least two first deck structures in the plurality of first deck structures, e.g., the first conductive structure is connected with the plurality of first conductive layers corresponding to the plurality of first deck structures, so that the plurality of first conductive layers may share the first conductive structure. On one hand, the total number of the first conductive structures and the driving circuits thereof may be reduced, and the size of the memory device may be reduced; on the other hand, the sharing of the first conductive structures extending along the first direction provides a good technical support for the stacking of the plurality of first deck structures along the first direction, thereby providing a technical basis for storage density improvement due to the multi-deck stacking.

### BRIEF DESCRIPTION OF THE DRAWINGS

FIG. 1 is a schematic diagram of a layout of a peripheral circuit including a string driver SD provided by an example of the present disclosure;

FIG. 2A is a first schematic three-dimensional diagram including a memory device architecture provided by an example of the present disclosure;

FIG. 2B is a second schematic three-dimensional diagram including a memory device architecture provided by an example of the present disclosure;

FIG. 2C is a third schematic three-dimensional diagram including a memory device architecture provided by an example of the present disclosure;

FIG. 2D is a fourth schematic three-dimensional diagram including a memory device architecture provided by an example of the present disclosure;

FIG. 2E is a fifth schematic three-dimensional diagram including a memory device architecture provided by an example of the present disclosure;

FIG. 3A is a first schematic diagram including a forming process of a memory device architecture provided by an example of the present disclosure;

FIG. 3B is a second schematic diagram including a forming process of a memory device architecture provided by an example of the present disclosure;

FIG. 3C is a third schematic diagram including a forming process of a memory device architecture provided by an example of the present disclosure;

FIG. 4A is a first schematic three-dimensional diagram including a first deck structure and a first conductive structure of a memory device provided by an example of the present disclosure;

FIG. 4B is a second schematic three-dimensional diagram including a first deck structure and a first conductive structure of a memory device provided by an example of the present disclosure;

FIG. 4C is a third schematic three-dimensional diagram including a first deck structure and a first conductive structure of a memory device provided by an example of the present disclosure;

FIG. 5A is a fourth schematic three-dimensional diagram including a first deck structure and a first conductive structure of a memory device provided by an example of the present disclosure;

FIG. 5B is a fifth schematic three-dimensional diagram including a first deck structure and a first conductive structure of a memory device provided by an example of the present disclosure;

FIG. 5C is a sixth schematic three-dimensional diagram including a first deck structure and a first conductive structure of a memory device provided by an example of the present disclosure;

FIG. 5D is a seventh schematic three-dimensional diagram including a first deck structure and a first conductive structure of a memory device provided by an example of the present disclosure;

FIG. 6A is a first schematic cross-sectional diagram including an example of a first conductive structure of a memory device provided by an example of the present disclosure;

FIG. 6B is a second schematic cross-sectional diagram including an example of a first conductive structure of a memory device provided by an example of the present disclosure;

FIG. 6C is a third schematic cross-sectional diagram including an example of a first conductive structure of a memory device provided by an example of the present disclosure;

FIG. 7A is a first schematic top view of a layout including an array region and a connection region provided by an example of the present disclosure;

FIG. 7B is a schematic cross-sectional diagram taken at X1-X1′ in FIG. 7A;

FIG. 8A is a second schematic top view of a layout including an array region and a connection region provided by an example of the present disclosure;

FIG. 8B is a schematic cross-sectional diagram taken at X2-X2′ in FIG. 8A;

FIG. 9A is a third schematic top view of a layout including an array region and a connection region provided by an example of the present disclosure;

FIG. 9B is a schematic cross-sectional diagram taken at Y1-Y1′ in FIG. 9A;

FIG. 10A is a first schematic three-dimensional diagram of a layout including an array of a memory device and a peripheral circuit provided by an example of the present disclosure;

FIG. 10B is a first schematic top view including a lead-out structure of BL and TSG of deck1 of a memory device provided by an example of the present disclosure;

FIG. 10C is a first schematic top view including a lead-out structure of BL and TSG of deck2 of a memory device provided by an example of the present disclosure;

FIG. 10D is a first schematic cross-sectional view including a lead-out structure of a BL of a memory device provided by an example of the present disclosure;

FIG. 10E is a first schematic cross-sectional view including a lead-out structure of a TSG of a memory device provided by an example of the present disclosure;

FIG. 11A is a second schematic three-dimensional diagram of a layout including an array of a memory device and a peripheral circuit provided by an example of the present disclosure;

FIG. 11B is a second schematic top view including lead-out structures of BLs of decks of a memory device provided by an example of the present disclosure;

FIG. 11C is a second schematic top view including lead-out structures of BLs of decks of a memory device provided by an example of the present disclosure;

FIG. 11D is a second schematic cross-sectional view including lead-out structures of TSGs of decks of a memory device provided by an example of the present disclosure;

FIG. 11E is a second schematic cross-sectional view including lead-out structures of TSGs of decks of a memory device provided by an example of the present disclosure;

FIG. 12A is a third schematic three-dimensional diagram of a layout including an array of a memory device and a peripheral circuit provided by an example of the present disclosure;

FIG. 12B is a third schematic top view including lead-out structures of BLs of decks of a memory device provided by an example of the present disclosure;

FIG. 12C is a third schematic top view including lead-out structures of BLs of decks of a memory device provided by an example of the present disclosure;

FIG. 12D is a third schematic cross-sectional view including lead-out structures of TSGs of decks of a memory device provided by an example of the present disclosure;

FIG. 12E is a third schematic cross-sectional view including lead-out structures of TSGs of decks of a memory device provided by an example of the present disclosure;

FIG. 13A is a fourth schematic three-dimensional diagram of a layout including an array of a memory device and a peripheral circuit provided by an example of the present disclosure;

FIG. 13B is a fourth schematic top view including lead-out structures of BLs of decks of a memory device provided by an example of the present disclosure;

FIG. 13C is a fourth schematic top view including lead-out structures of BLs of decks of a memory device provided by an example of the present disclosure;

FIG. 13D is a fourth schematic top view including a lead-out structure of BL and TSG of Model1 of a memory device provided by an example of the present disclosure;

FIG. 13E is a fifth schematic top view including a lead-out structure of BL and TSG of Model2 of a memory device provided by an example of the present disclosure;

FIG. 13F is a fourth schematic cross-sectional view including a lead-out structures of TSGs of decks of a memory device provided by an example of the present disclosure;

FIG. 14A is a first schematic diagram of a layout including functional layers coupled to a channel structure of a memory device provided by an example of the present disclosure;

FIG. 14B is a first schematic diagram of applying a voltage to functional layers in a selected sub-channel structure in a process of a read operation provided by an example of the present disclosure;

FIG. 14C is a first schematic diagram of applying a voltage to functional layers in an unselected sub-channel structure in a process of a read operation provided by an example of the present disclosure;

FIG. 14D is a first schematic diagram of applying a voltage to functional layers in a selected sub-channel structure in a process of a program operation provided by an example of the present disclosure;

FIG. 14E is a first schematic diagram of applying a voltage to functional layers in an unselected sub-channel structure in a process of a read operation provided by an example of the present disclosure;

FIG. 15A is a second schematic diagram of a layout including functional layers coupled to a channel structure of a memory device provided by an example of the present disclosure;

FIG. 15B is a second schematic diagram of applying a voltage to functional layers in a selected sub-channel structure in a process of a read operation provided by an example of the present disclosure;

FIG. 15C is a second schematic diagram of applying a voltage to functional layers in an unselected sub-channel structure in a process of a read operation provided by an example of the present disclosure;

FIG. 15D is a second schematic diagram of applying a voltage to functional layers in a selected sub-channel structure in a process of a program operation provided by an example of the present disclosure;

FIG. 15E is a second schematic diagram of applying a voltage to functional layers in an unselected sub-channel structure in a process of a read operation provided by an example of the present disclosure;

FIG. 16 is a schematic flowchart including an implementation of an operating method of a memory device provided by an example of the present disclosure;

FIG. 17 is a schematic diagram of an example system including a memory system provided by an example of the present disclosure;

FIG. 18 is a schematic diagram of an example memory card including a memory system provided by an example of the present disclosure;

FIG. 19 is a schematic diagram of an example solid state drive including a memory system provided by an example of the present disclosure.

In the above figures, which are not necessarily drawn to scale, like reference numerals may describe similar components in different views. Like reference numbers with different letter suffixes may represent different examples of similar components. The drawings generally illustrate various examples discussed herein as examples rather than as limitations.

### DETAILED DESCRIPTION

Example implementations disclosed in the present disclosure will be described in more detail below with reference to the accompanying drawings. Although example implementations of the present disclosure are shown in the accompanying drawings, it should be understood that the present disclosure may be implemented in various forms and should not be limited to the implementations set forth herein. Rather, these implementations are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that, the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, the sizes of layers, regions, elements, and their relative sizes may be exaggerated for clarity. Like reference numbers refer to like elements throughout the specification.

It should be understood that spatial relation terms such as “beneath,” “below,” “lower,” “under”, “above,” “upper,” etc., may be used herein for ease of description to describe the relationship between one element or feature and other elements or features shown in the figures. It should be appreciated that, in addition to the orientations shown in the figures, the spatial relation terms intend to also comprise different orientations of the devices in use and operation. For example, if the devices in the figures are flipped over, then those described as “below” or “under” or “beneath” other elements or features will be oriented “on” other elements or features. Thus, the example terms “below” and “beneath” may comprise both upper and lower orientations. The devices may be additionally oriented (rotated 90 degrees or other orientations) and the spatial description terminology used herein is interpreted accordingly.

The terms used herein are for the purpose of describing a particular example only and are not to be considered as limitation of the present disclosure. As used herein, “a”, “an” and “the” in the singular form are intended to comprise the plural forms as well, unless the context indicated clearly otherwise. It should also be understood that the terms “consist of” or “comprising”, when used in this description, indicate the presence of the stated features, integers, steps, operations, elements or components, but do not exclude the presence and addition of one or more other features, integers, steps, operations, elements, components or groups. As used herein, the term “and/or” comprises any and all combinations of the related listed items.

For a more detailed understanding of the features and technical contents of the examples of the present disclosure, the implementations of the examples of the present disclosure are described in detail below with reference to the accompanying drawings, and the accompanying drawings are for illustrative purposes only and are not intended to limit the examples of the present disclosure.

The technical development trend of three-dimensional (3D) NAND memories is to achieve higher storage density, better performance and lower cost. Increasing the number of deck layers of the 3D NAND memory is an effective way to increase the storage density and reduce the cost per unit capacity, and the increase in the number of layers will result in a gradual increase in the occupied area of the string driver (SD), which in turn leads to a decrease in effective utilization rate (array efficiency) of the array region, and eventually leads to a low utilization of the 3D NAND memory chip. Meanwhile, as the number of deck layers increases, the memory block size of the minimum operation unit gradually increases, and the performance of 3D NAND memory decreases accordingly.

In view of this, on the premise of increased number of deck layers of the 3D NAND memory, how to improve the effective utilization rate of the array region and/or reduce the memory block size is an urgent problem to be solved.

In some examples, the size of the string driver is reduced to reduce the occupied area of the string driver to achieve the purpose of improving the effective utilization rate of the array region; meanwhile, the number of fingers included in a single memory block is reduced, thereby reducing the memory block size to achieve the purpose of improving the performance of the 3D NAND memory chip. However, the reduction of the number of fingers of a single memory block results in an increase in the length of the string driver within the memory block along the X-axis direction perpendicular to the bit line extending direction, resulting in an increase in the occupied area of the string driver, which in turn reduces the effective utilization rate of the array region. Here, each memory block includes a plurality of parallel fingers along the Y-axis direction of the bit line extending direction divided by the gate slit structure GLS.

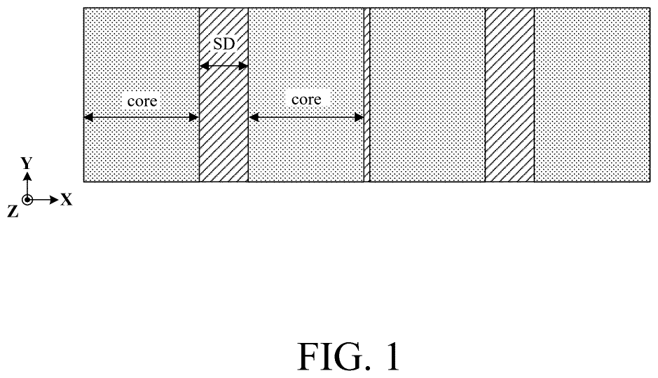

FIG. 1 shows a schematic diagram of a layout of a peripheral circuit including a string driver according to an example of the present disclosure. A specific calculation method of the effective utilization rate of the array region and the memory block size is as follows: the effective utilization rate of the array region=number of BLs/(the number of BLs located in the core area+the number of SDs located in the area); the memory block size=number of WL layers*number of strings*number of BLs*TLC (3) or QLC (4). Hereinafter, the effective utilization rate of the array region may be referred to as array efficiency for short. Here, each memory block includes a plurality of parallel strings along the Y-axis direction of the bit line extending direction divided by the GLS and the top select gate isolation structure TSGCUT, and the number of strings included in one memory block is the number of strings.

It should be noted that, for ease of description, the directions involved in the present disclosure have a unified definition herein. In the example of the present disclosure, the first direction may be a direction in which the gate layer and the dielectric layer are stacked in the deck, the second direction may be a direction in which the bit lines are spaced apart, and the third direction may be a direction in which the bit lines extend; and both the second direction and the third direction are perpendicular to the first direction. In some examples, the second direction is perpendicular to the third direction. For example, the first direction may be an extending direction of the Z-axis shown in the figure, the first direction may be an extending direction of the Z-axis shown in the figure; the second direction may be an extending direction of the X-axis shown in the figure; and the third direction may be an extending direction of the Y-axis shown in the figure.

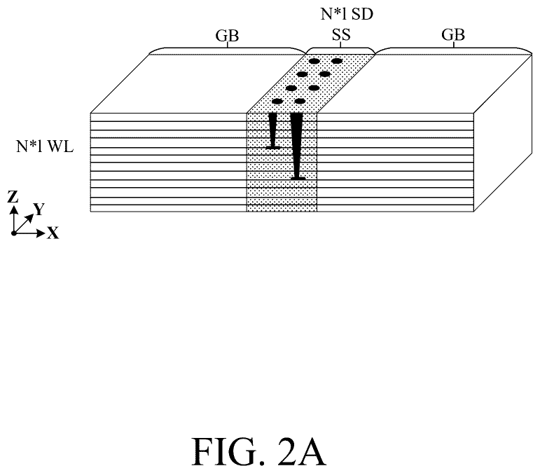

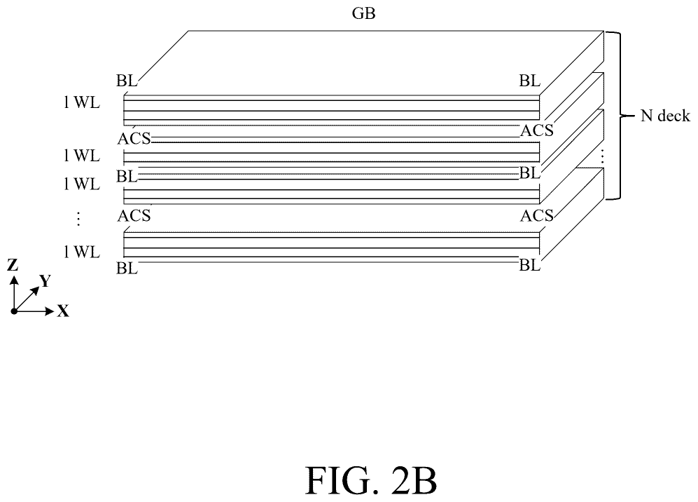

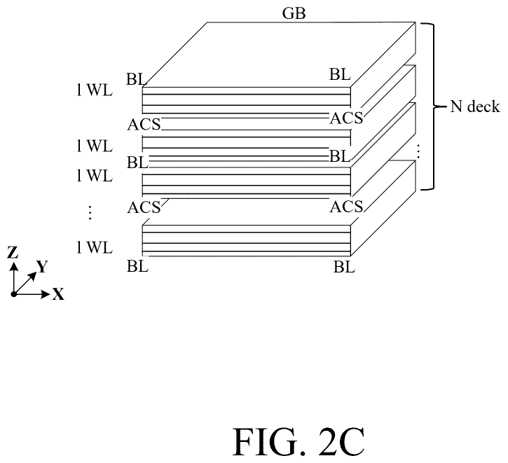

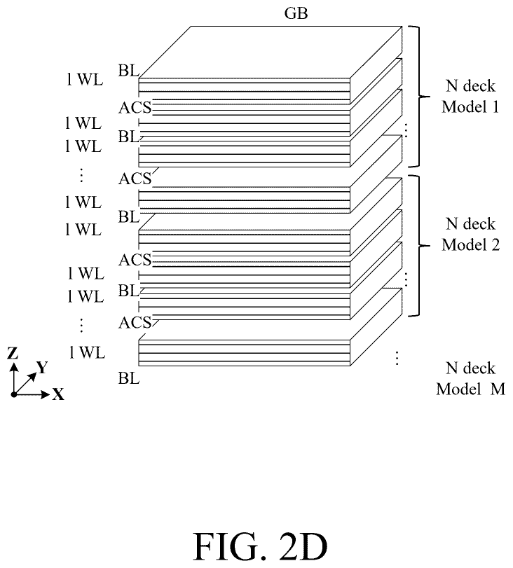

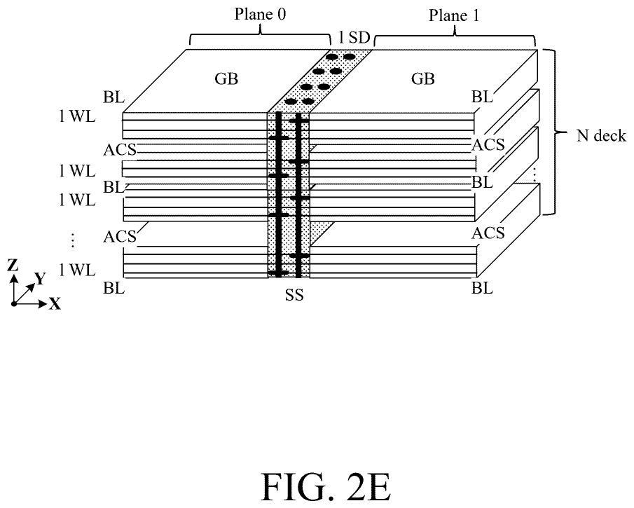

FIG. 2A shows a first schematic diagram including a memory device architecture according to an example of the present disclosure. In some examples, as shown in FIG. 2A, the memory device includes a memory array and a peripheral circuit. The memory array includes an array region GB and a connection region SS, for example, the connection region is located in the middle of the array region; a deck structure and a channel structure extending through the deck structure (not shown in FIG. 2A) are arranged in the array region, and the deck structure includes gate layers and dielectric layers that are stacked alternately; a plurality of first conductive structures (a first conductive structure may be referred to as a word line connection structure, or a first conductive structure may be referred to as a word line lead-out structure) are arranged in the connection region, and one first conductive structure is connected with one gate layer and is configured to lead out the gate layer (or referred to as the word line WL) to connect with the peripheral circuit, and specifically to the string driver SD in the peripheral circuit. In the example of the present disclosure, the number of gate layers is the same as the number of SDs, as shown in FIG. 2A, both are N*1. In the example of the present disclosure, two opposite sides of the deck structure in the first direction are arranged with a bit-line layer and a source layer respectively (not shown in FIG. 2A).

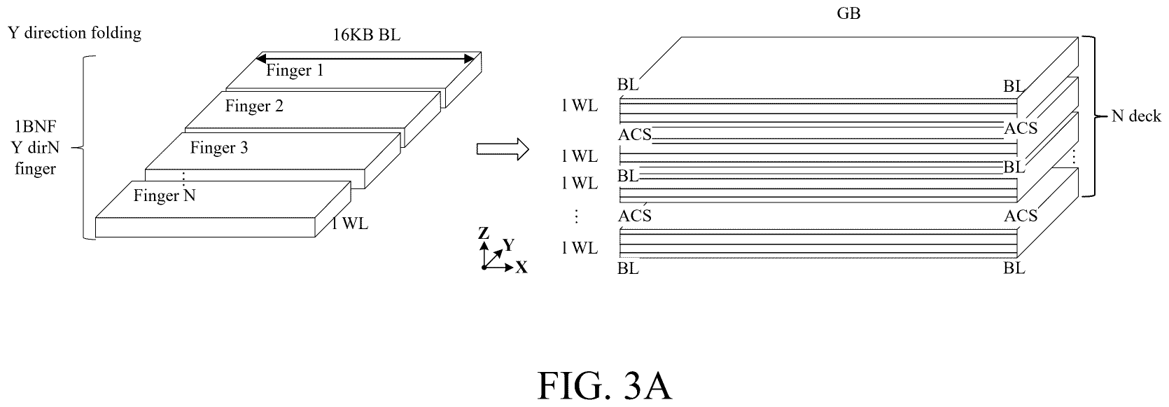

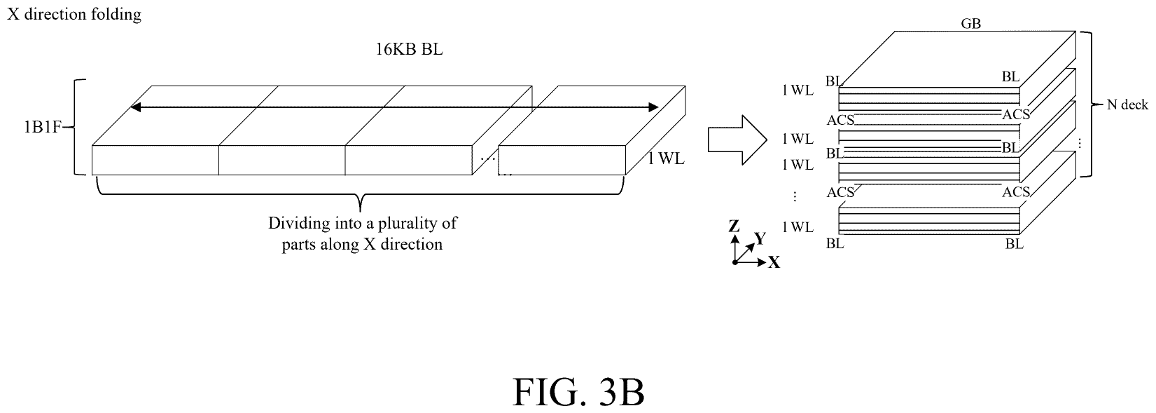

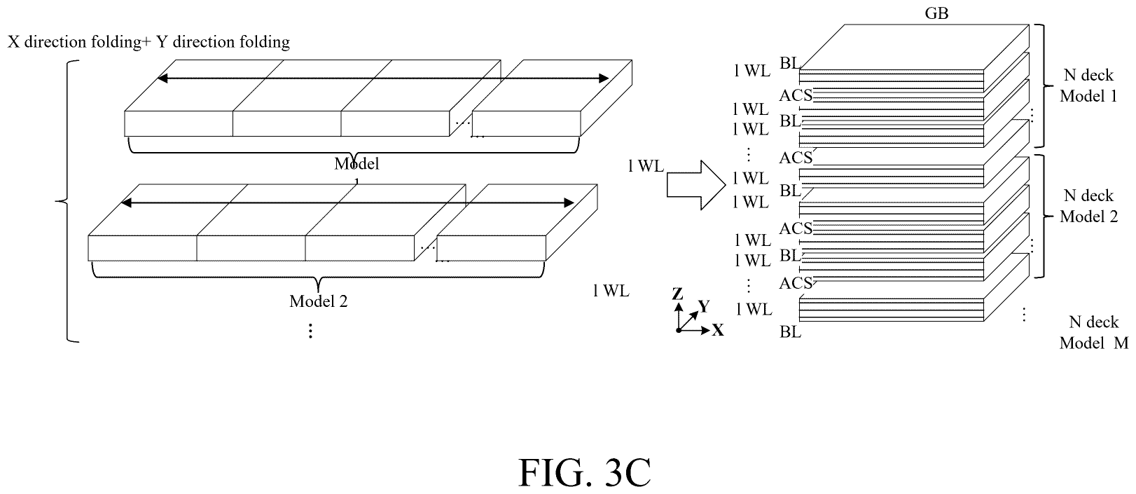

FIG. 2B to FIG. 2E show the second to fifth schematic diagrams including a memory device architecture according to an example of the present disclosure. FIG. 3A to FIG. 3C show the first to third schematic diagrams including a forming process of a memory device architecture according to an example of the present disclosure.

In some examples, as shown in FIG. 2B, the memory device includes a memory array and a peripheral circuit, the memory array includes N deck structures stacked along a first direction, and each stack structure (illustrated as a deck in FIG. 2B) includes 1 gate layer (illustrated as WL in FIG. 2B). A bit-line layer (illustrated as WL in FIG. 2B) and a source layer (illustrated as ACS in FIG. 2B) are arranged on two sides of each deck structure along the first direction, and two decks adjacent to each other along the first direction may share the same BL or ACS. The memory array may further include a plurality of first conductive structures, and one first conductive structure is connected with one gate layer of each of at least two deck structures (for example, N decks), so as to lead out the connected gate layers to the SD in the peripheral circuit.

As shown in FIG. 3A, the architecture of the memory device shown in FIG. 2B may be obtained by dividing a deck structure into N parts along the Y-axis direction, e.g., the third direction, and then stacking the N parts along the Z-axis direction. It should be noted that the architecture of the memory device shown in FIG. 2B only illustrates the array region, and the connection region is omitted. In addition, the total number of gate layers in FIG. 2B is also N*1. The architecture of the memory device shown in FIGS. 2B and 3A is referred to hereinafter as an array Y-axis direction folding architecture.

In some examples, as shown in FIG. 2C, the memory device includes a memory array and a peripheral circuit, the memory array includes N deck structures stacked along a first direction, and each deck (illustrated as deck in FIG. 2C) includes 1 gate layer (illustrated as WL in FIG. 2C). A bit-line layer (illustrated as WL in FIG. 2C) and a source layer (illustrated as ACS in FIG. 2C) are arranged on two sides of each deck structure along the first direction, and two deck structures adjacent to each other along the first direction may share the same BL or ACS. The memory array may further include a plurality of first conductive structures, and one first conductive structure is connected with one gate layer of each of at least two deck structures (for example, N decks), so as to lead out the connected gate layers to the SD in the peripheral circuit.

As shown in FIG. 3B, the architecture of the memory device shown in FIG. 2C may be obtained by dividing a deck structure into N parts along the X-axis direction, e.g., the second direction, and then stacking the N parts along the Z-axis direction. It should be noted that the architecture of the memory device shown in FIG. 2C only illustrates the array region, and the connection region is omitted. In addition, the total number of gate layers in FIG. 2C is also N*1. The architecture of the memory device shown in FIGS. 2C and 3B is referred to hereinafter as an array X-axis direction folding architecture.

It can be understood that, if the total number of the array region bit lines in one deck structure which is not divided is Q KB (here Q is a positive integer, for example, 16 KB), the total number of the array region bit lines in the example of FIG. 2B is still Q KB (for example, 16 KB), and the total number of the array region bit lines in the example of FIG. 2C is Q/N KB (for example, 16/N KB).

In some examples, as shown in FIG. 2D, the memory device includes a memory array and a peripheral circuit, the memory array includes a plurality of M memory modules stacked along a first direction, each memory module (illustrated as Model in FIG. 2D) includes N deck structures, the N deck structures may be N deck structures of the array Y-axis direction folding structure shown in FIG. 2B, and the N deck structures may further be N deck structures of the array X-axis direction folding structure shown in FIG. 2C. The memory array may further include a plurality of first conductive structures, and one first conductive structure is connected with one gate layer of each of at least two deck structures (for example, N decks), so as to lead out the connected gate layers to the SD in the peripheral circuit. It should be noted that the architecture of the memory device shown in FIG. 2D only illustrates the array region, and the connection region is omitted. The architecture of the memory device shown in FIG. 2D is referred to hereinafter as an array X axis+Y axis direction folding architecture.

The array X axis+Y axis direction folding structure has at least two formation methods as the following.

In some examples, as shown in FIG. 3C, first, the N deck structures are folded along the X-axis direction to obtain a memory module, and M memory modules are obtained accordingly, and then the M memory modules are folded along the Y direction to obtain M memory modules, and this scheme is referred to as an X-axis+Y-axis direction folding scheme 1 for short.

In some examples, first, the N deck structures are folded along the Y-axis direction to obtain a memory module, and M memory modules are obtained accordingly, and then the M memory modules are folded along the X direction to obtain M memory modules, and this scheme is referred to as an X-axis+Y-axis direction folding scheme 2 for short.

It can be understood that the forming method of the above two array X axis+Y axis direction folding architectures have different folding sequences. Taking the generation of two memory modules as an example, the scheme 1 is to divide one non-divided deck structure into 4*2=8 parts along the X axis and the Y axis directions, and the scheme 2 is to divide one non-divided deck structure into 2*4=8 parts along the X axis and the Y axis directions; although both are divided into 8 parts and the 8 parts are all stacked along the Z axis direction, if the sizes of the non-divided deck structure itself along the X axis and the Y axis directions are different, the sizes of parts in the final scheme 1 and the scheme 2 may be different.

In some examples, as shown in FIG. 2E, the memory device includes a memory array and a peripheral circuit, and the memory array includes two memory planes (Plane 0 and Plane 1 shown in FIG. 2E) arranged in parallel along the X-axis direction, e.g., the second direction. Each memory plane may be a deck structure of the array Y-axis direction folding architecture shown in FIG. 2B (in this case, the total number of bit lines of each memory plane is Q KB, for example, 16 KB); each memory plane may also be a deck structure of the array X-axis direction folding architecture shown in FIG. 2C (in this case, the total number of bit lines of each memory plane is Q/N KB, for example, 16/N KB); each memory plane may also be a deck structure of the array X direction+Y-axis direction folding architecture shown in FIG. 2D (regarding to first the X axis direction folding and then the Y axis direction folding, the total number of bit lines of each memory plane is Q/N KB, for example, 16/N KB).

The memory array further includes a connection region between the two memory planes, the connection region is arranged with a plurality of conductive structures shared by the two memory planes, one of the conductive structures may be connected with one gate layer of each of the plurality of deck structures (for example, N decks) in the two memory planes, and is configured to lead out the gate layer to the SD in the peripheral circuit, so that the number of the SDs in FIG. 2D may be 1. The architecture of the memory device shown in FIG. 2E is referred to hereinafter as a memory plane combination architecture.

It can be understood that, in the array Y-axis direction folding architecture shown in FIG. 2B, the sharing of the word line lead-out structures (e.g., the first conductive structures) in the N deck structures reduces the area of SD by N times, thereby improving the effective utilization rate of the array region on the premise of increased number of deck layers. In the array X-axis direction folding architecture shown in FIG. 2C, the total number of BLs is reduced to 1/N of the total number of BLs before folding, and the sharing of the folding and word line lead-out structures (e.g., the first conductive structure) reduces the area of SD by N times, and also reduces the memory block size by 1/N. In the array X-axis+Y-axis direction folding architecture shown in FIG. 2D, in combination with the advantages of the two architectures, the effective utilization rate of the array region can be improved, and also the memory block size can be reduced. The memory plane combination architecture shown in FIG. 2E further shares a word line lead-out structure, which further improves the effective utilization rate of the array region. In other words, the above four architectures of the memory device have solved the contradiction problem that the area of SD is increased due to reducing memory block size by reducing the number of fingers in the architecture shown in FIG. 2A.

For the above four architectures of the memory device, implementation details of those architectures will be described in detail below. It should be noted that the following implementation details may be applied to the foregoing four architectures of the memory device.

The example of the present disclosure provides a memory device, including: a plurality of first deck structures stacked together, where the first deck structure includes first conductive layers and first dielectric layers arranged alternately along a first direction; a first conductive structure extending along the first direction and connected with one first conductive layer of each of at least two first deck structures of the plurality of first deck structures; a plurality of channel structures extending through the plurality of first deck structures; and at least one semiconductor layer, where one semiconductor layer is connected with the channel structure in at least one of the plurality of first deck structures.

In the example of the present disclosure, the first deck structure may be understood as a deck structure in the foregoing four memory device architectures. In some examples, the material of the first conductive layer may include a conductive material including, but not limited to, tungsten (W), cobalt (Co), copper (Cu), aluminum (Al), polysilicon, doped silicon, silicide, or any combination thereof. In some implementations, each first conductive layer includes a metal layer, such as a tungsten layer. In some implementations, each first conductive layer includes a doped-polysilicon layer. In some examples, the material of the first dielectric layer may include an oxide. In some implementations, the material of the first dielectric layer includes silicon oxide.

In some examples, the channel structure extending through each of the plurality of first deck structures may include a gate dielectric layer, a charge storage layer, a tunneling layer, and a channel layer. In some examples, the channel structure may have a cylindrical shape (e.g., a pillar shape). In some implementations, the channel layer, the tunneling layer, the charge storage layer, and the gate dielectric layer are arranged radially from a center of the pillar toward an outer surface of the pillar in this order. The tunneling layer may include silicon oxide, silicon oxynitride, or any combination thereof. The charge storage layer may include silicon nitride, silicon oxynitride, or any combination thereof. The gate dielectric layer may include silicon oxide, silicon oxynitride, a high dielectric constant (high-k) dielectric, or any combination thereof. In some implementations, the tunneling layer, the charge storage layer, and the gate dielectric layer may be collectively referred to as a memory film, which may include a composite layer of silicon oxide/silicon oxynitride/silicon oxide (ONO).

In the example of the present disclosure, the semiconductor layer may serve as a source layer, and is connected with a channel layer in the channel structure. In some examples, the material of the semiconductor layer may include various semiconductor materials. In some implementations, the material of the semiconductor layer includes polysilicon.

In some examples, the memory device may further include at least one second conductive layer, and one second conductive layer is connected with the channel structure of at least one of the plurality of first deck structures, and includes a plurality of bit lines spaced apart along the second direction and extending along the third direction; both the second direction and the third direction are perpendicular to the first direction. In the example of the present disclosure, one semiconductor layer and one second conductive layer that are connected with the channel structure in the same first deck structure are arranged on two sides of the first deck structure respectively along the first direction.

In some examples, one semiconductor layer of at least one semiconductor layer is located between two adjacent first deck structures and is connected with the channel structure of each of the two adjacent first deck structures.

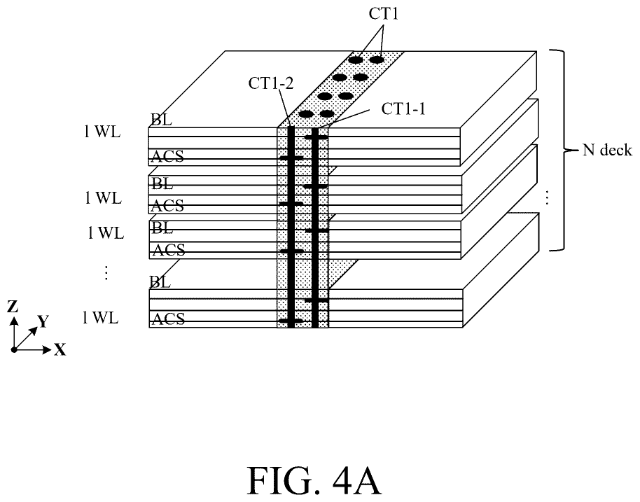

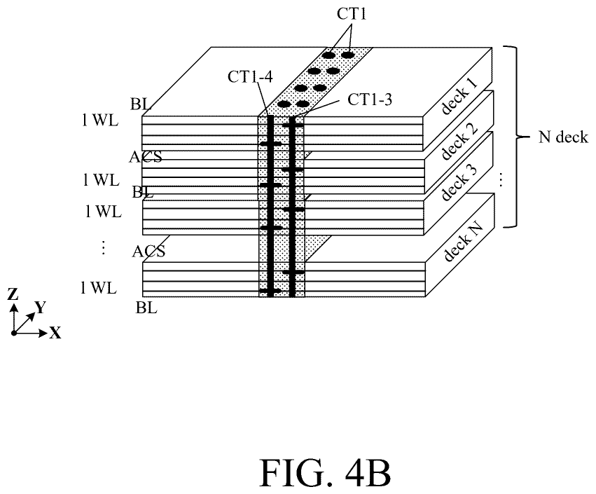

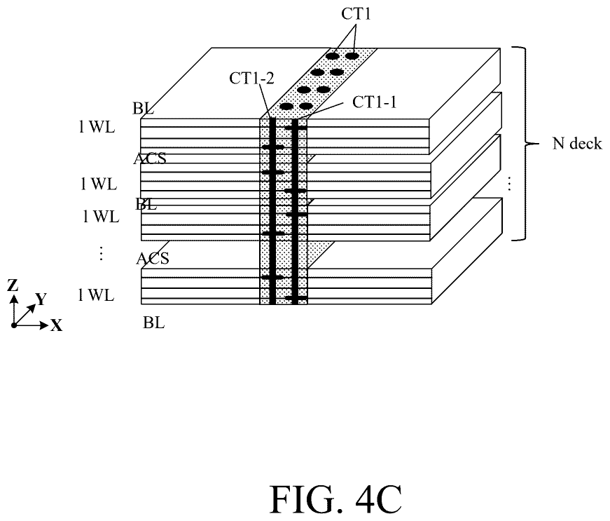

In some implementations, as shown in FIG. 4A, one second conductive layer (illustrated as BL in FIG. 4A) and one semiconductor layer (illustrated as ACS in FIG. 4A) are arranged on two sides of the first deck structure respectively along the first direction, and one second conductive layer and one semiconductor layer are arranged between two adjacent first deck structures along the first direction.

In some implementations, as shown in FIGS. 4B and 4C, one second conductive layer (illustrated as BL in FIG. 4B and FIG. 4C) and one semiconductor layer (illustrated as ACS in FIG. 4B and FIG. 4C) are arranged on two sides of the first deck structure respectively along the first direction, and one common second conductive layer or one common semiconductor layer is arranged between two adjacent first deck structures in the first direction. It should be noted that the common second conductive layer or the common semiconductor layer is connected with the channel layers of the channel structures in the first deck structures on both sides of the common second conductive layer or the common semiconductor layer, and is shared by the channel structures in the first deck structures on both sides of the common second conductive layer or the common semiconductor layer.

In some other implementations, if the second semiconductor layer and the semiconductor layer are not shared, two second conductive layers or two common semiconductor layers may be arranged between two adjacent first deck structures along the first direction, and each of the two second conductive layers or each of the two common semiconductor layers belongs to the first deck structure on both sides, respectively.

In some examples, the first conductive layers in each first deck structure include a plurality of gate layers, which may be referred to as word lines. In some examples, the first conductive layers in each first deck structure further include a top select gate layer and a bottom select gate layer, the gate layer of each first deck structure away from the semiconductor layer may serve as the top select gate layer of a corresponding deck structure, the gate layer of each deck structure close to the semiconductor layer may serve as the bottom select gate layer of the corresponding deck structure, and the gate layer between the top select gate layer and the bottom select gate layer may serve as a word line.

In the example of the present disclosure, the first conductive structure may include a word line lead-out structure, one first conductive structure is connected with one gate layer of at least two first deck structures, and is configured to lead out the gate layer (or referred to as the word line WL) to be connected with the peripheral circuit, and is specifically connected with the string driver SD in the peripheral circuit. In some implementations, there are N first deck structures; one first conductive structure is connected with one first conductive layer of M first deck structures of the N deck structures, e.g., one first conductive structure is connected with M first conductive layers corresponding to the M deck structures. Here, M and N are both positive integers, and N≥M≥2.

In some examples, the first conductive structure may be connected with one gate layer of each of two adjacent first deck structures, or may be connected with one gate layer of each of the first deck structures that are spaced apart, or may be connected with one gate layer of all first deck structures. The first conductive structure may be connected with one gate layer of one deck, extend through the deck, and be connected with one gate layer of another adjacent deck. The first conductive structure may also extend through all the decks and be connected with the gate layers of all the decks.

In some examples, the first conductive structure is connected with one first conductive layer of each of the plurality of first deck structures.

In some examples, each of the first conductive layers connected with the same first conductive structure in different ones of the first deck structures has the same distance from the semiconductor layer connected with the channel structure in a corresponding first deck structure.

In the example of the present disclosure, one first conductive structure CT1 is connected with one first conductive layer of each of the plurality of first deck structures, and the first conductive layer connected in each first deck structure has the same distance from the semiconductor layer or the second semiconductor layer connected with the channel structure in a corresponding first deck structure.

For example, as shown in FIG. 4A and FIG. 4C, each first deck structure includes 1 gate layer. Taking N=5 as an example, the gate layers of each of the first deck structures from the second conductive layer (BL) to the semiconductor layer (ACS) are WL1, WL2, WL3, WL4, and WL5, respectively. When the first conductive structure CT1 is connected to the gate layers of the plurality of decks, the first conductive structure CT1 may be connected to the same gate layer of different decks, for example, one of the plurality of first conductive structures CT1 is connected to WL2 of all the first deck structures, and the other one of the plurality of first conductive structures CT1 is connected to WL4 of all the deck structures.

In some examples, the first conductive layers connected with the same first conductive structure in two different ones of the first deck structures have different distances from the semiconductor layer connected with the channel structure in a corresponding first deck structure.

In the examples of the present disclosure, one first conductive structure is connected with one first conductive layer of each of the plurality of first deck structures, and the first conductive layers connected in at least two first deck structures have different distances from the semiconductor layer or the second semiconductor layer connected with the channel structure in a corresponding first deck structure.

For example, as shown in FIG. 4B, each first deck structure includes 1 gate layer. Taking N=5 as an example, the gate layers of each first deck structure from the second conductive layer (BL) to the semiconductor layer (ACS) are WL1, WL2, WL3, WL4 and WL5, respectively. When the first conductive structure CT1 is connected to the gate layers of the plurality of deck structures, the first conductive structure CT1 may be connected to different gate layers of different decks, for example, one first conductive structures CT1-3 of the plurality of first conductive structures CT1 is connected to WL2 of the deck1, and CT1-3 is connected to WL4 of the deck2; another first conductive structures CT1-4 of the plurality of first conductive structures CT1 is connected to WL4 of the Deck1, and the CT2 is connected to WL2 of the Deck2.

In some examples, if the first conductive structure is connected with one first conductive layer of each of the plurality of first deck structures, the number of the first conductive layers connected with one first conductive structure may be equal to the number N of the decks.

In some examples, different first conductive layers of the first deck structure are connected with different first conductive structures. That is, different gate layers of the deck structure are led out through different first conductive structures.

In some examples, the number of the first conductive structures is the same as the number of the first conductive layers included in the first deck structure; and the total number of the first conductive layers included in the plurality of first deck structures is greater than twice the number of the first conductive structures.

In the example of the present disclosure, there are a plurality of position relationships between the first region where the plurality of first deck structures are arranged and the second region where the first conductive structure is arranged.

In some examples, the plurality of first deck structures are arranged in the first region S1, the first conductive structures are all arranged in the second region S2, and the second region S2 is located in the middle of the first region S1.

In some examples, the plurality of first deck structures are arranged in the first region S1, the first conductive structures are all arranged in the second region S2, and the second region S2 is located on at least one of the two sides of the first region S2 perpendicular to the first direction.

Here, the first region may be understood as the foregoing array region GB, and the second region may be understood as the foregoing connection region SS.

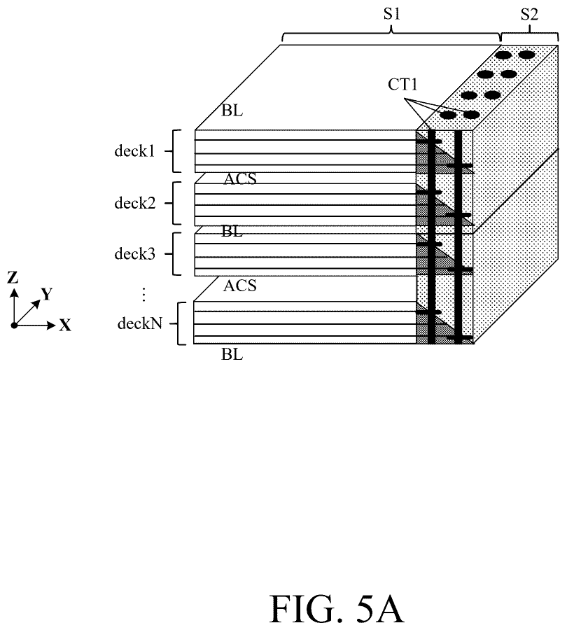

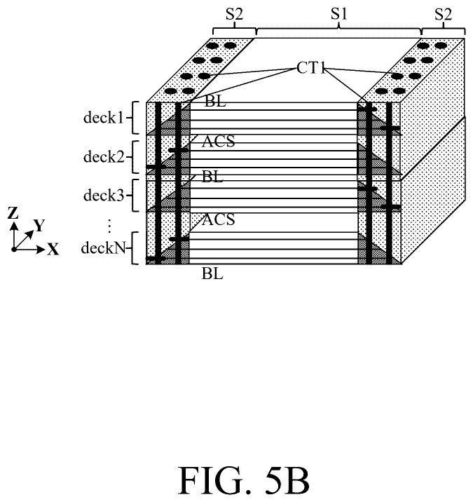

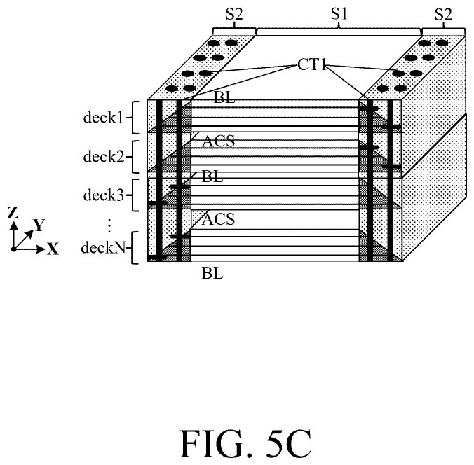

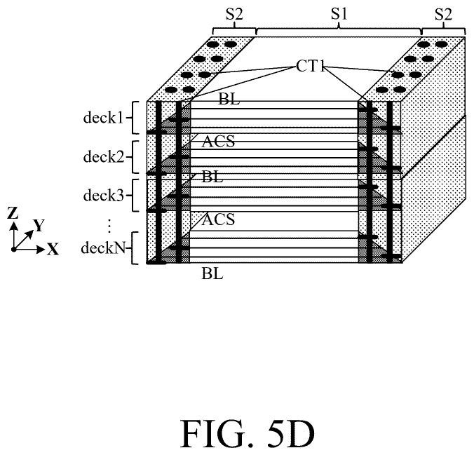

In some implementations, along the X-axis direction, e.g., the second direction, one second region S2 is located on one side of one first region S1 (the right side as shown in FIG. 5A), all of the first conductive structures are located on the same side of the first region, the area of the second region S2 is small, and has a high area utilization rate.

In some implementations, along the X direction, e.g., the second direction, the two second regions S2 are located on two sides of one first region S1 respectively, a portion of the first conductive structure is located on the left side of the first region S1, a portion of the first conductive structure is located on the right side of the first region S1, and the first conductive structures connected with all the gate layers of the same deck structure are located on the same side of the array region, and the first conductive structures corresponding to any adjacent decks are located on different sides of the first region S1. For example, as shown in FIG. 5B, when N=4, the first conductive structures connected with the gate layers of deck1 and deck3 are all located on the right side of the first region S1, and the first conductive structures connected with the gate layers of deck2 and deck4 are all located on the left side of the first region S1.

In some implementations, along the X direction, e.g., the second direction, the two second regions S2 are located on two sides of one first region S1 respectively, a portion of the first conductive structure is located on the left side of the first region S1, a portion of the first conductive structure is located on the right side of the first region S1, and the first conductive structures connected with all the gate layers of the same deck structure are located on the same side of the first region S1, and the first conductive structures corresponding to at least two adjacent decks may be located on the same side of the first region S1. For example, as shown in FIG. 5C, when N=4, the first conductive structures connected with all the gate layers of deck1 are all located on the right side of the first region S1, and the first conductive structures connected with all the gate layers of deck3 are all located on the left side of the first region S1.

In some implementations, along the X direction, e.g., the second direction, the two second regions S2 are located on two sides of one first region S1 respectively, a portion of the first conductive structures are located on the left side of the first region S1, a portion of the first conductive structures are located on the right side of the first region S1, and the first conductive structures connected with all the gate layers of the same deck structure are located at different sides of the first region S1. For example, as shown in FIG. 5D, when N=4, the portion of the first conductive structure connected with the portion of the gate layer of deck1 is located on the left side of the first region S1, and the other portion of the first conductive structure connected with the other portion of the gate layer of deck1 is located on the right side of the first region S1. As such, the area of the second region S2 is small and has a high area utilization rate.

It should be noted that, in other examples of the present disclosure, the arrangement of the first conductive structure in the above second region may also be a combination of the above plurality of arrangements.

In some examples, the first conductive structure at least partially extends through all the first deck structures and is connected with one gate layer of a portion of the first deck structures. In some examples, the first conductive structure may completely extend through all the first deck structures and is connected with one gate layer of all the first deck structures. In the example of the present disclosure, the first conductive structure may include a plurality of structural forms, several of which are described below.

In some examples, a cross-sectional shape of the plurality of first deck structures along the first direction includes a step-like shape; each step in the step-like shape corresponds to the first conductive layer and the first dielectric layer adjacent to each other; and the first conductive structure extends along the first direction in the first deck structure and is connected to at least two steps where one first conductive layer of at least two first deck structures is located.

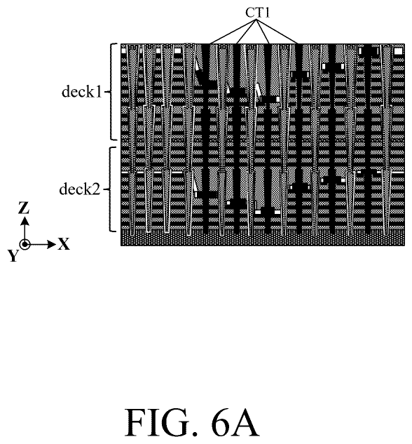

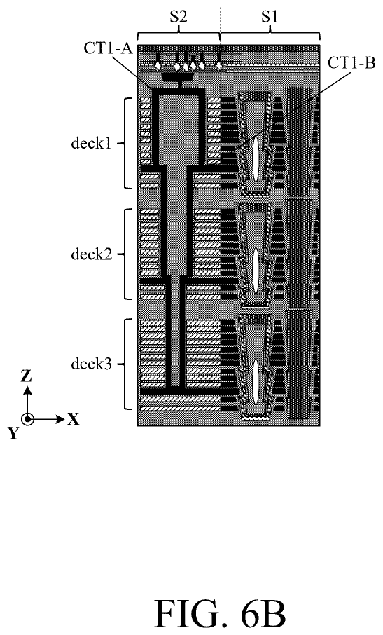

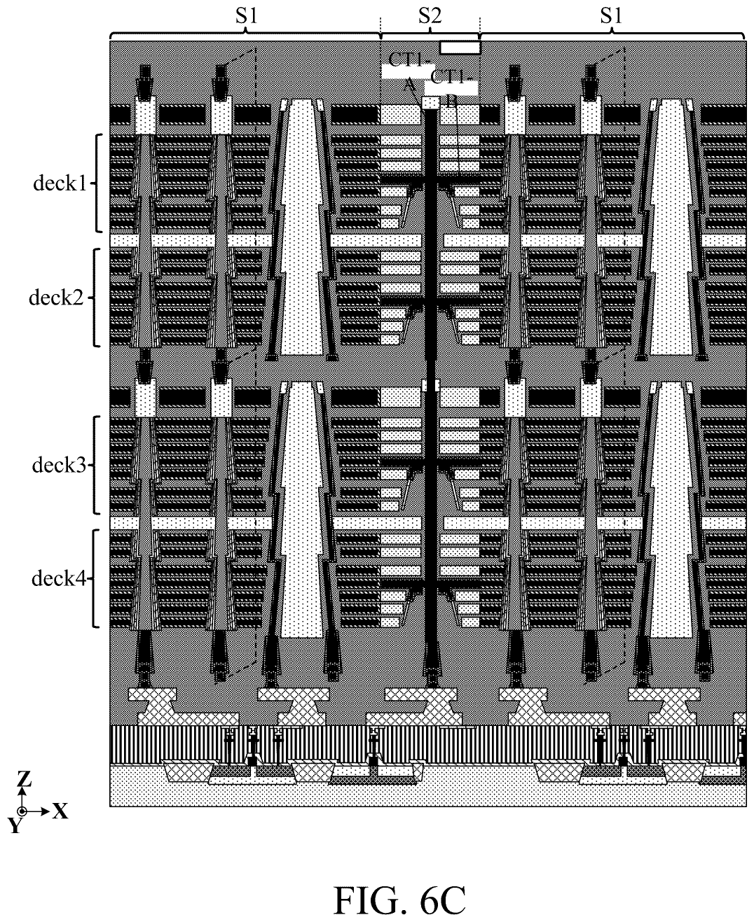

In the example of the present disclosure, the connection of the gate layers of different decks may be implemented in a manner of steps, as shown in FIG. 6A, a stair structure is formed in the second region of each first deck structure, the stair structure has a step shape including a plurality of steps, each step corresponds to one first conductive layer and one first dielectric layer adjacent to each other, and each first conductive structure CT1 is connected with a gate layer corresponding to one step of each of the plurality of decks.

It should be noted that, in the example of the present disclosure, each step corresponds to one gate layer, an arrangement form of the stair structure is not limited, and a regular or irregular increment or decrement arrangement may be presented. In the example of the present disclosure, the first conductive structure may be located in the first deck structure, e.g., the second region is in the first deck structure.

In some examples, the memory device further includes a second deck structure including isolation layers and second dielectric layers arranged alternately along the first direction; the first conductive structure includes a first lead-out portion and a plurality of first connection portions; the first lead-out portion extends along the first direction in the second deck structure and is connected with each of the plurality of first connection portions; each of the plurality of first connection portions is located in the isolation layer and is connected to one first conductive layer of a corresponding one of at least two first deck structures.

In some examples, a material of the isolation layer includes, but is not limited to, silicon nitride, and a material of the second dielectric layer includes, but is not limited to, silicon oxide. In the example of the present disclosure, the first conductive layer and the isolation layer are arranged in the same layer, and the first dielectric layer and the second dielectric layer are arranged in the same layer. The first conductive structure may be in the second deck structure, e.g., the second region is in the second deck structure. The second deck structure may be located in the middle or on both sides of the first deck structure.

In the example of the present disclosure, the first lead-out portion may extend through all the first deck structures along the first direction or only extend to the first conductive layer that needs to be connected with the corresponding first deck structure; the first lead-out portion may be solid or hollow; and the first lead-out portion may have the same aperture or have a varied aperture along the first direction.

In some examples, the first lead-out portion includes a dielectric structure extending along the first direction and a peripheral conductive layer surrounding the dielectric structure; and the peripheral conductive layer is connected with each of the plurality of first connection portions.

In the example of the present disclosure, WL connections of different decks are implemented in the form of sleeve holes. For example, as shown in FIG. 6B, the first lead-out portion CT1-A may be a segmented structure. Taking three first deck structures being stacked as an example, each first deck structure has a gate layer connected with the same first lead-out portion CT1-A, the first lead-out portion CT1-A includes a first sub-segment, a second sub-segment, and a third sub-segment, the first sub-segment is located above the gate layer correspondingly connected with the uppermost first deck structure, the second sub-segment is located between the gate layer correspondingly connected with the uppermost first deck structure and the gate layer correspondingly connected with the middle first deck structure, and the third sub-segment is located between the gate layer correspondingly connected with the middle first deck structure and the gate layer correspondingly connected with the lowermost first deck structure. A size of the first sub-segment along the second direction is greater than a size of the second sub-segment along the second direction, and a size of the second sub-segment along the second direction is greater than a size of the third sub-segment along the second direction. The gate layer correspondingly connected with each first deck structure is connected with the first connection portion CT1-B extending along the second direction and is connected to the first lead-out portions CT1-A through the corresponding first connection portion CT1-B.

In some examples, the first lead-out portion includes a conductive pillar.

In the example of the present disclosure, WL connections of different deck structures are implemented in a manner of SCTs. For example, as shown in FIG. 6C, the first lead-out portion CT1-A includes a conductive pillar extending through the plurality of second deck structures, a gate layer of each first deck structure is connected with the conductive pillar through one first connection portion CT1-B extending along the second direction, and the conductive pillar is filled with a conductive material, such as tungsten.

In some examples, the memory device further includes a peripheral circuit including a string driver; and one first conductive layer of each of at least two first deck structures is connected to each other through the first conductive structure and is connected with the same string driver SD.

In the example of the present disclosure, the peripheral circuit may include a plurality of string drivers, and the first conductive layers of at least two decks along the first direction are connected to the same SD after being interconnected, e.g., the same first conductive structure connects a plurality of gate layers interconnected in different decks to the same SD, and the plurality of gate layers that are interconnected may share one SD. It may be understood that, since the plurality of gate layers may share one SD, the total number of SDs can be reduced.

In some examples, along the first direction, the region where the string driver is arranged is aligned with the region where the first conductive structure is arranged. Therefore, the routing distance between them can be reduced, so that size of the string driver and the corresponding gate layer can be reduced, the power consumption loss is lower, and the delay is smaller.

In some examples, the memory device has a first number of first deck structures, the first deck structure has a second number of first conductive layers, the memory device has a third number of string drivers, and the third number is less than a product of the first number and the second number.

Here, the first number is the number of the first deck structures, the second number is the number of the first conductive layers included in each first deck structure, and the third number is the number of the SDs. In the example of the present disclosure without the stacking of decks (as shown in FIG. 2A), the number of SDs and the number of WLs (gate layers) are the same. In the example of the present disclosure with the stacking of decks (as shown in FIG. 2B, FIG. 2C, and FIG. 2D), the number of the SDs may be the same as the number of the first conductive structures, the number of the SDs is less than the total number of WLs; and the number of WLs is N (the number of decks, e.g., the first number) times of the number of the SDs. In some examples, if the first conductive layer is WL, then the total number of WLs=N*the number of SDs.

In some examples, there are at least one second conductive layer and a plurality of second conductive structures; one second conductive layer is connected with the channel structure of at least one of the plurality of first deck structures and includes a plurality of bit lines spaced apart along the second direction and extending along the third direction; both the second direction and the third direction are perpendicular to the first direction; and the second conductive structures extend along the first direction in the first deck structure and are connected with one bit line of at least one second conductive layer.

In some examples, the plurality of first deck structures are arranged in a first region, the plurality of second conductive structures are all arranged in a third region, and the third region is located on at least one of two sides of the first region along the third direction.

Here, the second conductive structure is a lead-out structure corresponding to the bit line, and the structural form of the second conductive structure and the position where the second conductive structure is arranged will be further described below.

In some examples, the memory device further includes third conductive structures; the first conductive layers in the first deck structure include a top select gate layer and a gate layer; the top select gate layer is located at one end of two ends of a corresponding first deck structure along the first direction away from the semiconductor layer connected with the channel structure in the corresponding first deck structure; the third conductive structure extends along the first direction in the first deck structure and is connected with the top select gate layer included in at least one of the plurality of first deck structures; and the first conductive structure is connected with one gate layer of each of at least two first deck structures of the plurality of first deck structures

In some examples, the plurality of first deck structures are arranged in a first region, the first conductive structures are all arranged in a second region, the third conductive structures are all arranged in a fourth region, and the fourth region is located between the first region and the second region.

In some examples, the third conductive structure includes a second lead-out portion, a second connection portion and a contact portion; the second lead-out portion extends along the first direction and is connected with the second connection portion; the second connection portion extends along the second direction and is connected with the contact portion; the contact portion extends along the first direction and is connected with the top select gate layer; and the second direction is perpendicular to the first direction.

Here, the third conductive structure is a lead-out structure corresponding to the top select gate layer, and the structural form of the third conductive structure and the position where the third conductive structure is arranged will be further described below.

In some examples, the plurality of first deck structures stacked together constitute a memory plane; the memory device includes at least two memory planes; two memory planes of at least two memory planes are arranged in parallel along the second direction; the second direction is perpendicular to the first direction; and the first conductive structure is located between the two memory planes and is connected with one first conductive layer of each of different ones of the first deck structures in at least one memory plane.

In the example of the present disclosure, the first conductive structure is located between the two memory planes, but whether the two memory planes share the first conductive structure is not limited, e.g., one first conductive structure may be connected with the first conductive layer of each of different decks of one memory plane, and one first conductive structure may also be connected with the first conductive layer of different decks of each memory plane of the two parallel memory planes.

In some examples, the memory device further includes a peripheral circuit; the peripheral circuit includes a plurality of string drivers; and the first conductive layers of different memory planes at the same position along the first direction are connected with each other and connected with the same one of the string drivers.

Here, Regarding the memory plane, reference may be made to the description about the memory plane in FIG. 2E. The first conductive layers at the same positions along the first direction in different memory planes may be understood as the first conductive layers in the same layer in different memory planes, the first conductive layers in the same layer are connected with the same first conductive structure, and connected with the same SD through the same first conductive structure.

As mentioned above, each first deck structure is arranged with a semiconductor layer (source layer) and a second conductive layer (a layer formed by a plurality of bit lines, which may also be referred to as a bit-line layer) corresponding to the first deck structure. In the example of the present disclosure, the semiconductor layer or the second conductive layer may be shared between two first deck structures adjacent to each other along the first direction.

In some examples, one semiconductor layer of at least one semiconductor layer is located between two adjacent first deck structures and is connected with the channel structure of each of the two adjacent first deck structures.

In some examples, one of the at least one second conductive layer is located between two adjacent first deck structures and is connected with the channel structure of each of the two adjacent first deck structures.

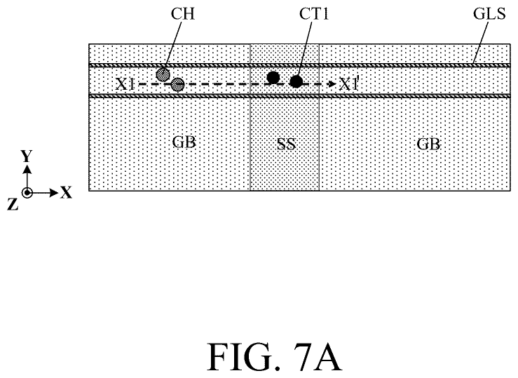

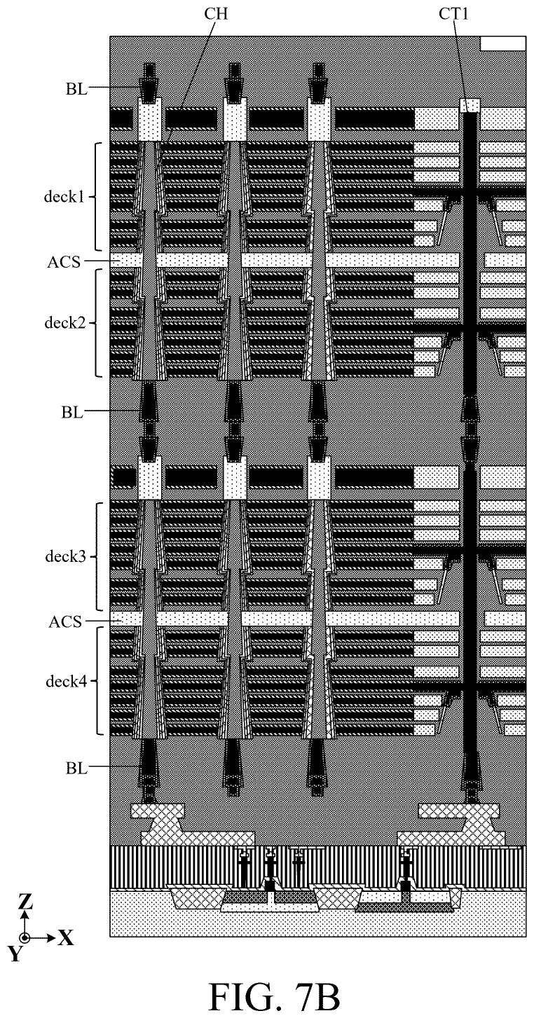

In some implementations, as shown in FIG. 7A to FIG. 7B, the memory device includes a first deck structure located in an array region GB (a first region) and a second deck structure located in a connection region SS (second region), the first deck structure includes a first conductive layer and a first dielectric layer that are stacked alternately, and the second deck structure includes an isolation layer and a second dielectric layer that are stacked alternately. The first conductive layer and the isolation layer are arranged in the same layer, and the first dielectric layer and the second dielectric layer are arranged in the same layer. The memory device includes a plurality of first deck structures stacked along a first direction (4 decks are shown in FIG. 7B), a bit-line layer (for example, a bit-line layer between deck2 and deck3) may be shared between two adjacent decks, the bit lines of all the decks along the first direction (all bit lines connected with the same channel structure) may be interconnected, and the connection of bit lines may be connected by a conductive pillar (not shown in FIG. 7A, FIG. 7B, and with reference to a dotted line in FIG. 6C), may be connected by a structure similar to a channel (for example, a dummy channel), or may be connected by a structure in a gate slit structure.

In some implementations, the source layer ACS may be shared between two decks adjacent to each other along the first direction, and the source layers of all the decks may be interconnected or may not be interconnected. The source layers of all the decks may be interconnected by channel layers in the channel structure.

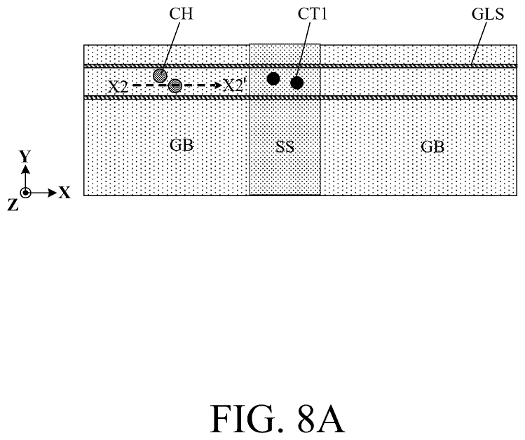

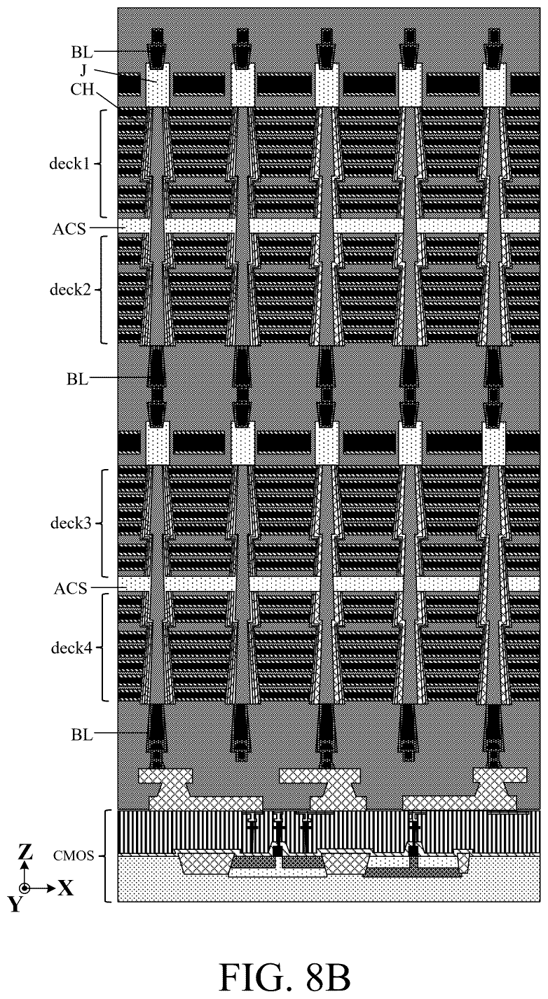

In some implementations, as shown in FIG. 8A to FIG. 8B, the memory device includes a plurality of channel structures CH located in an array region GB (first region), the channel structure CH may extend through two adjacent decks, the channel structure may include a channel layer and a functional layer surrounding the channel layer, and the functional layer includes a tunneling layer, a charge trapping layer, and a charge blocking layer arranged from inside to outside. In some implementations, two ends of the channel structure each are connected with one bit line BL, and a common source layer ACS (such as an ACS between deck1 and deck2, an ACS between deck3 and deck4) is arranged between two adjacent first deck structures, and the common source ACS is connected with the channel layer of the channel structure. The material of the common source ACS includes, but is not limited to, polysilicon.

In some implementations, the functional layer of the channel structure may be a discontinuous structure, the functional layer includes a first functional layer above the common source ACS and a second functional layer below the common source ACS, and the first functional layer and the second functional layer are isolated by a common source layer.

In some implementations, as shown in FIG. 8A to FIG. 8B, the bit lines BL connected with two ends of the channel structure respectively may be led out separately and connected with the peripheral circuit CMOS separately, or may be led out from the bit line on one side of the channel structure after being connected and then connected with the peripheral circuit, or may be other implementations of bit line and peripheral circuit. In some implementations, the connection structure J is further arranged between the bit line connected with the channel structure and away from the side of the peripheral circuit and the corresponding channel structure, and the material of the connecting structure may include doped polysilicon or other materials for achieving ohmic contact between the channel structure and the bit line.

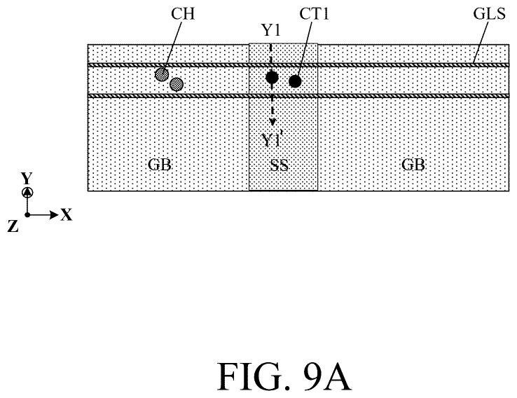

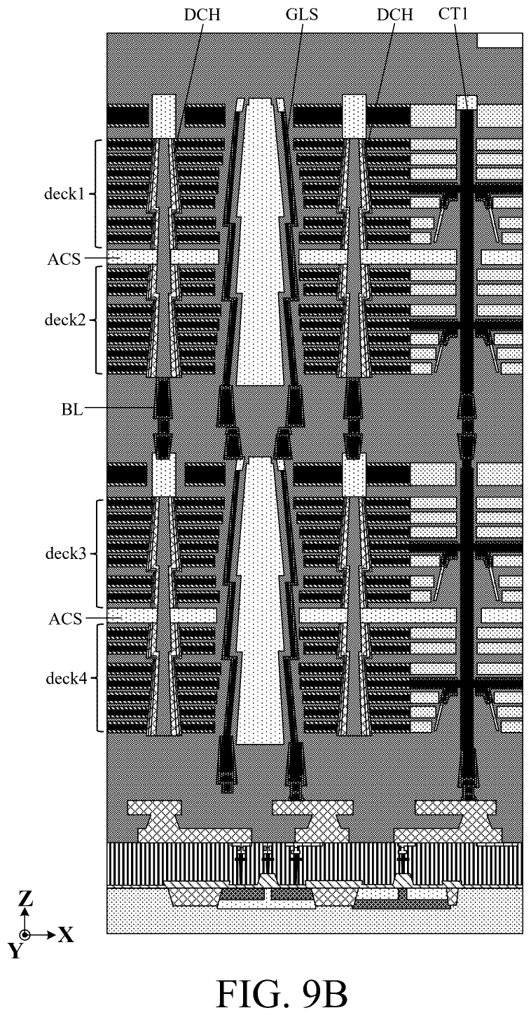

In some examples, as shown in FIG. 9A to FIG. 9B, the memory device further includes a plurality of second deck structures and a plurality of third deck structures in addition to the first deck structures, the second deck structure and the third deck structure are arranged along the Y-axis direction and are both located in the connection region SS, the third deck structure includes a third conductive layer and a third dielectric layer that are stacked alternately, and the second deck structure includes an isolation layer and a second dielectric layer that are stacked alternately; where the first conductive layer, the second conductive layer, and the isolation layer are in the same layer, and the first dielectric layer, the second dielectric layer, and the third dielectric layer are in the same layer. The memory device may further include a gate slit structure GLS extending along the X-axis direction, and the gate slit structure extends through the third deck structure along the Z-axis direction. The memory device may further include a dummy channel structure DCH located on both sides of the GLS, and the DCH may have the same material as the CH, or may have a different material, such as fully filled with dielectric layers.

In some implementations, as shown in FIG. 9A to FIG. 9B, the first conductive structure CT1 extending through each of the plurality of second deck structures may be connected with one first conductive layer of the plurality of first deck structures and connected with a third conductive layer of each of the plurality of third decks. In some implementations, the outer side of the first conductive structure CT1 is further arranged with an insulating dielectric, so that the first conductive structure CT1 is connected with one first conductive layer or one third conductive layer of the first deck structure or the third deck structure, and is isolated from other conductive layers of the first deck structure or the third deck structure.

An example of the present disclosure provides a memory device, including: a plurality of first deck structures stacked together, where the first deck structure includes first conductive layers and first dielectric layers arranged alternately along a first direction; a plurality of channel structures extending through the plurality of first deck structures; at least one semiconductor layer, where the semiconductor layer is connected with the channel structure in at least one of the plurality of first deck structures; and at least one second conductive layer, where one second conductive layer is located between two adjacent first deck structures and is connected with the channel structure in at least one of the plurality of first deck structures, and one semiconductor layer and one second conductive layer that are connected with the channel structure in the same first deck structure are arranged on two sides of the first deck structure respectively along the first direction.

Here, the first deck structure, the first conductive layer, the first dielectric layer, the channel structure, the semiconductor layer, and the second conductive layer may all be understood with reference to corresponding structures in the foregoing examples, and details will not described herein.

In some examples, the second conductive layer includes a plurality of bit lines spaced apart along the second direction and extending along the third direction; the second direction and the third direction intersect with each other and are both perpendicular to the first direction; and a plurality of second conductive structures extending along the first direction in the first deck structure are connected with one bit line of at least one second conductive layer.

In some examples, the second conductive structure includes a conductive pillar extending along the first direction.

Here, the second conductive layer may be understood as a bit-line layer, the bit-line layer may include a plurality of bit lines spaced apart along the X-axis direction and extending along the third direction, and the second conductive structure is a lead-out structure corresponding to the bit line. In some examples, the bit line lead-out structure may extend through one or more first deck structures of the bit line lead-out direction, e.g., the bit lines may be led out through a through-silicon contact (TSC). The TSC extends through the plurality of first deck layers, and is connected to a bit line BL of the common bit line region (the region between deck2 and deck3 as shown in FIG. 7B and FIG. 8B), e.g., the TSC extends through one or more first deck structures on the side from which the bit line is lead-out.

In some examples, different bit lines connected with different first deck structures through which the same channel structure extends are all connected with the same second conductive structure.

Here, the same channel structure may be understood as the channel structure extending through all the first deck structures along the first direction, and the different bit lines connected with the same channel structure are all connected with the same second conductive structure, which may be applicable to the Y-axis direction folding and the X-Y axis folding architecture of the memory devices related to FIG. 2B and FIG. 2D, and will be further illustrated in the following examples.

In some examples, at least one of the plurality of second conductive layers is located between two adjacent first deck structures and is connected with the channel structure of each of the two adjacent first deck structures.

In the example of the present disclosure, when the bit lines BL in different first deck structures are interconnected, the bit-line layers between two adjacent first deck structures may be shared.

In some examples, the memory device further includes a peripheral circuit; the peripheral circuit includes a page buffer; and the plurality of second conductive structures are connected to the same page buffer PB.

In the example of the present disclosure, when different bit lines connected with different first deck structures through which the same channel structure extends are all connected with the same second conductive structure, bit lines of different decks are each led out to the same page buffer, and a plurality of second conductive structures in the memory device architecture folding along the Y-axis direction in FIG. 2B may be connected to the same page buffer PB.

In some examples, different bit lines connected with different first deck structures through which the same channel structure extends are connected with different second conductive structures.

Here, the same channel structure may be understood as the channel structures extending through all the first deck structures along the first direction, and different bit lines connected with the same channel structure are all connected with different second conductive structures, which may be applicable to the array Y-axis direction folding architecture and the memory plane combination architecture shown in FIG. 2C and FIG. 2E, and will be further illustrated in the following examples.

In some examples, the second conductive layers corresponding to different first deck structures have different sizes along the third direction; and different second conductive structures connected with the second conductive layers corresponding to different first deck structures are arranged in sequence along the third direction.

In the example of the present disclosure, when the bit lines BL in different first deck structures are led out separately, different second conductive structures connected with the second conductive layers corresponding to different first deck structures are arranged in sequence along the third direction (e.g., the bit line extending direction). That is, the regions where the plurality of second conductive structures corresponding to each of the plurality of first deck structures along the first direction are arranged are arranged in sequence along the third direction.

In some examples, the memory device further includes a peripheral circuit; the peripheral circuit includes a plurality of page buffers; the second conductive structures connected with the bit lines of the same second conductive layer are connected with the same page buffer of the plurality of page buffers; and the second conductive structures connected with the bit lines of different second conductive layers are connected with different page buffers of the plurality of page buffers.

In some examples, along the first direction, the region where the page buffer is arranged is aligned with the region where the plurality of first deck structures are arranged.

In the example of the present disclosure, when different bit lines connected with different first deck structures through which the same channel structure extends are all connected with the same second conductive structure, bit lines of different decks are led to different page buffers respectively, and a plurality of second conductive structures in the array X-axis direction folding architecture shown in FIG. 2C may be connected with different PBs. In this case, the number of PBs may be the same as the number of decks, and the bit lines of the same deck structure are led out to the same page buffer PB.

In some examples, the plurality of first deck structures are all arranged in a first region, the plurality of second conductive structures are all arranged in a third region, and the third region is located on at least one of two sides of the first region along the third direction.

In the example of the present disclosure, the region where the first deck structure is arranged is the first region, the region where the second conductive structure (e.g., the bit line lead-out structure) is located is the third region, the region where the first conductive structure (e.g., the word line lead-out structure) is located is the second region, the second region and the third region are located at different sides of the first region respectively; and in an example, the second region is located on at least one of two sides of the first region along the second direction, and the third region is located on at least one of two sides of the first region along the third direction.

It can be understood that, for the array Y-axis direction folding architecture shown in FIG. 2B, compared with the unfolding memory device architecture shown in FIG. 2A, the number of BLs remains the same (for example, the number of BLs is 130K to 160K), but the number of SDs is reduced. For the array X-axis direction folding architecture shown in FIG. 2C, compared with the unfolding memory device architecture shown in FIG. 2A, the number of BLs becomes 1/N (for example, the number of BLs is (130K−160K)/N, where N is the number of decks). For the array X-axis+Y-axis direction folding structure shown in FIG. 2D, the number of BLs is the same as the number of BLs in the array X-axis direction folding structure shown in FIG. 2C, but for the two architectures, the lead-out structures corresponding to the bit lines are different from the lead-out structures corresponding to the top select gate layers.

In some examples, the plurality of first deck structures stacked together constitute one memory module; the memory device includes at least two memory modules; two memory modules of at least two memory modules are stacked together along the first direction; the memory device further includes a fourth conductive structure; different bit lines corresponding to different first deck structures through which the same channel structure extends are all connected with different second conductive structures; and the plurality of second conductive structures corresponding to the first deck structures specified in different memory modules through which the same channel structure extends are connected with each other through the fourth conductive structure.

Here, Regarding the memory module, reference may be made to the description about the memory module in FIG. 2D. In the example of the present disclosure, in the same memory module, a channel structure is led out from corresponding different bit lines in different decks respectively, and in different memory modules, a channel structure is led out altogether from corresponding different bit lines in a specified deck.

Here, the specified deck is related to the folding rule. Taking first the X-axis direction folding and then the Y-axis direction folding as an example, referring to the left half part of FIG. 3C, in the Model1 and the Model2, a channel structure is led out from corresponding different bit lines in different decks respectively, a deck corresponding to a first one on the left in the Model1 and a deck corresponding to a first one on the left in the Model2 are two decks led out from the specified bit line, a deck corresponding to a second one on the left in the Model1 and a deck corresponding to a second one on the left in the Model2 are two decks led out from the specified bit line, a deck corresponding to a third one on the left in the Model1 and a deck corresponding to a third one on the left in the Model2 are two decks led out from the specified bit line, and a deck corresponding to a fourth one on the left in the Model1 and a deck corresponding to a fourth one on the left in the Model2 are two decks led out from the specified bit line.

In the example of the present disclosure, the second conductive structures of the two decks led out from the specified bit line are connected through the fourth conductive structure, and the fourth conductive structure is on either side of two sides of the plurality of first deck structures along the first direction.

In some examples, at least one of the plurality of semiconductor layers is located between two adjacent first deck structures and is connected with the channel structure of each of the two adjacent first deck structures.

In some examples, the two adjacent first deck structures of the plurality of first deck structures form a deck group; the memory device includes a plurality of semiconductor layers; the plurality of semiconductor layers are located between the two adjacent first deck structures of the deck group, respectively; and the plurality of semiconductor layers are connected with each other.

Here, the semiconductor layer may be understood with reference to the structure features of the semiconductor layer in the foregoing examples, and details will not described herein.

In some examples, the memory device further includes a first conductive structure extending along the first direction and connected with one first conductive layer of each of at least two first deck structures of the plurality of first deck structures.

Here, the first conductive structure may be understood with reference to the structure features of the first conductive structure in the foregoing examples, and details will not described herein.

In some examples, the memory device further includes a third conductive structure; the first conductive layers in the first deck structure include a top select gate layer and a gate layer; the top select gate layer is located at one end of two ends of a corresponding first deck structure along the first direction away from the semiconductor layer connected with the channel structure in the corresponding first deck structure; the third conductive structure extends along the first direction in the first deck structure and is connected with the top select gate layer included in at least one of the plurality of first deck structures; and the first conductive structure is connected with one gate layer of each of at least two first deck structures of the plurality of first deck structures.

Here, the third conductive structure is a lead-out structure corresponding to the top select gate layer, and the structural form of the third conductive structure and the position where the third conductive structure is arranged will be further described below.

An example of the present disclosure further provides a memory device, including: a plurality of first deck structures stacked together, where the first deck structure includes first conductive layers and first dielectric layers arranged alternately along a first direction; the first conductive layers in the first deck structure include a top select gate layer and a gate layer; the top select gate layer is located at one end of two ends of a corresponding first deck structure along the first direction away from a semiconductor layer connected with a channel structure in the corresponding first deck structure; a plurality of channel structures extending through the plurality of first deck structures; at least one semiconductor layer, where one semiconductor layer is connected with the channel structure in at least one of the plurality of first deck structures; and third conductive structures extending along the first direction in the first deck structure and connected with the top select gate layer included in at least one of the plurality of first deck structures.

Here, the first deck structure, the first conductive layer, the first dielectric layer, the channel structure, and the semiconductor layer may all be understood with reference to corresponding structures in the foregoing examples, and details will not described herein.

In the example of the present disclosure, the third conductive structure is a lead-out structure corresponding to the top select gate layer, and the top select gate layer in the first deck structure may include one or more layers, and when a plurality of layers are included, the plurality of layers may be led out together or may be led out separately. In the example of the present disclosure, the third conductive structure extends through the plurality of first deck structures, and the third conductive structure is at least electrically connected with the TSG layer of one deck.

In some examples, the memory device further includes a top select gate isolation structure, where the top select gate isolation structure divides the top select gate layer into a plurality of top select gate sub-layers; and different top select gate sub-layers included in the same top select gate layer are connected with different third conductive structures.

Here, the top select gate isolation structure TSGCUT has a similar extending direction with the gate slit structure GLS shown in FIG. 9A and FIG. 9B, except that the GLS extends through all the first conductive layers of all the first deck structures and the top isolation structure extends through a portion of the first conductive layer of each first deck structure. More specifically, the top isolation structure extends through the top select gate layer in the first conductive layer of each first deck structure. For example, the top select gate layer includes one or three layers.

In the example of the present disclosure, the top select gate isolation structure divides the top select gate layer into a plurality of top select gate sub-layers, and the channel structure corresponding to each top select gate sub-layer forms one string. Different top select gate sub-layers connected with different strings are connected with different third conductive structures.

It should be noted that both the bit line and the top select gate layer are connected with the channel structure, and can achieve the selecting and unselecting of the connected channel structure. The difference between them is that: the bit line extends along the third direction and is connected with one channel structure column, and the channel structure column includes a plurality of channel structures arranged along the third direction; the top select gate is connected with the plurality of channel structure rows, and each channel structure row includes a plurality of channel structures arranged along the second direction. Based on that, both the bit line and the top select gate layer have a selecting function for the channel structure; in order to save the layout area of the lead-out structures corresponding to the bit line and the top select gate layer, the lead-out structures corresponding to the bit line and the top select gate layer may have a comprehensive arrangement under different memory architectures.

It should be noted that the top select gate layer is configured to select the string, and the bottom select gate layer may actually have the same function. In view of this, the top select gate layer in this example of the present disclosure may be replaced with the bottom select gate layer on without conflict. In some examples, different top select gate layers included in different first deck structures are connected with different third conductive structures. In the example of the present disclosure, the top select gate layers of different decks are led out separately. It should be noted that, for the foregoing architectures of the four memory devices, top select gate layers of different decks may be led out separately. The lead-out structures corresponding to the bit lines of different decks are connected together, and the array Y-axis direction folding architecture shown in FIG. 2B has to lead out top select gate layers of different decks respectively, so as to select and deselect the sub-channel structures in different decks respectively. Here, the number of the first deck structures is N, and the channel structure includes N sub-channel structures corresponding to the N first deck structures.

In some examples, the memory device further includes a plurality of second conductive layers and a plurality of second conductive structures; one second conductive layer is connected with the channel structure of at least one of the plurality of first deck structures; the second conductive layer includes a plurality of bit lines, and each bit line is connected with all channel structures of a column of the channel structures; and the second conductive structures extend along the first direction in the first deck structure and are connected with one bit line of at least one second conductive layer.

Here, the second conductive layer may be understood as a bit-line layer, the bit-line layer may include a plurality of bit lines spaced apart along the X axis direction and extending along the third direction, and the second conductive structure is a lead-out structure corresponding to the bit line. Regarding features of the second conductive layer and the second conductive structure, reference may be made to the description in the foregoing examples, and details will not described herein.

In some examples, different bit lines corresponding to different first deck structures through which the same channel structure extends are all connected with different second conductive structures; and different top select gate layers included in different first deck structures are connected with the same third conductive structure.

In the example of the present disclosure, when the bit lines of different deck structures are led out separately (as described above in the array X-axis direction folding structure shown in FIG. 2C), the top select gate layers of different decks may be led out together. As such, the separate selection and deselection of the sub-channel structures in different decks can be achieved, and the layout area of the corresponding lead-out structure of the top select gate layer can be saved compared with the separate lead-out of the top select gate layers of different decks.

In some examples, the plurality of first deck structures stacked together constitute one memory plane; the memory device includes at least two memory planes; two memory planes of at least two memory modules are arranged in parallel along a second direction; the second direction is perpendicular to the first direction; the memory device further includes first conductive structures; the first conductive structure is located between the two memory planes, and the first conductive structure is connected with one gate layer of each of different first deck structures in at least one memory plane.

In the example of the present disclosure, the first conductive structure is located between the two memory planes, but whether the two memory planes share the first conductive structure is not limited, e.g., one first conductive structure may be connected with the first conductive layer of each of different decks of one memory plane, and one first conductive structure may also be connected with the first conductive layer of each of different decks of each memory plane of the two parallel memory planes.

In some examples, the memory device further includes a peripheral circuit; the peripheral circuit includes a plurality of string drivers; and the first conductive layers at the same position along the stacking direction in different memory planes are connected with each other and connected with the same one of the string drivers.

Here, Regarding the memory plane, reference may be made to the description about the memory plane in FIG. 2E. The first conductive layers at the same positions along the first direction in different memory planes may be understood as the first conductive layers in the same layer in different memory planes. The first conductive layers in the same layer are connected with the same first conductive structure and are connected with the same SD through the same first conductive structure.

In some examples, different bit lines corresponding to different first deck structures through which the same channel structure extends are all connected with different second conductive structures; different top select gate layers included in different first deck structures of the same memory plane are connected with the same third conductive structure; and different top select gate layers included in the first deck structures of different memory planes at the same position in the first direction are connected with different third conductive structures.

In the examples of the present disclosure, the top select gate layers of different decks in the same memory plane are led out together; the top select gate layers of different memory planes are led out separately, and the top select gate layers of different memory planes in the same layer are also led out separately.

It should be noted that the lead-out scheme of the bit line and the top select gate layer is applicable to the array X-axis direction folding structure adopted in each memory plane. When the array Y-axis direction folding architecture is adopted in each memory plane, top select gate layers of different decks in the same memory plane are led out separately; and top select gate layers of different memory planes are also led out separately.

In some examples, the plurality of first deck structures stacked together form one memory module; the memory device includes at least two memory modules; the at least two first memory modules are stacked together along the first direction; the memory device further includes first conductive structures; and the first conductive structures are connected with one gate layer of each deck structure of the two memory modules.

Here, Regarding the memory module, reference may be made to the description about the memory module in FIG. 2D. The first conductive structure may be understood with reference to the structure features of the first conductive structure in the foregoing examples, and details will not described herein.

In some examples, the memory device further includes a fourth conductive structure; different bit lines corresponding to different first deck structures through which the same channel structure extends in the same memory module are all connected with different second conductive structures; two bit lines corresponding to two first deck structures specified in different memory modules are connected with each other through the fourth conductive structure; different top select gate layers included in different first deck structures in the same memory module are connected with the same third conductive structure; and two top select gate layers included in two first deck structures in different memory modules are connected with different third conductive structures.

The example of the present disclosure the array architecture of first folding in the X-axis direction and then folding in the Y-axis direction mentioned above. In the same memory module, channel structures are led out separately from corresponding different bit lines in different decks and are led out together from corresponding different top select gate layers in different decks; in different memory modules, channel structures are led out together from corresponding different bit lines in different decks and are led out separately from corresponding different top select gate layers in different decks.

Here, the specified deck is related to the folding rule. Taking first the X-axis direction folding and then the Y-axis direction folding as an example, referring to the left half part of FIG. 3C, in the Model1 and the Model2, a channel structure is led out from corresponding different bit lines in different decks respectively, a deck corresponding to a first one on the left in the Model1 and a deck corresponding to a first one on the left in the Model2 are two decks led out together from the specified bit line, a deck corresponding to a second one on the left in the Model1 and a deck corresponding to a second one on the left in the Model2 are two decks led out together from the specified bit line, a deck corresponding to a third one on the left in the Model1 and a deck corresponding to a third one on the left in the Model2 are two decks led out together from the specified bit line, and a deck corresponding to a fourth one on the left in the Model1 and a deck corresponding to a fourth one on the left in the Model2 are two decks led out together from the specified bit line.

In some examples, the fourth conductive structure is located on one side of two sides of the region where the second conductive structure is located along the first direction; and two second conductive structures corresponding to two first deck structures specified in different memory modules are connected with each other through the fourth conductive structure.

In the example of the present disclosure, the second conductive structures of the two decks led out together by the specified bit line are connected through the fourth conductive structure, and the fourth conductive structure is on either side of two sides of the plurality of first deck structures along the first direction.

In some examples, different bit lines corresponding to different first deck structures through which the same channel structure extends in the same memory module are all connected with the same second conductive structure; different bit lines corresponding to two first deck structures in different memory modules are all connected with different second conductive structures; different top select gate layers included in different first deck structures in the same memory module are connected with different third conductive structures; and two top select gate layers included in two first deck structures in different memory modules are connected with the same third conductive structure.

The example of the present disclosure is applicable to the array architecture of first folding in the Y-axis direction and then folding in the X-axis direction mentioned above. In the same memory module, channel structures are led out together from corresponding different bit lines in different decks and are led out separately from corresponding different top select gate layers in different decks; in different memory modules, a channel structure are led out separately from corresponding different bit lines in different decks and are led out together from corresponding different top select gate layers in different decks.

It should be noted that, Regarding the array architecture of the X direction+Y direction folding, since the two folding methods of first the X-axis direction folding and then the Y-axis direction folding, and since first the Y-axis direction folding and then the X-axis direction folding are different, the lead-out method of the corresponding bit lines and the top select gate layer are not the same either, and the lead-out methods of the bit lines and the top select gate layers are related to the folding rule. In an example, when folded in the X-axis direction, the number of bit lines of each deck structure after folding is unchanged as compared to the number of bit lines of each deck structure before folding; in this case, the bit lines of channel structures in different decks need to be led out separately, and the top select gate layers of different deck structures may be led out separately; and when folded in the Y-axis direction, the number of bit lines of each deck structure after folding is changed to 1/N (N is the number of decks) as compared to the number of bit lines of each deck structure before folding; in this case, the bit lines of channel structure in different decks need to be led out together, and the top select gate layers of different decks may be led out separately.

In some examples, the plurality of first deck structures are arranged in a first region, the first conductive structures are all arranged in a second region, the third conductive structures are all arranged in a fourth region, and the fourth region is located between the first region and the second region.

Here, the first region and the second region may be understood with reference to the first region and the second region in the foregoing examples, the fourth region where the third conductive structure (e.g., the top select gate layer) is located between the first region and the second region. In some implementations, if the second region is located in the middle of the first region, the fourth region may be divided into two parts, and the two parts are located at two sides of the second region along the second direction and close to the second region.

In some examples, the third conductive structure includes a second lead-out portion, a second connection portion and a contact portion; the second lead-out portion extends along the first direction and is connected with the second connection portion; the second connection portion extends along a direction perpendicular to the first direction and is connected with the contact portion; and the contact portion extends along the first direction and is connected with the top select gate layer.

Here, the third conductive structure is a lead-out structure corresponding to the top select gate layer, and the structural form of the third conductive structure will be further described below.

In some examples, each first deck structure includes a plurality of top select gate layers; a cross-sectional shape of the plurality of top select gate layers along the first direction includes a step-like shape; each step in the step-like shape corresponds to one top select gate layer; and one contact portion is connected to a step where one top select gate layer is located.

In the example of the present disclosure, the top select gate layer of each first deck structure includes a plurality of layers, and if the voltage strategies applied to the plurality of layers are the same, the plurality of layers may be led out together; and if the voltage strategies applied to the plurality of layers are different, the multiple layers may be led out separately. In an implementation, the plurality of layers may form a stair structure, the stair structure is in step shape, each step includes one top select gate layer, and the third conductive structure may be connected to each step.

In some examples, a semiconductor layer in at least one semiconductor layer is located between two adjacent first deck structures and is connected with the channel structure in each of the two adjacent first deck structures.

Here, the semiconductor layer may be understood with reference to the structure features of the semiconductor layer in the foregoing examples, and details will not described herein.

In some examples, the memory device further includes a first conductive structure; the first conductive structure extends along the first direction and is connected with one gate layer of each of at least two first deck structures of the plurality of first deck structures.

Here, the first conductive structure may be understood with reference to the structure features of the first conductive structure in the foregoing examples, and details will not described herein.

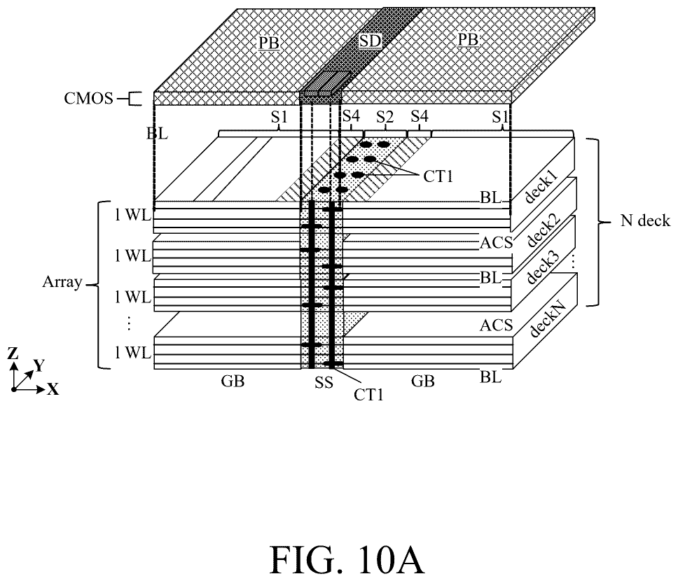

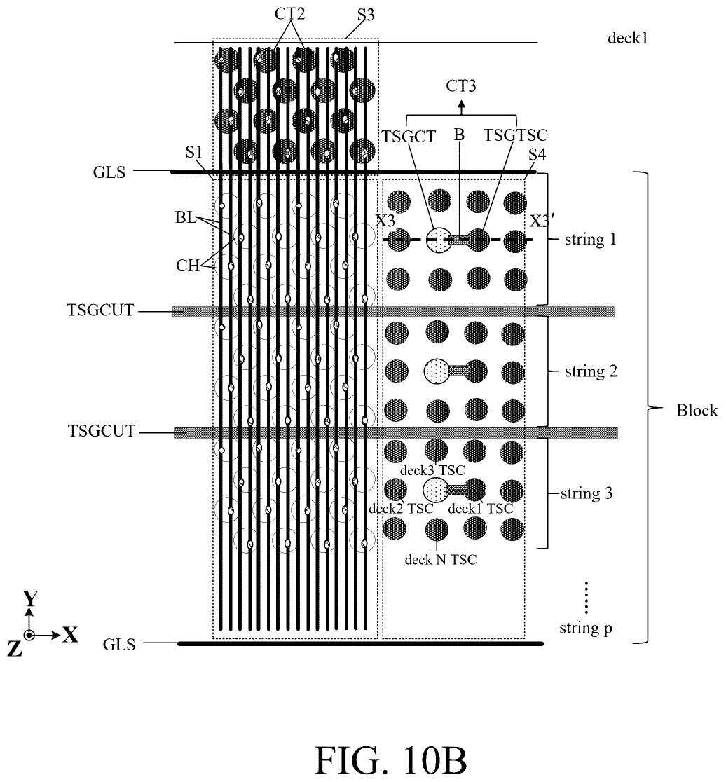

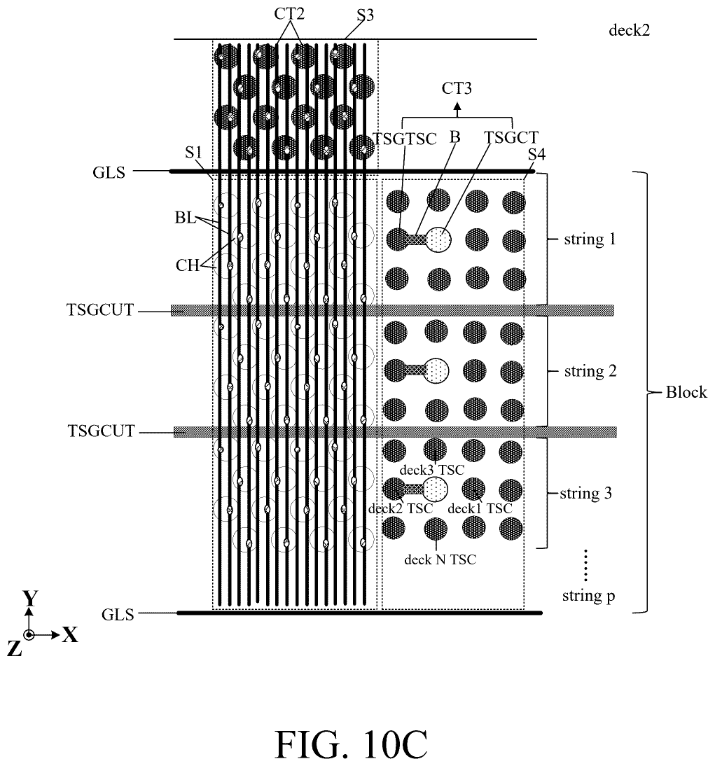

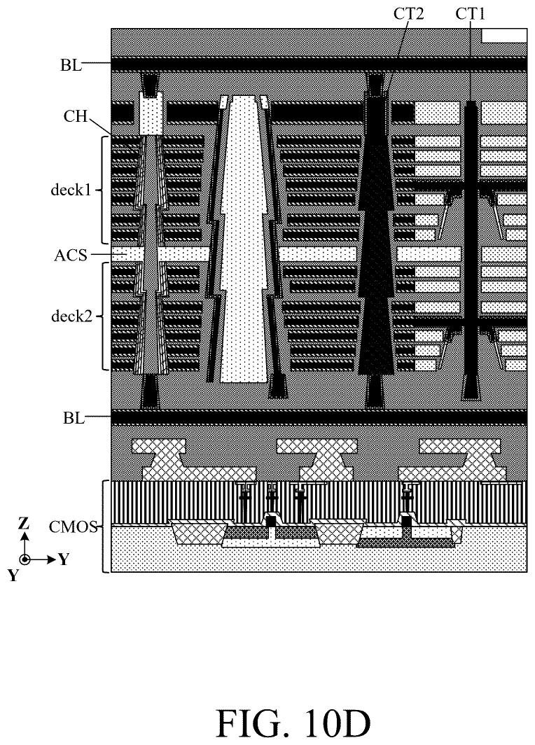

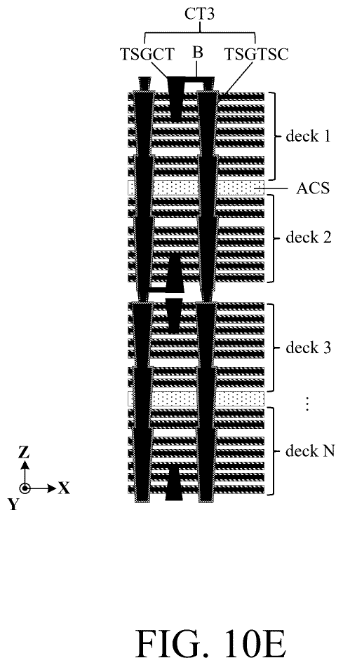

FIG. 10A is a first schematic diagram of a layout including an array of a memory device and a peripheral circuit provided by an example of the present disclosure; FIG. 10B is a first schematic top view including a lead-out structure of BL and TSG of deck1 of a memory device provided by an example of the present disclosure; FIG. 10C is a first schematic top view including a lead-out structure of BL and TSG of deck2 of a memory device provided by an example of the present disclosure; FIG. 10D is a first schematic cross-sectional view including a lead-out structure of a BL of a memory device provided by an example of the present disclosure; FIG. 10E is a first schematic cross-sectional view including a lead-out structure of a TSG of a memory device provided by an example of the present disclosure.

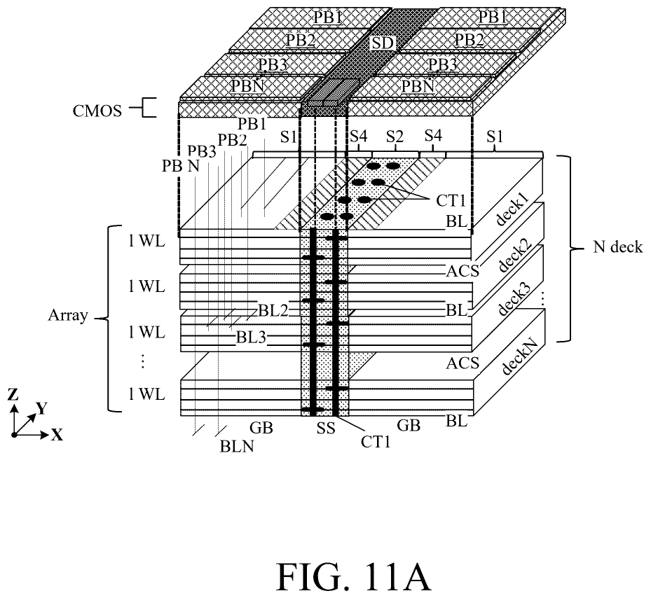

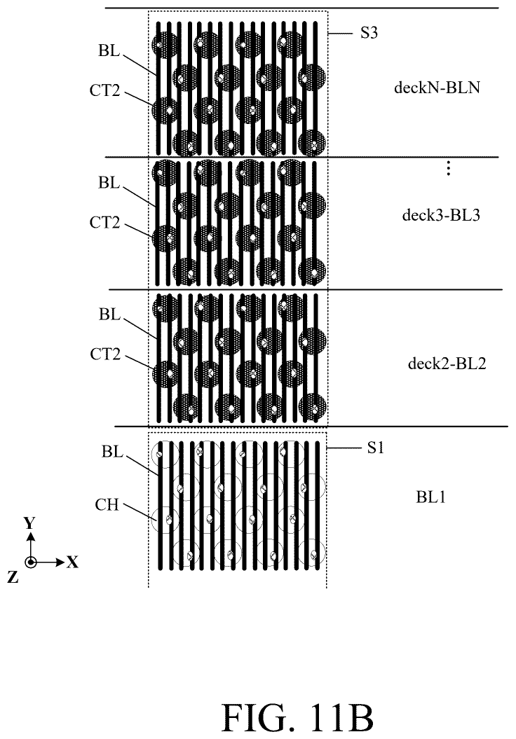

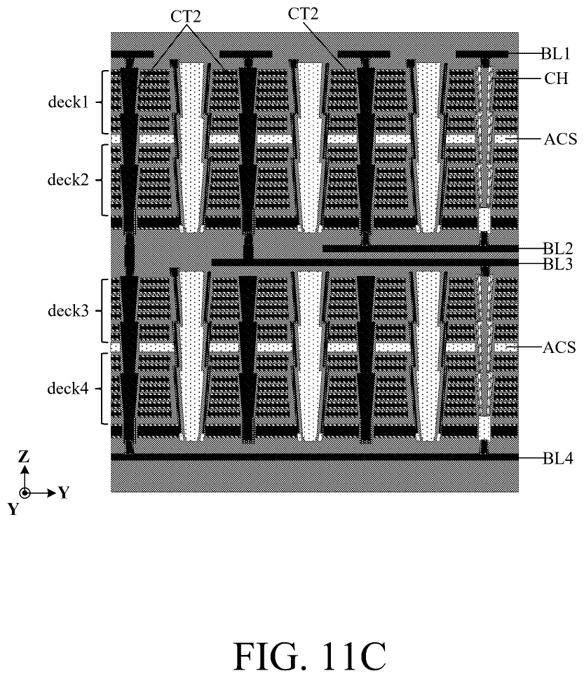

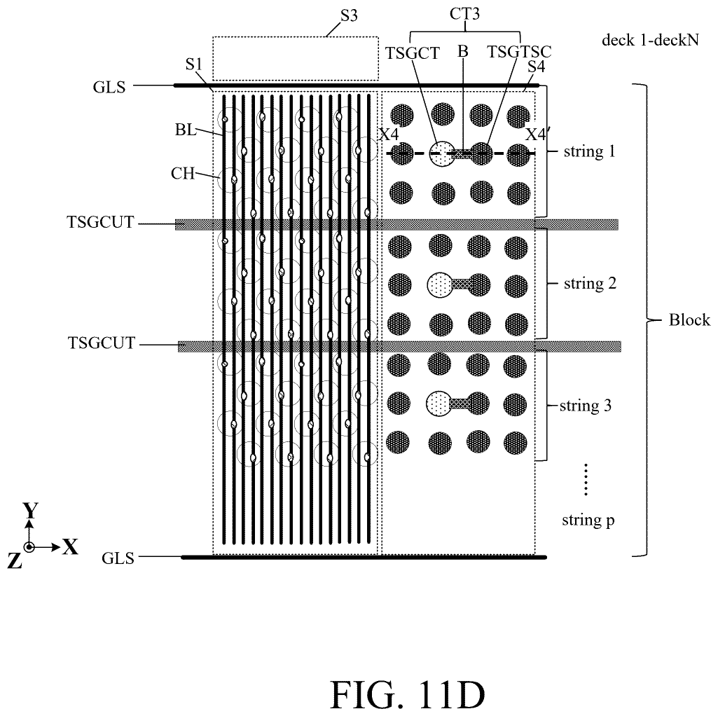

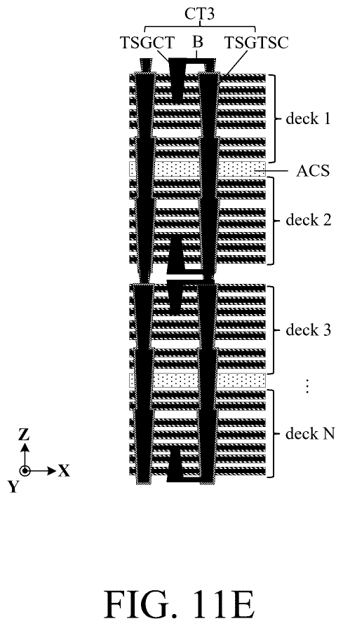

FIG. 11A is a second schematic diagram of a layout including an array of a memory device and a peripheral circuit provided by an example of the present disclosure; FIG. 11B is a second schematic top view including lead-out structures of BLs of decks of a memory device provided by an example of the present disclosure; FIG. 11C is a second schematic top view including lead-out structures of BLs of decks of a memory device provided by an example of the present disclosure; FIG. 11D is a second schematic cross-sectional view including lead-out structures of TSGs of decks of a memory device provided by an example of the present disclosure; FIG. 11E is a second schematic cross-sectional view including lead-out structures of TSGs of decks of a memory device provided by an example of the present disclosure.

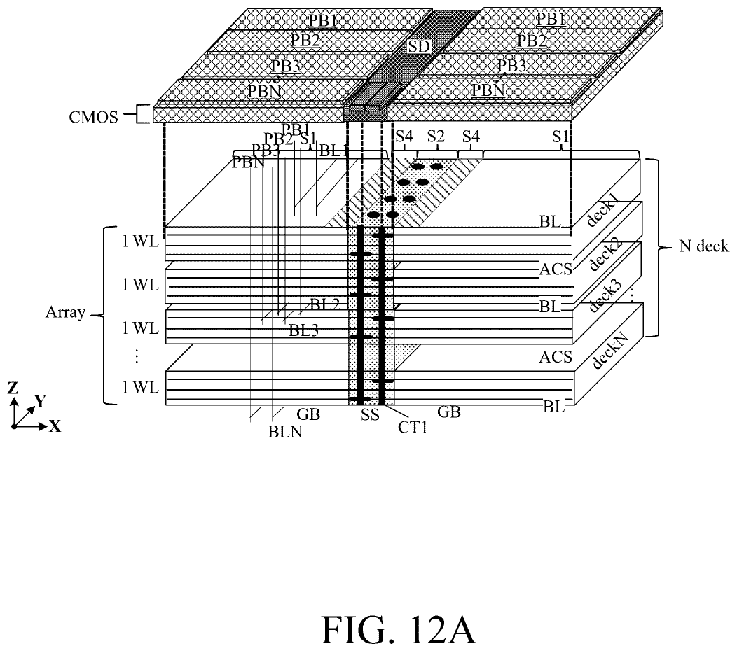

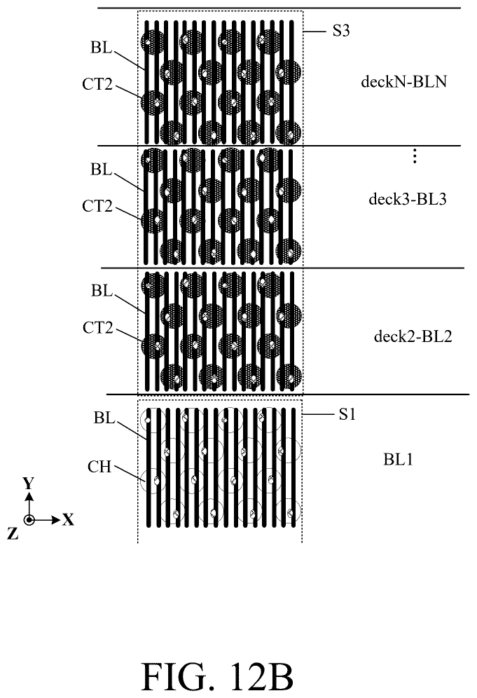

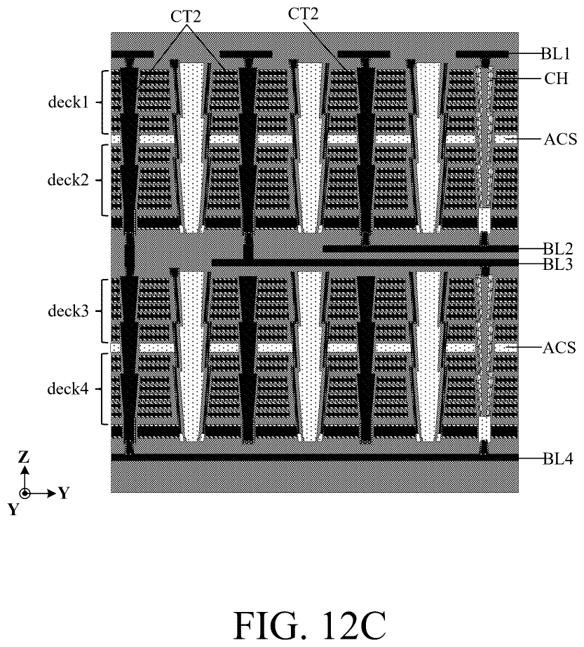

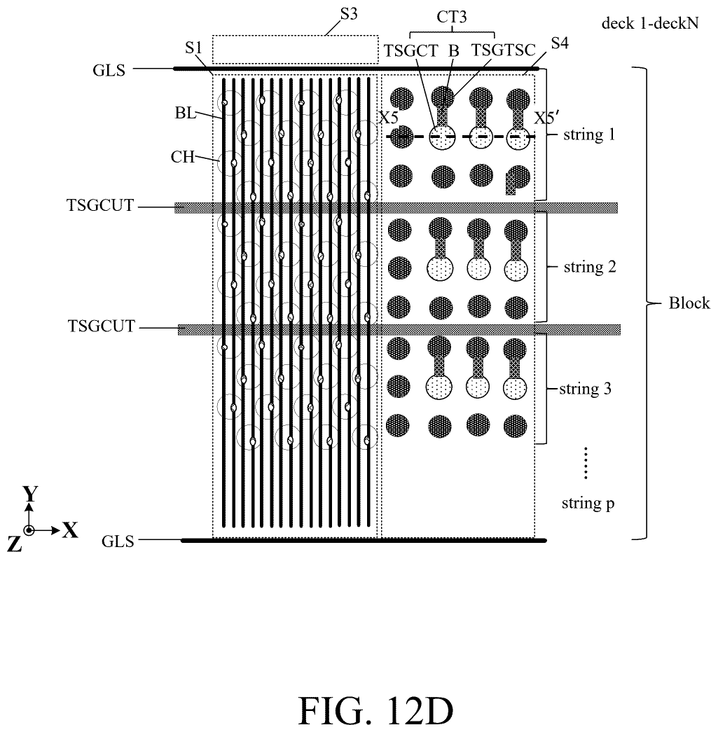

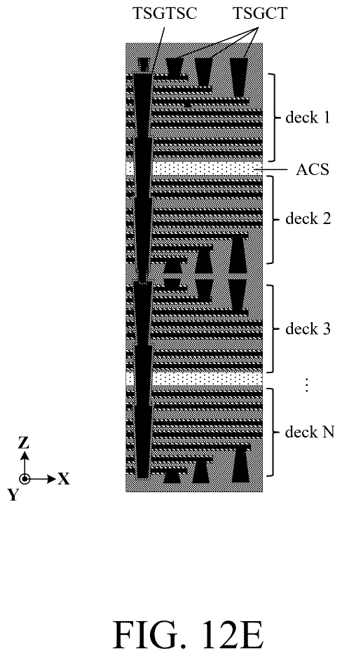

FIG. 12A is a third schematic diagram of a layout including an array of a memory device and a peripheral circuit provided by an example of the present disclosure; FIG. 12B is a third schematic top view including lead-out structures of BLs of decks of a memory device provided by an example of the present disclosure; FIG. 12C is a third schematic top view including lead-out structures of BLs of decks of a memory device provided by an example of the present disclosure; FIG. 12D is a third schematic cross-sectional view including lead-out structures of TSGs of decks of a memory device provided by an example of the present disclosure; FIG. 12E is a third schematic cross-sectional view including lead-out structures of TSGs of decks of a memory device provided by an example of the present disclosure.

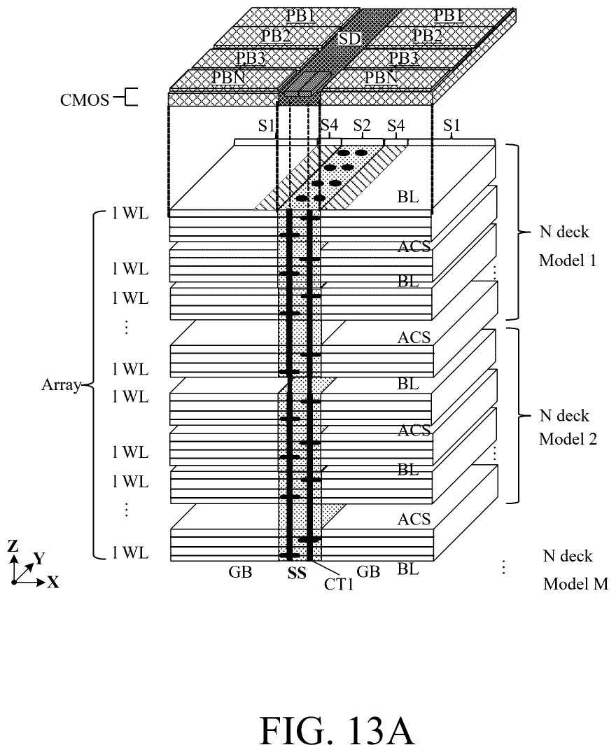

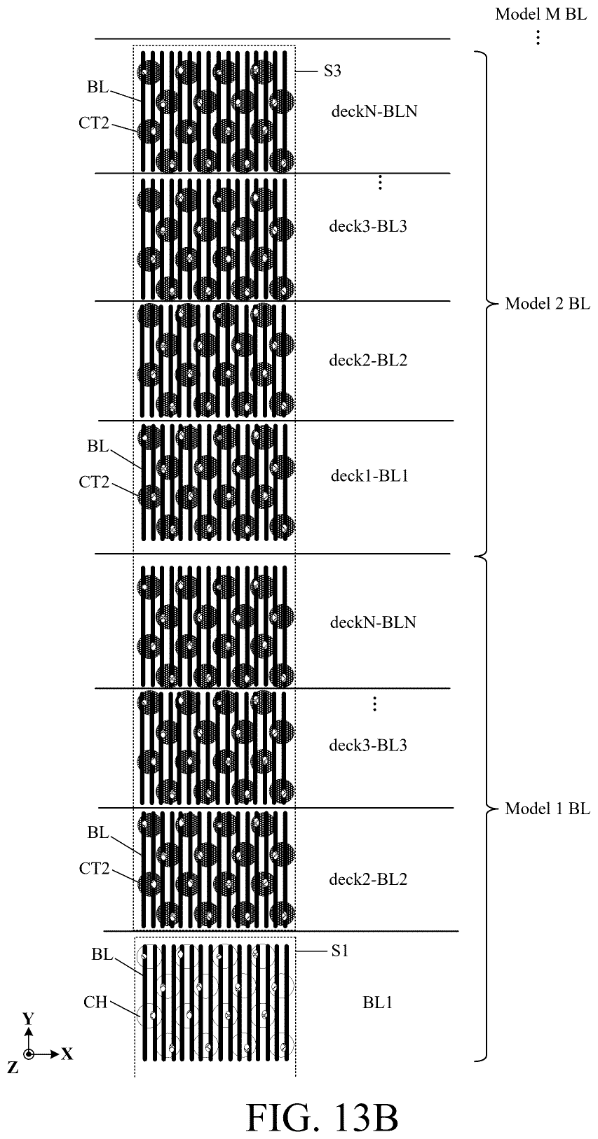

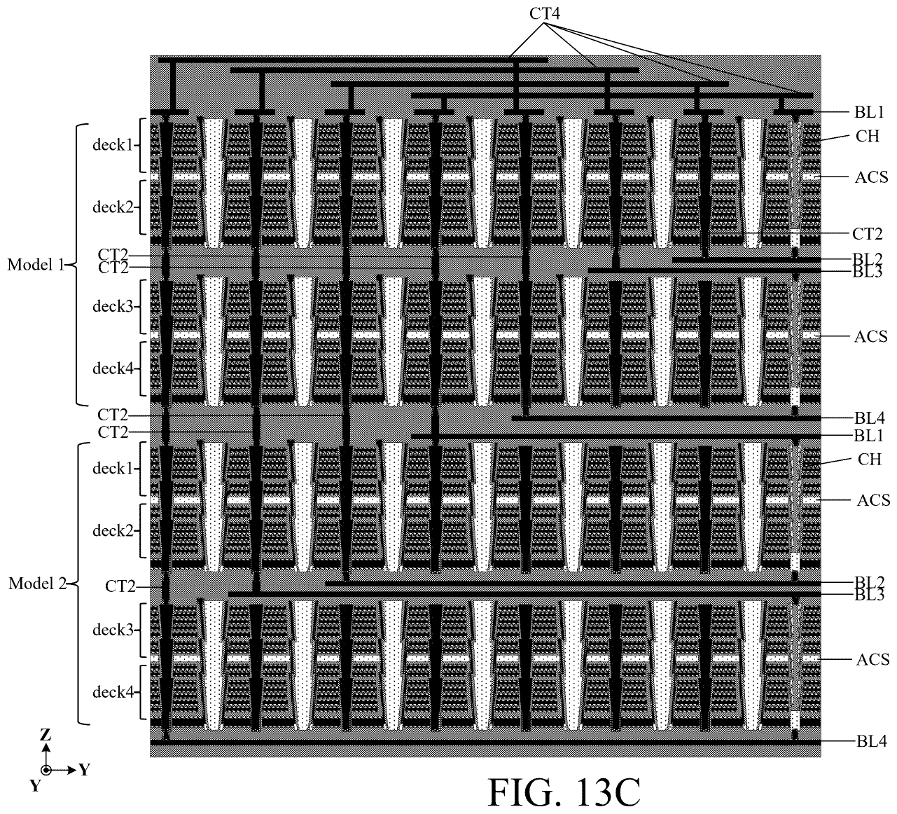

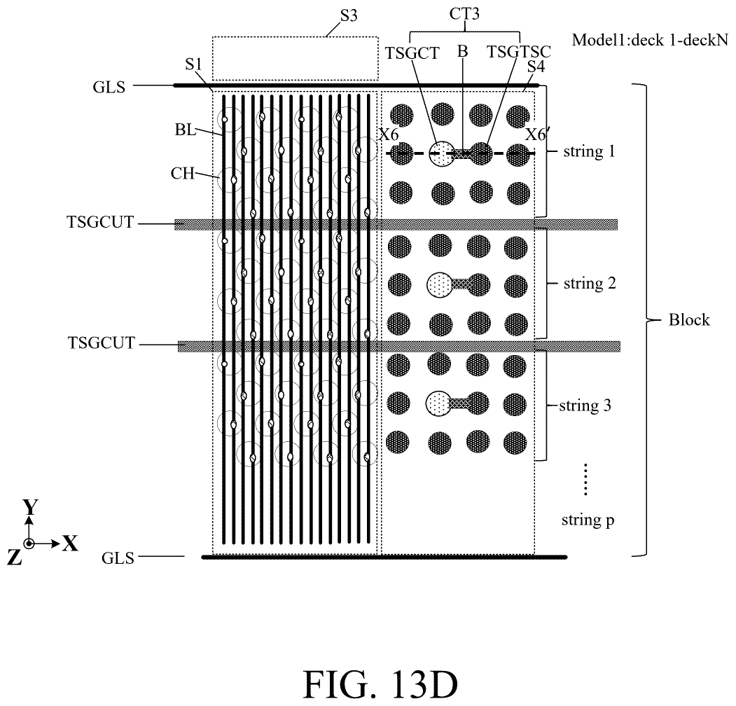

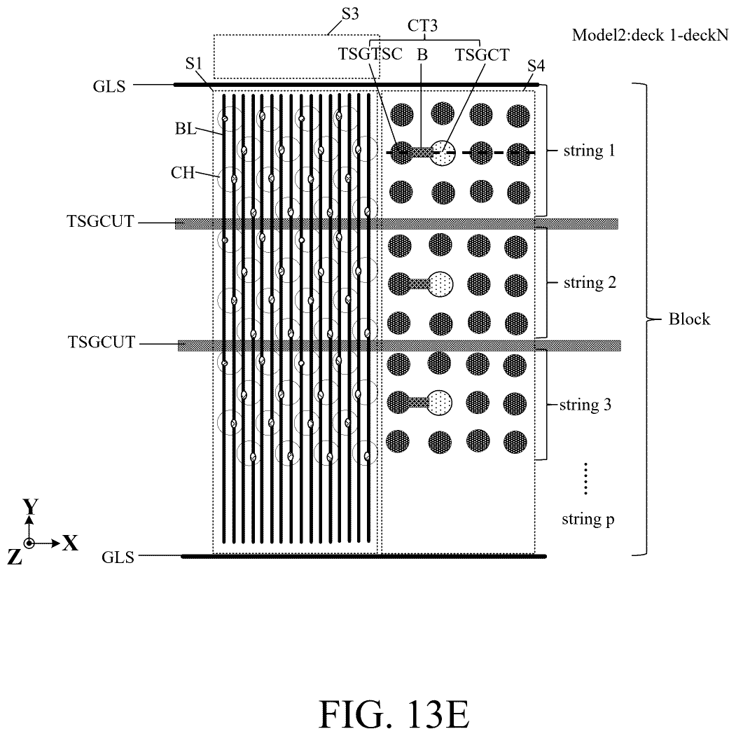

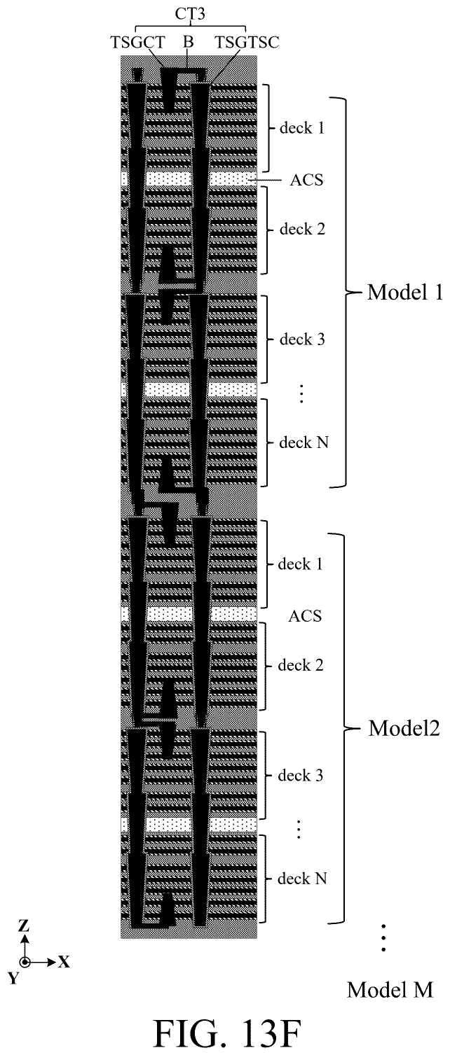

FIG. 13A is a fourth schematic diagram of a layout including an array of a memory device and a peripheral circuit provided by an example of the present disclosure; FIG. 13B is a fourth schematic top view including lead-out structures of BLs of decks of a memory device provided by an example of the present disclosure; FIG. 13C is a fourth schematic top view including lead-out structures of BLs of decks of a memory device provided by an example of the present disclosure; FIG. 13D is a fourth schematic top view including a lead-out structure of BL and TSG of Model1 of a memory device provided by an example of the present disclosure; FIG. 13E is a fifth schematic top view including a lead-out structure of BL and TSG of Model2 of a memory device provided by an example of the present disclosure; FIG. 13F is a fourth schematic cross-sectional view including a lead-out structures of TSGs of decks of a memory device provided by an example of the present disclosure.

Implementations of the lead-out structure (the second conductive structure) of the BL and the lead-out structure (the third conductive structure) of the top select gate layer TSG under different folding architecture are illustrated in detail below with reference to FIG. 10A to FIG. 10E, FIG. 11A to FIG. 11E, FIG. 12A to FIG. 12E, and FIG. 13A to FIG. 13F, respectively.

An example of the present disclosure provides a memory device. Regarding the foregoing array Y-axis direction folding architecture, as shown in FIG. 10A to FIG. 10E, in the example of the present disclosure, the original array is divided along the Y direction and then stacked, and the gate layer WL is shared to form a memory array including an array region GB and a connection region SS. In some implementations, along the X-axis direction, the connection region is located in the middle of the memory array, and the connection region is located between the two array regions (as shown in FIG. 10A). In some implementations, along the X direction, the connection region may be located at an edge of the array, and the connection region is located on a side of the array region, for example, located at a left edge or a right edge of the array structure.

In the example of the present disclosure, the array may include a plurality of first conductive structures CT1, the first conductive structures CT1 may be located in the connection region, e.g., the second region S2; and each deck structure may have one gate layer WL, which may be commonly connected to one first conductive structure CT1. The second region S2 may include or may not include a stair structure; or the second region S2 may include other connection structures that may lead out the gate layer WL.

In the example of the present disclosure, the memory device further includes a peripheral circuit CMOS, and the array and the CMOS may be bonded or otherwise combined. The peripheral circuit may include a string driver (SD) and a page buffer (PB); where there may be a plurality of SDs, and each SD is a small cuboid in FIG. 10A (two SDs are shown in FIG. 10A). Each of the first conductive structures CT1 may be correspondingly connected with one SD, the region where the SD is arranged may be located directly above the connection region SS, and the region where the PB is arranged may be located above the array region GB, thereby reducing the winding and reducing the manufacturing difficulty of the process.

In the example of the present disclosure, the array includes a memory block, the memory block includes a plurality of first deck structures (N decks are shown in FIG. 10A, e.g., deck1-deckN) stacked along a Z-axis direction, each of the first deck structures includes a top select gate layer TSG, the structure includes at least one top select gate isolation structure TSG CUT extending along the X direction, the TSG CUT extends through the top select gate layer TSG along the Z-axis direction, the TSG is divided into a plurality of top select gate sub-layers, and each top select gate layer corresponds to one string (P strings are shown in FIG. 10B and FIG. 10C, e.g., string1-stringP). The material of the TSG CUT includes, but is not limited to, silicon oxide.

In the example of the present disclosure, as shown in FIG. 10B and FIG. 10C, the memory device includes a plurality of bit lines BL extending along the Y-axis direction and spaced apart along the X-axis direction, and each bit line BL is connected with each channel structure in one column of channel structures CH. The lead-out structure corresponding to the bit line, e.g., the second conductive structure CT2, is arranged in the third region S3, each bit line extends further along the extending direction of the bit line, and the further extended portion is connected with the second conductive structure CT2. In the example of the present disclosure, channel structures are led out together from different bit lines connected in different decks, e.g., connected to a page buffer PB in a peripheral circuit through the same second conductive structure. In the example of the present disclosure, a memory block may include a page buffer PB.

In the example of the present disclosure, as shown in FIG. 10D, the second conductive structure CT2 connects different bit lines connected with a channel structure in different decks through conductive structures having a morphology similar to the channel structure, and connects the different bit lines to PB (a portion connected to PB is not shown in FIG. 10D). It should be noted that FIG. 10D only shows the case where the memory device includes two decks, and the case where the memory device includes a plurality of deck structures may be analogized according to the figure.

In the example of the present disclosure, as shown in FIG. 10B and FIG. 10C, the TSGs of different decks are led out through different third conductive structures CT3. The third conductive structure CT3 includes a second lead-out portion TSGTSC, a second connection portion B, and a contact portion TSGCT; the second lead-out portion TSGTSC extends along the Z-axis direction and is connected with the second connection portion B; the second connection portion B extends along a direction perpendicular to the Z-axis direction and is connected with the contact portion TSGCT; and the contact portion TSGCT extends along the Z-axis direction and is connected with the top select gate layer. The second lead-out portion TSGTSC extends through all the decks along the Z-axis direction, the TSGCTs of each deck structure may be aligned along the first direction, and projections of the TSGCTs of all the decks in the same string overlap in a plane perpendicular to the Z-axis direction. The TSGCT is connected with the second lead-out portion TSC through the conductive structure extending along the X-axis direction, and the TSGTSC connected with the TSGCT in different decks in the same string are the same. The materials of TSGT, B and TSGTSC include, but are not limited to, tungsten. The number of TSGTSCs is greater than or equal to the number of decks.

In the example of the present disclosure, as shown in FIG. 10B, taking deck1 as an example, deck1 may include a plurality of sub-TSGs, the plurality of sub-TSGs may be correspondingly connected with different TSGCTs, different TSGCTs are connected with the same TSGTSC, or may also be connected with different TSGTSCs (as shown in FIG. 10E, and FIG. 10E is a corresponding cross-sectional view at X3-X3′ in FIG. 10B). In other examples, deck1 further includes one TSG connected with the TSGCT, and the TSGCT is connected with the TSGTSC through the second connection portion B.

In the example of the present disclosure, as shown in FIG. 10C, taking deck2 as an example, deck2 may include a plurality of sub-TSGs, the plurality of sub-TSGs may also be correspondingly connected with different TSGCTs, different TSGCTs are connected with the same TSGTSC, or may also be connected with different TSGTSCs (as shown in FIG. 10E). In other examples, deck1 further includes one TSG connected with the TSGCT, and the TSGCT is connected with the TSGTSC through the second connection portion B.

It should be noted that, in FIG. 10B and FIG. 10C, the TSGT is connected with different TSGTSCs through a second connection portion B extending along the opposite direction (B is along the +X-axis in deck1, and B is along the −X-axis in deck2). It can be understood that for deck3, the TSGCT is connected with a different TSGTSC through a second connection portion B extending along the +Y-axis direction. The specific extending direction of the second connection portion B referred to above does not limit the extending direction of the second connection portion B in the example of the present disclosure, and is only used to describe that in different decks, the TSGCT may be connected to different TSGTSCs through the second connection portion B extending toward different directions.

An example of the present disclosure provides a memory device. Regarding the foregoing array X-axis direction folding architecture, as shown in FIG. 11A to FIG. 11E, in the example of the present disclosure, the original array is divided along the X direction and then stacked, and the gate layer WL is shared to form a memory array, the array includes an array region GB and a connection region SS. In some implementations, along the X-axis direction, the connection region is located in the middle of the memory array, and the connection region is located between the two array regions (as shown in FIG. 11A). In some implementations, along the X direction, the connection region may be located at an edge of the array, and the connection region is located on a side of the array region, for example, located at a left edge or a right edge of the array structure.

In the example of the present disclosure, the array may include a plurality of first conductive structures CT1, the first conductive structures CT1 may be located in the connection region, e.g., the second region S2, and each deck structure may have one gate layer WL, which may be commonly connected to one first conductive structure CT1. The second region S2 may include or may not include a stair structure, or may include other connection structures that may lead out the gate layer WL.

In the example of the present disclosure, the memory device further includes a peripheral circuit CMOS, and the array and the CMOS may be bonded or otherwise combined. The peripheral circuit may include a string driver SD and a page buffer PB, where there may be a plurality of PBs and the SDs, such as PB1 to PBN, and bit lines of each of the N deck structures are correspondingly connected to one PB; and each SD is a small cuboid as shown in FIG. 11A (two SDs are shown in FIG. 11A). Each of the first conductive structures CT1 may be correspondingly connected with one SD, the region where the SD is arranged may be located directly above the connection region SS, and the region where the PB is arranged may be located above the array region GB, thereby reducing the winding and reducing the manufacturing difficulty of the process.

In the example of the present disclosure, as shown in FIG. 11A, the array includes a plurality of first deck structures (N decks are shown in FIG. 11A, e.g., deck1-deckN) stacked along the Z-axis direction, and each deck is correspondingly connected with a second conductive layer, e.g., the bit-line layers BL1-BLN, and there may be a plurality of PBs, for example, PB1-PBN. Bit lines BL of different decks are led out separately to corresponding PBs, for example, bit-line layer BL1 of deck1 is connected with PB1, and bit line BLN of deckN is connected with PBN. It should be noted that FIG. 11A only illustrates the connection relationship between the bit-line layer of the deck structure and the corresponding PB, and the connection relationship does not reflect the actual position of the lead-out structure (e.g., the second conductive structure) of the bit line. It may be clear that in the example of the present disclosure, different bit lines connected with a channel structure in different decks are led out through different second conductive structures.

In the example of the present disclosure, as shown in FIG. 11B, the lengths of the bit-line layers BL1-BLN corresponding to each deck along their extending direction may be different. In view of this, the two adjacent bit-line layers are disconnected along the Y-axis direction in the top view of FIG. 11B. For BL1 to BL4 in FIG. 11C, the length variation of the bit lines in the bit-line layers corresponding to different decks can be seen from another viewing angle, thereby facilitating the lead-out of the second conductive structure. It should be noted that the bit line of deck1 may be located at the top layer of all the first deck structures, which need not be led out by specifically providing the second conductive structure. In view of this, in FIG. 11B, the bit line in BL1 is connected with the channel structure CH, and the bit line in BL2-BLN is connected with the second conductive structure CT2.

In the example of the present disclosure, as shown in FIG. 11C, the bit lines of all the decks are led out from the same side, for example, from the top of the first deck structure, and the second conductive structure CT2 connected with the bit line of the deck extends through all the decks between the bit line BL and the top of the structure. For example, the second conductive structure CT2 connected with the bit-line layer BL2 of deck2 extends through deck2 and deck1; the second conductive structure CT2 connected with the bit-line layer BL4 of deck4 extends through all the decks. In other examples, the bit lines of all the decks may also be led out from the bottom of the first deck structure, and there may also be other lead-out methods for the bit line BL and the second conductive structure CT2.

In the example of the present disclosure, as shown in FIG. 11D, the third region S3 where the second conductive structure CT2 connected with the bit line is located is on at least one side of the first region where the first deck structure is located along the Y direction. A plurality of channel structures CH are arranged in the first deck structure, and the second conductive structures CT2 connected with the bit lines may extend through the deck structure where the conductive layer and the dielectric layer are stacked alternately, or may extend through the dielectric structure.

In an example of the present disclosure, the array includes one memory block, the memory block includes a plurality of first deck structures that are stacked along a Z-axis direction, each first deck structure includes a top select gate layer TSG, the structure includes at least one top select gate isolation structure TSG CUT extending along the X direction, the TSG CUT extends through the top select gate layer TSG along the Z-axis direction, the TSG is divided into a plurality of top select gate sub-layers, and each top select gate layer corresponds to one string (P strings are illustrated in FIG. 11D, e.g., string1-stringP). The material of the TSG CUT includes, but is not limited to, silicon oxide.

In the example of the present disclosure, as shown in FIG. 11D and FIG. 11E (FIG. 11E is a cross-sectional view corresponding to X4-X4′ in FIG. 11D), the TSGs of different decks are led out through the same third conductive structure CT3. The third conductive structure CT3 includes a second lead-out portion TSGTSC, a second connection portion B, and a contact portion TSGCT; the second lead-out portion TSGTSC extends along the Z-axis direction and is connected with the second connection portion B; the second connection portion B extends along a direction perpendicular to the Z-axis direction and is connected with the contact portion TSGCT; and the contact portion TSGCT extends along the Z-axis direction and is connected with the top select gate layer. The second lead-out portion TSGTSC extends through all the decks along the Z-axis direction, the TSGCTs of each deck structure may be aligned along the first direction, and projections of the TSGCTs of all the decks in the same string overlap in a plane perpendicular to the Z-axis direction. The TSGCT is connected with the second lead-out portion TSGTSC through the conductive structure extending along the X-axis direction, and the TSGTSC connected with the TSGCT in different decks in the same string are the same. The materials of TSGT, B and TSGTSC include, but are not limited to, tungsten. The number of TSGTSC is greater than or equal to the number of decks.

In the example of the present disclosure, as shown in FIG. 11D, for deck1-deckN, each deck structure may include a plurality of sub-TSGs, and the plurality of sub-TSGs may be corresponding to different TSGCTs and different TSGTSCs respectively. In other examples, each deck structure may further include one TSG, the TSG is connected with the TSGCT, and the TSGCT is connected with the TSGTSC through the second connection portion B.

In the example of the present disclosure, as shown in FIG. 11E, for the same string, deck1-deckN may share the same second lead-out portion TSGTSC, and different TSGs may be connected to the same second lead-out portion through different second connection layers B and contact portions TSGCT, so that the TSGs of different decks are led out through the same third conductive structure CT3.

In the example of the present disclosure, for the foregoing memory plane combination architecture, each memory plane in the two combined memory planes as described above may be an array Y-axis direction folding architecture, may be an array X-axis direction folding architecture, or may also be an array X-axis direction+Y-axis direction folding architecture. The following illustration takes each of the two combined memory planes being an array X-axis direction folding architecture as an example.

As shown in FIG. 12A to FIG. 12E, in the example of the present disclosure, the memory device includes a memory array, the array includes two memory planes and a connection region SS located between the two memory planes, the two memory planes share a gate WL, each memory plane includes a plurality of first deck structures, and a bit-line layer BL, e.g., a second semiconductor layer and a source layer ACS are arranged on both sides of each deck structure along the first direction. In some implementations, two adjacent decks along the Z-axis direction alternately share bit-line layers BL and source layers ACS.

In the example of the present disclosure, as shown in FIG. 12A, the array may include a plurality of first conductive structures CT1, the first conductive structures CT1 may be located in the connection region, e.g., the second region S2, and each deck structure may have one gate layer WL, which may be commonly connected to one first conductive structure CT1. The second region S2 may include or may not include a step structure, or may include other connection structures that may lead out the gate layer WL.

In the example of the present disclosure, the memory device further includes a peripheral circuit CMOS, and the array and the CMOS may be bonded or otherwise combined. The peripheral circuit may include a string driver SD and a page buffer PB, where there may be a plurality of PBs and the SDs, such as PB1 to PBN, and bit lines of each of the N deck structures are correspondingly connected to one PB; and each SD is a small cuboid as shown in FIG. 12A (two SDs are shown in FIG. 12A). Each of the first conductive structures CT1 may be correspondingly connected with one SD, the region where the SD is arranged may be located directly above the connection region SS, and the region where the PB is arranged may be located above the memory plane, thereby reducing the winding and reducing the manufacturing difficulty of the process.

FIG. 12B and FIG. 12C may be understood with reference to FIG. 11B and FIG. 11C, and details will not described herein.

In an example of the present disclosure, the array includes one memory block, the memory block includes a plurality of first deck structures that are stacked along a Z-axis direction, each first deck structure includes a top select gate layer TSG, the structure includes at least one top select gate isolation structure TSG CUT extending along the X direction, the TSG CUT extends through the top select gate layer TSG along the Z-axis direction, the TSG is divided into a plurality of top select gate sub-layers, and each top select gate layer corresponds to one string (P strings are illustrated in FIG. 12D, e.g., string1-stringP). The material of the TSG CUT includes, but is not limited to, silicon oxide.

In the example of the present disclosure, as shown in FIG. 12D and FIG. 12E (FIG. 12E is a cross-sectional view corresponding to X5-X5′ in FIG. 12D), the TSGs of different decks are led out through the same third conductive structure CT3. The third conductive structure CT3 includes a second lead-out portion TSGTSC, a second connection portion B, and a contact portion TSGCT; the second lead-out portion TSGTSC extends along the Z-axis direction and is connected with the second connection portion B; the second connection portion B extends along a direction perpendicular to the Z-axis direction and is connected with the contact portion TSGCT; and the contact portion TSGCT extends along the Z-axis direction and is connected with the top select gate layer. The second lead-out portion TSGTSC extends through all the decks along the Z-axis direction, the TSGCTs of each deck structure may be aligned along the first direction, and projections of the TSGCTs of all the decks in the same string overlap in a plane perpendicular to the Z-axis direction. The TSGCT is connected with the second lead-out portion TSGTSC through the conductive structure extending along the X-axis direction, and the TSGTSC connected with the TSGCT in different decks in the same string are the same. The materials of TSGT, B and TSGTSC include, but are not limited to, tungsten. The number of TSGTSC is greater than or equal to the number of decks.

In the example of the present disclosure, as shown in FIG. 12E, for deck1-deckN, each deck structure may include a plurality of sub-TSGs, the plurality of sub-TSGs form a stair structure, and a cross-sectional shape of the stair structure along the first direction is a step shape; each step in the stair structure corresponds to one top select gate layer; and one contact portion TSGCT is connected to a step where one top select gate layer is located. The plurality of sub-TSGTs may be correspondingly connected with different TSGCTs, a plurality of TSGCTs in the same string may be connected to the same second leading-out portion TSGTSC, or may be connected to a different second leading-out portion TSGTSC (three contact portions TSGCT in the same string in FIG. 12D are correspondingly connected to different second leading-out portions TSGTSC).

It should be noted that the second connection portion B for connecting the contact portion TSGCT and the second lead-out structure TSGTSC is shown in FIG. 12D, while the second connection portion B is not shown in FIG. 12E due to the cross-sectional view angle.

An example of the present disclosure provides a memory device, and for the foregoing array X-axis direction+Y-axis direction folding architecture, the array X-axis direction+Y-axis direction folding architecture as described above may be first the X-axis direction folding and then the Y-axis direction folding, or may be first the Y-axis direction folding and then the X-axis direction folding. The following illustration takes first the X-axis direction folding and then the Y-axis direction folding as an example.

As shown in FIG. 13A to FIG. 13F, in the example of the present disclosure, the original array is divided along the X-axis direction and Y-axis direction and then stacked, and the gate layer WL is shared to form a memory array, the array includes an array region GB and a connection region SS. In some implementations, along the X-axis direction, the connection region is located in the middle of the memory array, and the connection region is located between the two array regions (as shown in FIG. 13). In some implementations, along the X direction, the connection region may be located at an edge of the array, and the connection region is located on a side of the array region, for example, located at a left edge or a right edge of the array structure.

In the example of the present disclosure, as shown in FIG. 13A, the array includes a plurality of memory modules Models (Model1-Model M is illustrated in FIG. 13A, M is a positive integer greater than or equal to 2), and each Model includes a plurality of first deck structures (FIG. 13A shows that each Model includes N decks, N is a positive integer greater than or equal to 2). The bit-line layers BL (FIG. 13A shows that the bit-line layers of the N deck structures included in each Model are BL1-BLN), e.g., the second semiconductor layer and the source layer ACS are arranged on two sides of each deck structure in the first direction respectively, and in some implementations, two adjacent deck structures along the Z-axis direction alternately shares the bit-line layers BL and the source layer ACS. Each deck structure is correspondingly connected with a second conductive layer, e.g., a bit-line layer.

In the example of the present disclosure, as shown in FIG. 13A, the array may further include a plurality of first conductive structures CT1, the first conductive structures CT1 may be located in the connection region, e.g., the second region S2, and each deck structure may have one gate layer WL, which may be commonly connected to one first conductive structure CT1. The second region S2 may include or may not include a stair structure, or may include other connection structures that may lead out the gate layer WL.

In the example of the present disclosure, the memory device further includes a peripheral circuit CMOS, and the array and the CMOS may be bonded or otherwise combined. The peripheral circuit may include a string driver SD and a page buffer PB; where there may be a plurality of PBs and the SDs, such as PB1 to PBN, and bit lines of each of the N deck structures of each of the memory modules are correspondingly connected to a corresponding PB, for example, a bit-line layer BL1 of the deck1 is connected with the PB1, and a bit line BLN of the deckN is connected with the PBN. The bit lines of the same deck structure of the different memory modules are connected in parallel to the corresponding PB, for example, the bit-line layers BL1 of deck1 of Model1 and the bit-line layers BL1 of deck1 of Model1 are both connected to PB1. The bit lines of the deckN of each memory module are connected with the PBN. Each SD is a small cuboid as shown in FIG. 13A (two SDs are shown in FIG. 13A). Each of the first conductive structures CT1 may be correspondingly connected with one SD, the region where the SD is arranged may be located directly above the connection region SS, and the region where the PB is arranged may be located above the memory plane, thereby reducing the winding and reducing the manufacturing difficulty of the process.

In the example of the present disclosure, in the same memory module, a channel structure is led out from corresponding different bit lines in different decks respectively; and in different memory modules, a channel structure is led out together from different bit lines in a specified deck.

In the example of the present disclosure, as shown in FIG. 13B, the lengths of the bit-line layers BL1-BLN corresponding to each deck in each Model along their extending direction may be different. In view of this, the two adjacent bit-line layers are disconnected along the Y-axis direction in the top view of FIG. 13B. For BL1 to BL4 in Model1 and Model2 in FIG. 13C, the length variation of the bit lines in the bit-line layers corresponding to different decks can be seen from another viewing angle, thereby facilitating the lead-out of the second conductive structure. It should be noted that the bit line of deck1 of Model1 may be located at the top layer of all the first deck structures, which need not be led out by specifically providing the second conductive structure. In view of this, in FIG. 13B, the bit line in BL1 of Model1 is connected with the channel structure CH, and the bit lines in other bit-line layers (BL2-BLN) of Model1 and all the bit-line layers (BL1-BLN) of Model2 are connected with the second conductive structure CT2.

In the example of the present disclosure, as shown in FIG. 13C, the bit lines of all the decks are led out from the same side, for example, from the top of the first deck structure, and the second conductive structure CT2 connected with the bit line of the deck structure extends through all the decks between the bit line BL and the top of the structure. For example, in Model1, the second conductive structure CT2 connected with the bit-line layer BL2 of deck2 extends through deck2 and deck1, and the second conductive structure CT2 connected with the bit-line layer BL4 of deck4 extends through all the decks; in the Model 2, the second conductive structure CT2 connected with the bit-line layer BL1 of deck1 extends through all the decks of Model1, and the second conductive structure CT2 connected with the bit-line layer BL4 of deck4 extends through all the decks of Model1 and all the decks of Model2. In other examples, the bit lines of all the decks may also be led out from the bottom of the first deck structure, and the bit line BL and the second conductive structure CT2 may also have other lead-out methods.

In the example of the present disclosure, as shown in FIG. 13C, the array may further include a plurality of fourth conductive structures CT4, each of the fourth conductive structures CT4 is arranged at the top of all the first deck structures, and each of the fourth conductive structures is configured to connect the second conductive structure CT2 of the two decks specified in the two different Models; for example, one CT4 connects the second conductive structure CT2 corresponding to deck1 of Model1 to the second conductive structure CT2 corresponding to deck1 of Model2. In some implementations, the fourth conductive structure CT4 may include a combination of a plurality of conductive structures extending along different directions. In other examples, the plurality of fourth conductive structures CT4 may also be arranged at the bottom of all the first deck structures.

In an example of the present disclosure, the array includes one memory block, the memory block includes a plurality of first deck structures that are stacked along a Z-axis direction, each first deck structure includes a top select gate layer TSG, the structure includes at least one top select gate isolation structure TSG CUT extending along the X direction, the TSG CUT extends through the top select gate layer TSG along the Z-axis direction, the TSG is divided into a plurality of top select gate sub-layers, and each top select gate layer corresponds to one string (P strings are illustrated in FIG. 13D and FIG. 13E, e.g., string1-stringP). The material of the TSG CUT includes, but is not limited to, silicon oxide.

In the example of the present disclosure, in the same memory module, a channel structure is led out together from the corresponding different top select gate layers in different decks; and in different memory modules, a channel structure is led out from the corresponding different top select gate layers in different decks respectively.

In the example of the present disclosure, as shown in FIG. 13D and FIG. 13E, the TSGs of different decks are led out through the same third conductive structure CT3. The third conductive structure CT3 includes a second lead-out portion TSGTSC, a second connection portion B, and a contact portion TSGCT; the second lead-out portion TSGTSC extends along the Z-axis direction and is connected with the second connection portion B; the second connection portion B extends along a direction perpendicular to the Z-axis direction and is connected with the contact portion TSGCT; and the contact portion TSGCT extends along the Z-axis direction and is connected with the top select gate layer. The second lead-out portion TSGTSC extends through all the decks along the Z-axis direction, the TSGCTs of each deck structure may be aligned along the first direction, and projections of the TSGCTs of all the decks in the same string overlap in a plane perpendicular to the Z-axis direction. The TSGCT is connected with the second lead-out portion TSGTSC through the conductive structure extending along the X-axis direction, and the TSGTSC connected with the TSGCT in different decks in the same string are the same. The materials of TSGT, B and TSGTSC include, but are not limited to, tungsten. The number of TSGTSC is greater than or equal to the number of decks.

In the example of the present disclosure, as shown in FIG. 13D, taking Model1 as an example, each deck in the deck1-deckN of Model1 may include a plurality of sub-TSGs, the plurality of sub-TSGs may be correspondingly connected with different TSGCTs, different TSGCTs may be connected with the same TSGTSC, or different TSGCTs may also be connected with different TSGTSCs (as shown in FIG. 13D). In other examples, deck1 further includes one TSG, the TSG is connected with the TSGCT, and the TSGCT is connected with the TSGTSC through the second connection portion B.

In the example of the present disclosure, as shown in FIG. 13E, taking Model2 as an example, each deck in the deck1-deckN of Model2 may include a plurality of sub-TSGs, the plurality of sub-TSGs may also be correspondingly connected with different TSGCTs, different TSGCTs may be connected with the same TSGTSC, or different TSGCTs may also be connected with different TSGTSCs (as shown in FIG. 13E). In other examples, deck1 further includes one TSG, the TSG is connected with the TSGCT, and the TSGCT is connected with the TSGTSC through the second connection portion B.

It should be noted that, in FIG. 13D and FIG. 13E, the TSGCT is connected with different TSGTSCs through a second connection portion B extending along the opposite direction (B is along the +X axis in Model1, and B is along the −X axis in Model2). It can be understood that, for different models, the TSGCT is connected with different TSGTSCs through second connection portions B extending along different directions. The specific extending direction of the second connection portion B mentioned above does not limit the extending direction of the second connection portion B in the example of the present disclosure, and is only used to describe that in different models, the TSGCT may be connected to different TSGTSCs through the second connection portion B extending along different directions.

In the example of the present disclosure, as shown in FIG. 13F (FIG. 13F is a cross-sectional view corresponding to X6-X6′ in FIG. 13D), for deck1-deckN in Model1, different decks may be connected to the same second lead-out portion TSGTSC through different contact portions TSGCT and different second connection portions B; for deck1-deckN in Model2, different decks may be connected to the same second lead-out portion TSGTSC through different contact portions TSGCT and different second connection portions B. The second lead-out portion TSGTSC in Model1 may be different from the second lead-out portion TSGTSC in Model2, and the second lead-out portion TSGTSC in Model1 may only extend through the decks in Model1, or extend through the decks in Model1 and Model2; the second lead-out portion TSGTSC in Model2 extends through the decks in Model1 and Model2.

An example of the present disclosure provides a memory device, including:

A plurality of first deck structures stacked together, where the first deck structure includes first conductive layers and first dielectric layers arranged alternately along a first direction; a plurality of first conductive structures, where each of the first conductive structures is connected with one first conductive layer of each of at least two first deck structures of the plurality of first deck structures; a plurality of channel structures, where each of the channel structures extends through the plurality of first deck structures; at least one semiconductor layer and at least one second conductive layer, where one semiconductor layer and one second conductive layer are located on two sides of one first deck structure respectively along the first direction and are both connected with the channel structure in one first deck structure, each second conductive layer includes a plurality of bit lines spaced apart along a second direction and extending along a third direction, and the second direction and the third direction intersect with each other and are both perpendicular to the first direction; and a plurality of second conductive structures, where each of the second conductive structures is connected with one bit line of at least one second conductive layer.

In some examples, different bit lines corresponding to different first deck structures through which the same channel structure extends are all connected with the same second conductive structure.

In some examples, the at least one second conductive layer is located between two adjacent first deck structures and is connected with the channel structure in each of the two adjacent first deck structures.

In some examples, the memory device further includes a peripheral circuit; the peripheral circuit includes a page buffer; and the plurality of second conductive structures are connected with the same page buffer.

In some examples, different bit lines corresponding to different first deck structures through which the same channel structure extends are all connected with different second conductive structures.

In some examples, the second conductive layers corresponding to different first deck structures have different sizes along the third direction; and different second bit lines connected with the second conductive layers corresponding to different first deck structures are arranged in sequence along the third direction.

In some examples, the memory device further includes a peripheral circuit; the peripheral circuit includes a plurality of page buffers; the second conductive structures connected with the bit lines of the same second conductive layer are connected with the same page buffer of the plurality of page buffers; and the second conductive structures connected with the bit lines of different second conductive layers are connected with different page buffers of the plurality of page buffers.

In some examples, the at least one semiconductor layer is located between two adjacent first deck structures and is connected with the channel structure in each of the two adjacent first deck structures.

In some examples, the two adjacent first deck structures of the plurality of first deck structures form a deck group; the memory device includes a plurality of semiconductor layers; the plurality of semiconductor layers are located between the two adjacent first deck structures of the deck group, respectively; and the plurality of semiconductor layers are connected with each other.

In some examples, a cross-sectional shape of the plurality of first deck structures along the first direction includes a step-like shape; each step in the step-like shape corresponds to the first conductive layer and the first dielectric layer adjacent to each other; and the first conductive structure extends along the first direction in the first deck structure and is connected to at least two steps where one first conductive layer of at least two first deck structures is located.

In some examples, the memory device further includes a second deck structure including isolation layers and second dielectric layers that are arranged alternately; the first conductive structure includes a first lead-out portion and a plurality of first connection portions; the first lead-out portion extends along the first direction in the second deck structure and is connected with each of the plurality of first connection portions; and each of the plurality of first connection portions is located in the isolation layer and is connected to one first conductive layer of a corresponding one of at least two first deck structures.

In some examples, the first conductive structure is connected with one first conductive layer in each of the first deck structures that has the same distance from the semiconductor layers connected with the channel structure of a corresponding one of the first deck structures.

In some examples, the first conductive structure is connected with one first conductive layer in each of the first deck structures that has different distances from the semiconductor layers connected with the channel structure of a corresponding one of the first deck structures.

In some examples, the memory device further includes a peripheral circuit; the peripheral circuit includes a plurality of string drivers; and the first conductive layers of at least two first deck structures are connected with each other through the first conductive structure and are connected with the same one of the string drivers.

In some examples, the memory device further includes a plurality of third conductive structures; the first conductive layer in the first deck structure include a top select gate layer and a gate layer; the top select gate layer is located at one end of two ends of a corresponding first deck structure along the first direction away from a semiconductor layer connected with a channel structure in the corresponding first deck structure; the third conductive structure extends along the first direction in the first deck structure and is connected with the top select gate layer included in at least one of the plurality of first deck structures; the first conductive structure is connected with one gate layer of each of at least two first deck structures of the plurality of first deck structures.

In some examples, the memory device further includes a top select gate isolation structure, where the top select gate isolation structure divides the top select gate layer into a plurality of top select gate sub-layers; and different top select gate sub-layers included in the same top select gate layer are connected with different third conductive structures.

In some examples, different top select gate layers included in different first deck structures are connected with different third conductive structures; and different bit lines corresponding to different first deck structures through which the same channel structure extends are all connected with the same second conductive structure.

In some examples, different bit lines corresponding to different first deck structures through which the same channel structure extends are all connected with different second conductive structures; and different top select gate layers included in different first deck structures are connected with the same third conductive structure.

In some examples, the plurality of first deck structures stacked together constitute one memory plane; the memory device includes a first memory plane and a second memory plane; the first memory plane and the second memory plane are arranged in parallel along a second direction; the memory device further includes a plurality of string drivers; the plurality of first conductive structures are located between the first memory plane and the second memory plane, and the first conductive structure is connected with one gate layer of each of different first deck structures in at least one memory plane; and the first conductive layers of the first memory plane and the second memory plane at the same position in the first direction are connected with each other and connected with the same one of the string drivers.

In some examples, different bit lines corresponding to different first deck structures through which the same channel structure extends are all connected with different second conductive structures; different top select gate layers included in different first deck structures of the same memory plane are connected with the same third conductive structure; and different top select gate layers included in the first deck structures of different memory planes at the same position in the first direction are connected with different third conductive structures.

In some examples, the plurality of first deck structures stacked together constitute one memory module; the memory device includes a first memory module and a second memory block; the first memory module and the second memory block are stacked together along the first direction; and the plurality of first conductive structures are connected with one gate layer of each of first deck structures in the first memory module and the second memory block.

In some examples, different bit lines corresponding to different first deck structures through which the same channel structure extends in the same memory module are all connected with different second conductive structures; two bit lines corresponding to two first deck structures specified in different memory modules are connected with each other; different top select gate layers included in different first deck structures in the same memory module are connected with the same third conductive structure; and two top select gate layers included in two first deck structures in different memory modules are connected with different third conductive structures.

In some examples, different bit lines corresponding to different first deck structures through which the same channel structure extends in the same memory module are all connected with the same second conductive structure; different bit lines corresponding to two first deck structures in different memory modules are all connected with different second conductive structures; different top select gate layers included in different first deck structures in the same memory module are connected with different third conductive structures; and two top select gate layers included in two first deck structures in different memory modules are connected with the same third conductive structure.

In some examples, the plurality of first deck structures are arranged in a first region, the plurality of first conductive structures are all arranged in a second region, the plurality of second conductive structures are all arranged in a third region, and the plurality of third conductive structures are all arranged in a fourth region; the second region is located in the middle of the first region, or the second region is located on at least one of two sides of the first region along a direction perpendicular to the stacking direction; the third region is located on at least one of two sides of the first region along the third direction; and the fourth region is located between the first region and the second region.

It should be noted that, one region being on one side of another region here and above in the example of the present disclosure is a limitation on the relative positional relationship between the two regions, but is not a limitation on the belonging relationship between the two regions. That is, one side of the region in the example of the present disclosure may be understood as one end or edge of the region (e.g., belonging to the inside of the region), or may be understood as aside or next to the region (e.g., belonging to the outside of the region).

It should be noted that each component structure in the memory device in the foregoing examples of the present disclosure may be understood with reference to the descriptions of the corresponding structures in the foregoing examples.

In the example of the present disclosure, the first conductive structure CT1 is connected with any one of the gate layers WL in each of the plurality of first deck structures, the first conductive structure CT1 may be located in the first deck structure or may be located in the second deck structure, the first conductive structure CT1 may partially or completely extend through the first deck structure or the second deck structure, the first conductive structure CT1 may be located in the middle or the edge of the first deck structure, the plurality of gate layers of the first deck structure may form a step structure or be flush along a plane perpendicular to the first direction (a direction in which the WL extends), and the first conductive structure CT1 may include a conductive pillar or a hollow conductive layer, and selectively include a first connection portion along a direction perpendicular to the first direction. The first conductive structure CT1 connects any one of the gate layers WL of each of the plurality of first deck structures to the string driver SD.

In the example of the present disclosure, if the first conductive structure CT1 is connected with any one of the gate layers WL in each of the plurality of first deck structures, the total number of the gate layers included in one memory block is equal to the product of the number of the decks and the number of the string drivers SD corresponding to the memory block.

In the example of the present disclosure, for a certain fixed memory capacity, if the number of bit lines corresponding to one memory block in the unfolding architecture (as shown in FIG. 2A) is Q (where Q is a positive integer); the total number corresponding to one memory block in the array Y-axis direction folding architecture (as shown in FIG. 2B) is still Q; the total number corresponding to one memory block in the array X-axis direction folding architecture (as shown in FIG. 2C) is still Q/N, where N is the number of deck structures included in one memory block, and N is an integer greater than 1; the total number corresponding to one memory block in the array X axis+Y axis direction folding architecture (as shown in FIG. 2D) is still Q/N, where N is the number of deck structures included in one memory block, and N is an integer greater than 1; in the memory plane combination architecture (which may also be considered as a combination of two folding memory blocks, as shown in FIG. 2E), each of the two memory planes that are combined may refer to a specific folding architecture, while the first conductive structure CT1 is shared by two memory planes, and the sharing ratio of the first conductive structure CT1 is further improved.

In the example of the present disclosure, each deck is interconnected through a source layer ACS and a bit-line layer BL, and two decks form one two-deck structure architecture; a multi-deck structure architecture may be formed by hybrid bonding between one two-deck structure and another two-deck structure, or two adjacent decks share a bit-line layer BL in sequence or share an ACS to form a plurality of multi-deck structure architectures. As such, it can not only solve the problem of reduced saturation current of the channel due to too many gate layers in the non-folding architecture, but also save the corresponding bit-line layers BL and ACS, thereby reducing the manufacturing cost.

In the example of the present disclosure, the BLs of all the decks are connected with the page buffer PB in the peripheral circuit through the second conductive structure CT2, and the specific morphology of the second conductive structure CT2 may be a circular, rectangular, or a conductive column similar to the shape of the channel structure CH, or directly arranged in the GLS.

In the example of the present disclosure, parameters of the memory device in various architectures are shown in Table 1. It should be noted that the explanation of various parameters and numbers in Table 1 may be understood with reference to the foregoing description of various parameters and numbers, and the memory block size and the array efficiency may be calculated in reference to the foregoing calculation methods.

In Table 1, RS represents the resistance of the entire gate layer (WL). The resistance of the entire gate layer in the X-axis direction folding, the multi-memory plane combination and the X+Y axis direction folding scheme is significantly reduced compared with the resistance of the entire gate layer in the unfolding scheme, so that the delay can be reduced, and the reading and writing operation speed can be improved.

It can be seen from Table 1 that, compared with the unfolding scheme, at least one of reduced memory block size or improved array efficiency can be achieved by various folding scheme. The Y folding scheme mainly achieves the improved array efficiency, the X folding scheme mainly achieves the reduced memory block size, and the X+Y axis direction folding scheme achieves both the reduced memory block size and the improved array efficiency.

TABLE 1

| | | | X-axis | X-axis | Multi- | |
|---|---|---|---|---|---|---|
| | | | direction | direction | memory | X + Y axis |
| | | Y-axis | folding | folding | plane | direction |
| | | direction | (in the middle | (at the edge | combination | folding |
| | Unfolding | folding | of CT1) | of CT1) | 2 plane | 2 model |
| Total | N*1 | N*1 | N*1 | N*1 | N*1 | N*1 |
| number of | | | | | | |
| WLs | | | | | | |
| Number | N*1 | 1 | 1 | 1 | 1 | ½ |
| of SDs | | | | | | |
| Plane X | Q BL + N*1 | Q BL + 1 SD | (Q/N) BL + 1 | (Q/N) BL + 1 | (Q/N) | (Q/N) |
| length | SD | | SD | SD | BL + (½) SD | BL + (½) SD |
| Memory | N*1*Q*3(TLC)* | N*1*Q*3(TLC)*number | 1*Q*3(TLC)* | 1*Q*3(TLC)* | 1*Q*3(TLC)* | 1*Q*3(TLC)* |
| block size | number of | of strings | number of | number of | number of | number of |
| | strings | (unchanged) | strings | strings | strings | strings |
| | | | (smaller) | (smaller) | (smaller) | (smaller) |
| RS | A | A | A/16 | A/4 | A/4 | A/16 |
| Array | Q BL / | Q BL / | (Q/N) BL / | (Q/N) BL / | (Q/N) BL / | (Q/N) BL / |
| efficiency | (Q | (Q BL + 1 SD) | ((Q/N) BL + 1 | ((Q/N) BL + 1 | ((Q/N) | ((Q/N) |
| | BL + N*1 | (higher) | SD) | SD) | BL + (½)SD)(higher) | BL + (½)SD)(higher) |
| | SD) | | (unchanged) | (unchanged) | | |

In the example of the present disclosure, all the four folding architectures can solve the problem of the reduced saturation current of the channel as the number of deck layers increases. WL sharing of N deck structures in the array Y-axis direction folding architecture enables the SD to be shared, so that the total number of the SDs can be reduced, e.g., the area occupied by SD is reduced, and the area of the final memory device is reduced. In the array X-axis direction folding architecture, by reducing the BL to 1/N, the area occupied by SD shared by WLs of N decks is reduced by N times, CHIP*diesize is reduced by 1/N, the memory block size is reduced by 1/N, and the WL RC is reduced by 1/N². In the memory plane combination architecture, the area of the SD is further reduced, the array efficiency is improved and the area of the memory device is reduced. The array X-axis+Y-axis direction folding architecture combines the advantages of the array Y-axis direction folding architecture and the array X-axis direction folding architecture.

In the example of the present disclosure, a channel structure extends through all the first deck structures, and a portion of the channel structure corresponding to each deck structure is referred to as a sub-channel structure, and in a process of performing a read operation or a program operation (or referred to as a write operation), each sub-channel structure may achieve selecting and unselecting of the sub-channel structure through the semiconductor layer (e.g., the source layer ACS) and the second conductive layer (e.g., the bit-line layer BL) of the corresponding deck.

It should be noted that, in a process of performing a read operation each time, one sub-channel structure in one channel structure is a selected sub-group channel structure, and both BL and TSG corresponding to the selected group channel structure are selected BL (SelBL) and selected TSG (SelTSG); all sub-group channel structures other than the sub-channel structure in the channel structure are unselected sub-group channel structures, and BL and TSG corresponding to the unselected group channel structure are unselected BL (unSelBL) and selected TSG (unSelTSG). The selected gate layer in each deck is SelWL, and the unselected gate layer in each deck is unSelWL.

In the example of the present disclosure, the foregoing four folding architectures of the memory device are summarized into two types, e.g., the first type: BL of each deck is interconnected and TSG is led out separately, and the second type: TSG of each deck is interconnected and BL is led out separately.

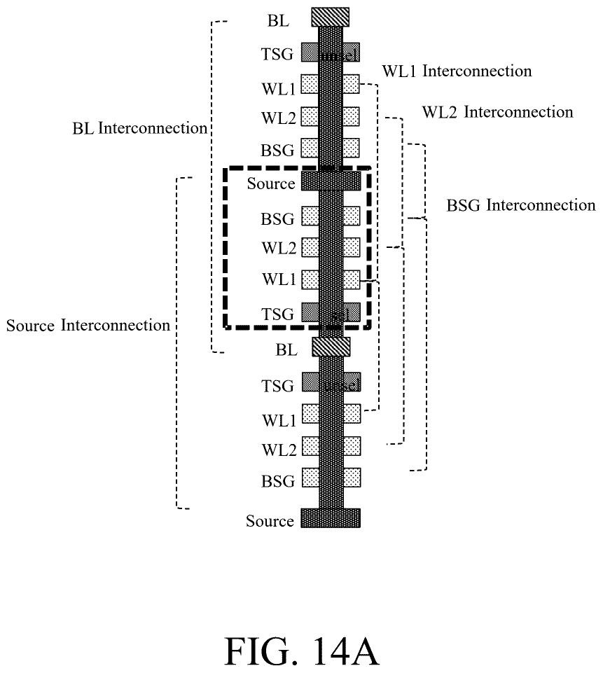

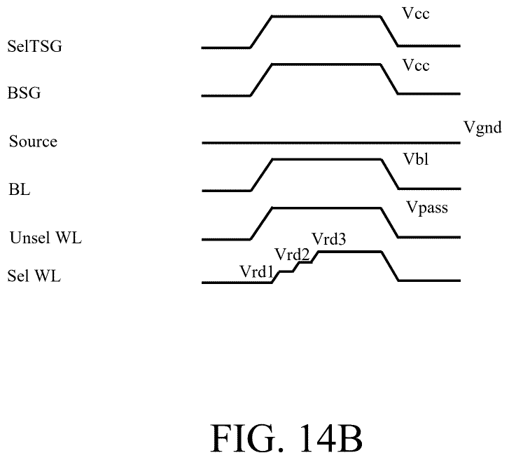

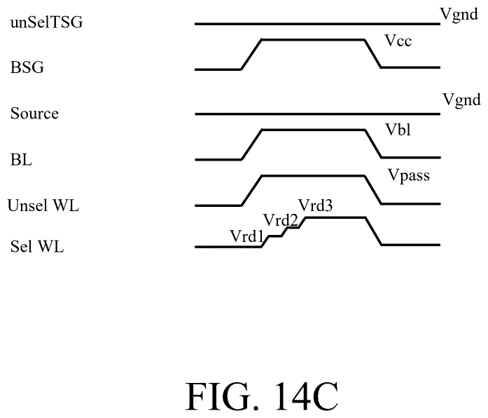

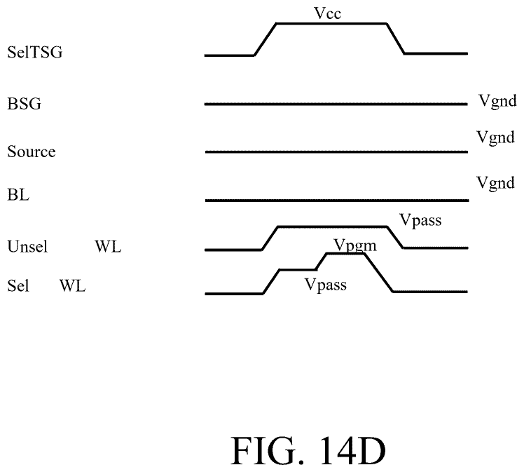

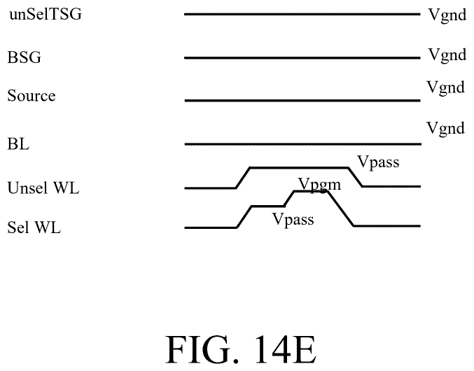

FIG. 14A is a first schematic diagram of a layout including functional layers coupled to a channel structure of a memory device provided by an example of the present disclosure; FIG. 14B is a first schematic diagram of applying a voltage to functional layers in a selected sub-channel structure in a process of a read operation provided by an example of the present disclosure; FIG. 14C is a first schematic diagram of applying a voltage to functional layers in an unselected sub-channel structure in a process of a read operation provided by an example of the present disclosure; FIG. 14D is a first schematic diagram of applying a voltage to functional layers in a selected sub-channel structure in a process of a program operation provided by an example of the present disclosure; FIG. 14E is a first schematic diagram of applying a voltage to functional layers in an unselected sub-channel structure in a process of a read operation provided by an example of the present disclosure.

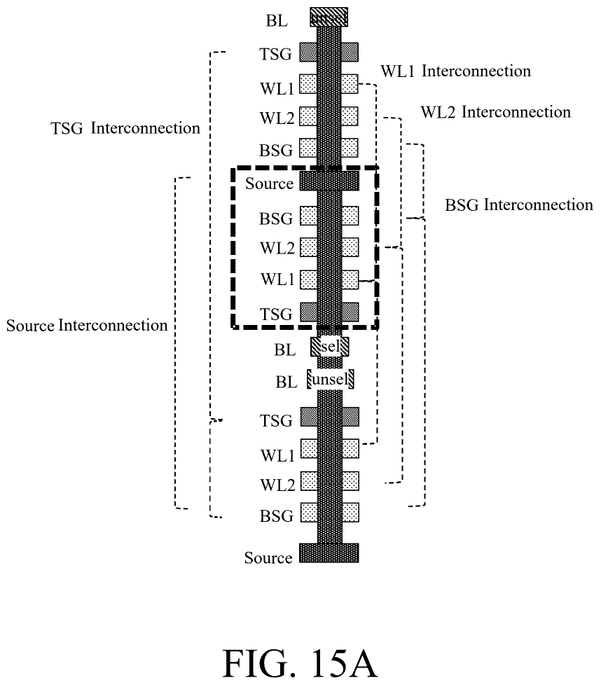

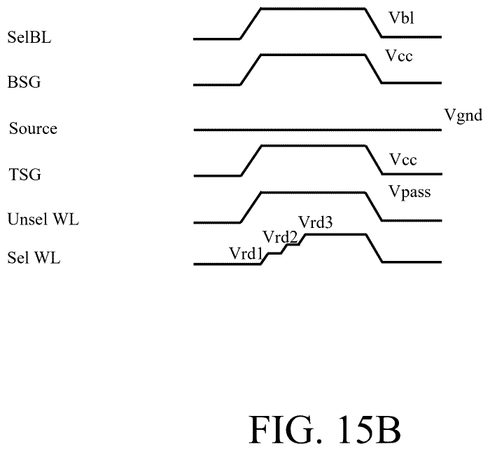

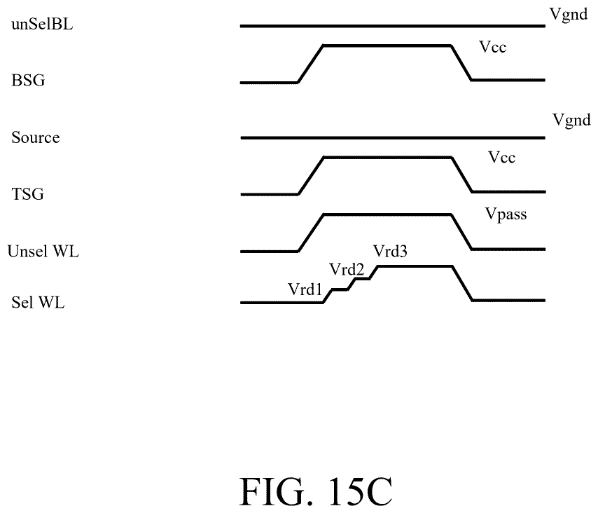

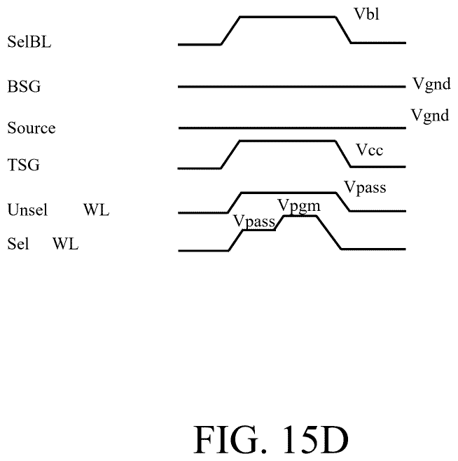

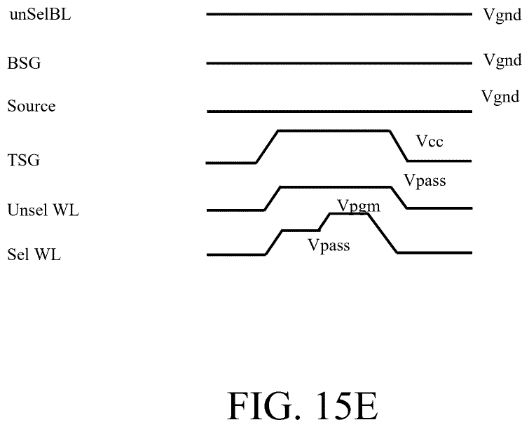

FIG. 15A is a second schematic diagram of a layout including functional layers coupled to a channel structure of a memory device provided by an example of the present disclosure; FIG. 15B is a second schematic diagram of applying a voltage to functional layers in a selected sub-channel structure in a process of a read operation provided by an example of the present disclosure; FIG. 15C is a second schematic diagram of applying a voltage to functional layers in an unselected sub-channel structure in a process of a read operation provided by an example of the present disclosure; FIG. 15D is a second schematic diagram of applying a voltage to functional layers in a selected sub-channel structure in a process of a program operation provided by an example of the present disclosure; FIG. 15E is a second schematic diagram of applying a voltage to functional layers in an unselected sub-channel structure in a process of a read operation provided by an example of the present disclosure.

A detailed description of implementations of the read operation and the write operation on the two types is described below in conjunction with FIG. 14A to FIG. 14E and FIG. 15A to FIG. 15E.

An example of the present disclosure provides a method of controlling a memory device, the memory device includes the memory device provided by an example of the present disclosure, the channel structure is divided into a plurality of sub-channel structures by the semiconductor layer and a second conductive layer; the first conductive layers in the first deck structure include a top select gate layer and a gate layer; the top select gate layer is located at one end of two ends of a corresponding first deck structure along the first direction away from a semiconductor layer connected with a channel structure in the corresponding first deck structure; and the method of controlling the memory device includes: in a process of performing a read operation, applying a first voltage to at least one of a top select gate of an unselected sub-channel structure of the plurality of sub-channel structures or a bit line coupled to the top select gate of the unselected sub-channel structure of the plurality of sub-channel structures, applying a second voltage to a top select gate of a selected sub-channel structure of the plurality of sub-channel structures and a bit line coupled to the top select gate of the selected sub-channel structure of the plurality of sub-channel structures, applying a pass voltage to all unselected gate layers, and applying a read voltage to the selected gate layer.

In the example of the present disclosure, when the types of the architectures of the memory device are different, the first voltage and the second voltage may be different based on the difference between the objects to which they are applied; while when the types of the architectures of the memory device are different, the voltages applied to all the unselected gate layers and the selected gate layer are unchanged.

It should be noted that, for the unselected sub-channel structure, there is no selected gate layer, but the gate layer connected with the selected gate layer in the selected sub-channel structure in the unselected sub-channel structure is also referred to as the selected gate layer in consideration of the sharing of the gate layer between a plurality of deck structures. For an unselected sub-channel structure, since its channel is in the unselected state, no read operation is performed even if the gate layer is applied with a read voltage.

In some examples, the first conductive layers in the first deck structure further include a bottom select gate layer located at one end of two ends of a corresponding first deck structure along the first direction close to the semiconductor layer connected with the channel structure in the corresponding first deck structure; and the method of controlling further includes: in the process of performing the read operation, applying a second turn-on voltage to all the bottom select gate layers.

In the example of the present disclosure, the memory device includes N (for example, three) first deck structures, and for the first type: BLs of each deck are interconnected and the TSG is led out separately, as shown in FIG. 14A, including the first deck structure deck1, the second first deck structure deck2, and the third first deck structure deck3 in sequence from top to bottom, deck1 and deck2 share the source layer Source, deck2 and deck3 share the bit-line layer BL, and each first deck structure includes a top select gate TSG, a plurality of gate layers, and a bottom select gate BSG, and the plurality of gate layers are illustrated by WL1 and WL2. WL1, WL2, BL, BSG and Source of all the first deck structures each are interconnected, and the TSG is led out separately.

In some examples, the first voltage includes a turn-off voltage, the second voltage includes a first turn-on voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the turn-off voltage to the top select gate of the unselected sub-channel structure, and applying the first turn-on voltage to the top select gate of the selected sub-channel structure.

In the example of the present disclosure, as shown in FIG. 14B and FIG. 14C, a turn-off voltage, such as a ground voltage, is applied to the top select gate unSel TSG in the unselected sub-channel structure, so that the unselected sub-channel structure is in a not turn-on state; and a first turn-on voltage, such as a voltage greater than a threshold voltage of the top select transistor, is applied to the top select gate Sel TSG in the selected sub-channel structure, so that the selected sub-channel structure is in a turn-on state. In addition, a second turn-on voltage is applied to the bottom select gate BSG and the unselected gate layer Unsel WL, a ground voltage is applied to the source layer, a read voltage is applied to the selected gate layer Sel WL, and then the BL current is read and the memory state of the memory cell Cell is determined. Here, the first turn-on voltage may be the same as or different from the second turn-on voltage. The read voltage may have a first order or a multi-order as shown in FIGS. 14B and 14C.

In the example of the present disclosure, the memory device includes N (for example, three) first deck structures, and for the first type: TSGs of each deck structure are interconnected and the BL is led out separately, as shown in FIG. 15A, including the first deck structure deck1, the second first deck structure deck2, and the third first deck structure deck3 in sequence from top to bottom, deck1 and deck2 share the source layer Source, and each first deck structure includes a top select gate TSG, a plurality of gate layers, and a bottom select gate BSG, and the plurality of gate layers are illustrated by WL1 and WL2. WL1, WL2, TSG, BSG and Source of all the first deck structures each are interconnected, and the BL is led out separately.

In some examples, the first voltage includes a program inhibit voltage, the second voltage includes a program enable voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the program inhibit voltage to the bit line coupled to the unselected sub-channel structure, applying the program enable voltage to the bit line coupled to the selected sub-channel structure, and applying a first turn-on voltage to all the top select gate layers.

In the example of the present disclosure, as shown in FIG. 15B and FIG. 15C, a program inhibit voltage, such as a ground voltage, is applied to the bit line unSel BL in the unselected sub-channel structure, so that the unselected sub-channel structure is in a not turn-on state; and a program enable voltage is applied to the bit line Sel BL in the selected sub-channel structure, so that the selected sub-channel structure is in a turn-on state. In addition, a second turn-on voltage is applied to the bottom select gate BSG and the unselected gate layer Unsel WL, a ground voltage is applied to the source layer, a read voltage is applied to the selected gate layer Sel WL, and then the BL current is read and the memory state of the memory cell Cell is determined. Here, the first turn-on voltage may be the same as or different from the second turn-on voltage. The read voltage may have a first order or a multi-order as shown in FIGS. 15B and 15C.

An example of the present disclosure further provides a method of controlling a memory device, the memory device includes the memory device provided by the example of the present disclosure, the channel structure is divided into a plurality of sub-channel structures by a plurality of first deck structures; the first conductive layers in the first deck structure include a top select gate layer and a gate layer; the top select gate layer is located at one end of two ends of a corresponding first deck structure along the first direction away from a semiconductor layer connected with a channel structure in the corresponding first deck structure; and the method of controlling the memory device includes: in a process of performing a program operation, applying a first voltage to at least one of a top select gate of an unselected sub-channel structure of the plurality of sub-channel structures or a bit line coupled to the top select gate of the unselected sub-channel structure of the plurality of sub-channel structures, applying a second voltage to a top select gate of a selected sub-channel structure of the plurality of sub-channel structures and a bit line coupled to the top select gate of the selected sub-channel structure of the plurality of sub-channel structures, applying a pass voltage to all unselected gate layers, and applying a program voltage to the selected gate layer.

In the example of the present disclosure, when the types of the architectures of the memory device are different, the first voltage and the second voltage both may be different based on the difference between the objects to which they are applied; while when the types of the architectures of the memory device are different, the voltages applied to all the unselected gate layers and the selected gate layer are unchanged.

It should be noted that, for the unselected sub-channel structure, there is no selected gate layer, but the gate layer connected with the selected gate layer in the selected sub-channel structure in the unselected sub-channel structure is also referred to as the selected gate layer in consideration of the sharing of the gate layer between a plurality of deck structures. For an unselected sub-channel structure, because its channel is in the unselected state, no program operation is performed even if the gate layer is applied with a program voltage.

In some examples, the first conductive layers in the first deck structure further include a bottom select gate layer located at one end of two ends of a corresponding first deck structure along the first direction close to the semiconductor layer connected with the channel structure in the corresponding first deck structure; and the method of controlling further includes: in the process of performing the program operation, applying a second turn-off voltage to all the bottom select gate layers.

In the example of the present disclosure, the memory device includes N (for example, three) first deck structures, and for the first type: BLs of each deck structure are interconnected and the TSG is led out separately, as shown in FIG. 14A, including the first deck structure deck1, the second first deck structure deck2, and the third first deck structure deck3 in sequence from top to bottom, deck1 and deck2 share the source layer Source, deck2 and deck3 share the bit-line layer BL, and each first deck structure includes a top select gate TSG, a plurality of gate layers, and a bottom select gate BSG, and the plurality of gate layers are illustrated by WL1 and WL2. WL1, WL2, BL, BSG and Source of all the first deck structures each are interconnected, and the TSG is led out separately.

In some examples, the first voltage includes a turn-off voltage, the second voltage includes a turn-on voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the turn-off voltage to the top select gate of the unselected sub-channel structure, and applying first turn-on voltage to the top select gate of the selected sub-channel structure.

In the example of the present disclosure, as shown in FIG. 14D and FIG. 14E, a turn-off voltage, such as a ground voltage, is applied to the top select gate unSel TSG in the unselected sub-channel structure, so that the unselected sub-channel structure is in a not turn-on state; and a first turn-on voltage, such as a voltage greater than a threshold voltage of the top select transistor, is applied to the top select gate Sel TSG in the selected sub-channel structure, so that the selected sub-channel structure is in a turn-on state. In addition, the turn-off voltage, such as ground voltage, is applied to the bottom select gate BSG, a second turn-on voltage is applied to the unselected gate layer Unsel WL, a ground voltage is applied to the source layer, a program voltage is applied to the selected gate layer Sel WL, and then the selected sub-channel structure completes the program operation. Here, the first turn-on voltage may be the same as or different from the second turn-on voltage. The second turn-on voltage applied on the unselected gate layer Unsel WL needs to be started before the program voltage is applied on the selected gate layer Sel WL, and the application is ended after the program voltage is applied to the selected gate layer Sel WL. Moreover, in view that the program voltage is high, the final program voltage can be obtained by using multiple boosting as shown in FIG. 14D and FIG. 14E.

In the example of the present disclosure, the memory device includes N (for example, three) first deck structures, and for the first type: TSGs of each deck structure are interconnected and the BL is led out separately, as shown in FIG. 15A, including the first deck structure deck1, the second first deck structure deck2, and the third first deck structure deck3 in sequence from top to bottom, deck1 and deck2 share the source layer Source, and each first deck structure includes a top select gate TSG, a plurality of gate layers, and a bottom select gate BSG, and the plurality of gate layers are illustrated by WL1 and WL2. WL1, WL2, TSG, BSG and Source of all the first deck structures each are interconnected, and the BL is led out separately.

In some examples, the first voltage includes a program inhibit voltage, the second voltage includes a program enable voltage, and applying the first voltage to at least one of the top select gate of the unselected sub-channel structure or the bit line coupled to the top select gate of the unselected sub-channel structure and applying the second voltage to the top select gate of the selected sub-channel structure and the bit line coupled to the top select gate of the selected sub-channel structure includes: applying the program inhibit voltage to the bit line coupled to the unselected sub-channel structure, applying the program enable voltage to the bit line coupled to the selected sub-channel structure, and applying a turn-on voltage to all the top select gate layers.

In the example of the present disclosure, as shown in FIG. 15D and FIG. 15E, a program inhibit voltage, such as a ground voltage, is applied to the bit line unSel BL in the unselected sub-channel structure, so that the unselected sub-channel structure is in a not turn-on state; and a program enable voltage is applied to the bit line Sel BL in the selected sub-channel structure, so that the selected sub-channel structure is in a turn-on state. In addition, the turn-off voltage, such as ground voltage, is applied to the bottom select gate BSG, a second turn-on voltage is applied to the unselected gate layer Unsel WL, a ground voltage is applied to the source layer, a program voltage is applied to the selected gate layer Sel WL, and then the selected sub-channel structure completes the program operation. Here, the first turn-on voltage may be the same as or different from the second turn-on voltage. The second turn-on voltage applied on the unselected gate layer Unsel WL needs to be started before the program voltage is applied on the selected gate layer Sel WL, and the application is ended after the program voltage is applied to the selected gate layer Sel WL. Moreover, in view that the program voltage is high, the final program voltage can be obtained by using multiple boosting as shown in FIG. 15D and FIG. 15E.

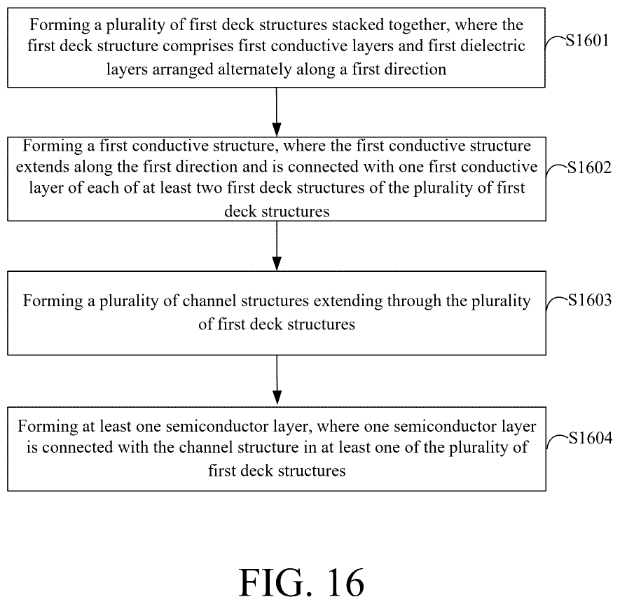

An example of the present disclosure provides a manufacturing method of a memory device, as shown in FIG. 16, the method of manufacturing the memory device may include operations S1601, S1602, S1603, and S1604.

At 1601, a plurality of first deck structures may be formed stacked together, where the first deck structure includes first conductive layers and first dielectric layers arranged alternately along a first direction.

At S1602, a first conductive structure may be formed, where the first conductive structure extends along the first direction and is connected with one first conductive layer of each of at least two first deck structures of the plurality of first deck structures.

At S1603, a plurality of channel structures may be formed extending through the plurality of first deck structures.

At S1604, at least one semiconductor layer may be formed, where one semiconductor layer is connected with the channel structure in at least one of the plurality of first deck structures.

It should be noted that the operations shown in FIG. 16 are not exclusive, and other operations may be performed before, after, or between any operations in the illustrated operations; the order of the operations shown in FIG. 16 may be adjusted according to actual needs.

In some examples, forming the plurality of first deck structures stacked together includes: providing a semiconductor structure, where the semiconductor structure includes a plurality of semiconductor units each including at least a deck layer, and the deck layer includes isolation material layers and dielectric layers arranged alternately along the first direction; dividing the semiconductor structure along at least one of the second direction or the third direction to form a plurality of semiconductor units separated from each other, where the second direction and the third direction intersect with each other and are both perpendicular to the first direction; stacking the plurality of semiconductor units along the first direction to form the plurality of semiconductor units stacked together; and replacing the isolation material layers in the plurality of semiconductor units stacked together with the first conductive layers to form a plurality of first deck structures stacked together.

According to the example of the present disclosure, the folding memory device in the example of the present disclosure is formed by dividing the semiconductor unit structure along at least one of the X-axis or the Y-axis and stacking the divided semiconductor unit structure along the Z-axis direction.

In some implementations, the semiconductor structure is divided by laser cutting to obtain a plurality of semiconductor units.

In some examples, stacking the plurality of semiconductor units along the first direction includes: stacking the plurality of semiconductor units along the first direction by using a bonding process.

In some examples, a material of the isolation material layer includes, but is not limited to, silicon nitride; a material of the first conductive layer includes, but is not limited to, tungsten and polysilicon; and a material of the dielectric layer includes, but is not limited to, silicon oxide. In some examples, the isolation material layer in the plurality of semiconductor units stacked together may be replaced with the first conductive layer by using a wet etching process and a deposition process.

In some examples, the semiconductor unit further includes a semiconductor layer located on a first side and a second conductive layer located on a second side; the first side and the second side are located on two opposite sides of the deck layer respectively along the first direction; the second conductive layer includes a plurality of bit lines spaced apart along the second direction and extending along the third direction; and stacking the plurality of semiconductor units along the first direction includes: stacking every two semiconductor units of the plurality of semiconductor units to form a plurality of semiconductor unit groups, where the two semiconductor units in each semiconductor unit group are stacked in a direction toward respective first sides; and stacking the plurality of semiconductor unit groups along the first direction.

In the example of the present disclosure, two sides of the semiconductor unit along the Z-axis direction include a semiconductor layer and a second conductive layer, and after performing the cutting, a subsequent stacking process may be directly performed, and two adjacent semiconductor units are stacked in a direction toward the semiconductor layer.

In some examples, the number of the formed separated semiconductor units is a first number N; the semiconductor structure is divided along the second direction, the number of the bit lines included in the formed semiconductor unit is a fourth number (folding along the X-axis direction, and the number of the bit lines is 1/N of the original number); the semiconductor structure is divided along the third direction, the number of the bit lines included in the formed semiconductor unit is a fifth number (folding along the Y-axis direction, the number of the bit lines is unchanged); and the fifth number is a product of the first number and the fourth number.

In some examples, the method of manufacturing further includes: before stacking every two semiconductor units of the plurality of semiconductor units, removing the semiconductor layer corresponding to one of the two semiconductor units, where a remaining semiconductor layer forms the semiconductor layer connected with both of the two semiconductor units.

In the examples of the present disclosure, before stacking the two adjacent semiconductor units in the direction toward the semiconductor layer, one semiconductor layer is removed, and a common semiconductor layer is formed between two adjacent semiconductor units.

In other examples, two adjacent semiconductor units are directly stacked in a direction toward the semiconductor layer, so as to obtain a structure where there are two semiconductor layers between the two semiconductor units stacked together.

In some examples, the semiconductor unit further includes a semiconductor layer located on a first side and a second conductive layer located on a second side; the first side and the second side are located on two opposite sides of the deck layer respectively along the first direction; the second conductive layer includes a plurality of bit lines spaced apart along the second direction and extending along the third direction; and stacking the plurality of semiconductor units along the first direction includes: stacking two semiconductor units adjacent to each other along the first direction in the plurality of semiconductor units in a direction toward different sides of corresponding semiconductor units.

In the example of the present disclosure, two sides of the semiconductor unit along the Z-axis direction include a semiconductor layer and a second conductive layer, and after performing the cutting, a subsequent stacking process may be performed directly, one of the two adjacent semiconductor units is stacked in a direction toward the semiconductor layer, and the other one is stacked in a direction toward the second conductive layer.

In some examples, the method of manufacturing further includes: forming a semiconductor layer and a second conductive layer on two opposite sides of each semiconductor unit respectively along the first direction, where the second conductive layer includes a plurality of bit lines spaced apart along a second direction and extending along a third direction, and stacking the plurality of semiconductor units along the first direction includes: stacking the plurality of semiconductor units formed with the semiconductor layer and the second conductive layer along the first direction.

In the example of the present disclosure, two sides of the semiconductor unit along the Z-axis direction may not include the semiconductor layer and the second conductive layer. In view of this, the semiconductor layer and the second conductive layer may be first formed on both sides of the cut structure along the Z-axis direction after the cutting is performed, and then the stacking process is performed.

In some examples, the method of manufacturing further includes: when the isolation material layers in the plurality of semiconductor units stacked together are replaced with the first conductive layers, replacing each isolation material layer in a portion of the plurality of semiconductor units with the first conductive layer, where a portion of a deck structure where the isolation material layers are replaced forms a first deck structure; a portion of a deck structure where the isolation material layers are not replaced forms a second deck structure; a dielectric layer corresponding to the first deck structure is a first dielectric layer; a dielectric layer corresponding to the second deck structure is a second dielectric layer; and forming the first conductive structure includes: forming the first conductive structure in the second deck structure.

In the example of the present disclosure, the overall architecture of the first deck structure and the second deck structure are formed together, and then a portion of a deck structure where the isolation material layers are replaced forms a first deck structure; a portion of a deck structure where the isolation material layers are not replaced forms a second deck structure. It can be seen that the first dielectric layer and the second dielectric layer are in the same layer, and the materials of the first dielectric layer and the second dielectric layer are the same; the remaining isolation material layer forms an isolation layer, and the isolation layer and the first conductive layer are in the same layer, but the materials of them are different.

In some examples, the memory device includes a first deck structure, a second deck structure, and a third deck structure, the second deck structure and the third deck structure are arranged along the Y-axis direction and are both located in the connection region SS, the third deck structure includes a third conductive layer and a third dielectric layer that are stacked alternately, and the second deck structure includes an isolation layer and a second dielectric layer that are stacked alternately, where the first conductive layer, the second conductive layer, and the isolation layer are in the same layer, and the first dielectric layer, the second dielectric layer, and the third dielectric layer are in the same layer.

In some examples, the forming process of the first deck structure, the second deck structure and the third deck structure may include the following operations.

First, forming an initial deck structure of an isolation material layer and a dielectric layer in an array region GB and a connection region SS; replacing all the isolation layers of the array region with first conductive layers to form a first deck structure; replacing a portion of isolation layers in the connection region on the two sides of the gate slit structure with a third conductive layer to form a third deck structure; and in the connection region, the isolation layer and the dielectric layer which are not replaced are remained to form a second deck structure.

In some examples, the method of manufacturing further includes: forming a plurality of second conductive structures extending along the first direction in the first deck structure and connected with one bit line of at least one second conductive layer.

In some examples, the second conductive structure may be formed by using a dry etching process and a deposition process.

In some examples, the first conductive layers in the first deck structure include a top select gate layer and a gate layer; the method of manufacturing further includes: forming a third conductive structure extending along the first direction in the first deck structure and connected with one top select gate layer of at least one of the plurality of first deck structures, where the first conductive structure is connected with one gate layer of each of at least two first deck structures of the plurality of first deck structures.

In some examples, forming the third conductive structure includes: for each first deck structure, forming a contact portion of the third conductive structure extending along a stacking direction of the plurality of first deck structures and connected with the top select gate layer respectively; forming a second connection portion of the third conductive structure extending along a direction perpendicular to the stacking direction and connected with the contact structure; forming a third contact hole extending through the plurality of first deck structures, and forming a second insulation layer on a sidewall of the third contact hole; filling a conductive material in a third contact hole formed with a second insulation layer to form a second lead-out portion of the third conductive structure; and connecting the second lead-out portion with one second connection portion corresponding to one or more first deck structures.

In addition to the foregoing method of cutting and stacking, in the example of the present disclosure, a folding memory device may be directly formed by layer-by-layer growth. In some examples, forming the plurality of first deck structures stacked together includes: forming a plurality of first deck structures stacked together in sequence, where the first deck structure includes first conductive layers and dielectric layers that are arranged alternately; and the method of manufacturing further includes: forming the semiconductor layer and a second conductive layer alternately between two sides of the plurality of first deck structures along the first direction and between every two adjacent ones of the first deck structures.

In the example of the present disclosure, a plurality of deck structures may also be formed by stacking along the Z-axis direction; a plurality of deck structures are divided along the Z-axis direction, and the deck structure is divided into a plurality of separate deck structures; a bit-line layer BL and a source layer ACS are formed on the upper side and the lower side of each deck structure respectively to form a plurality of semiconductor units separated from each other; and all the semiconductor units are formed as a memory device.

For the four architectures of the memory device described above, the manufacturing methods of these architectures are illustrated as following.

An example of the present disclosure provides a manufacturing method of a memory device, and for the foregoing array Y-axis direction folding architecture, as shown in FIG. 3A, the manufacturing method of the memory device includes:

a1: providing a semiconductor structure including a deck structure, where the deck structure includes a plurality of semiconductor units arranged along a Y-axis direction, the Y-axis direction is parallel to an extending direction of a bit line BL, the semiconductor unit includes a deck structure and a bit-line layer BL and a source layer ACS located on upper and lower sides of the deck structure respectively.

a2: dividing the deck structure along the Y direction, so that all the semiconductor units are separated from each other.

a3: stacking all the semiconductor units along the Z-axis direction to form a memory device.

In some implementations, there are a variety of methods of stacking all the semiconductor units, including but not limited to, stacking all the semiconductor units face-to-face, stacking all the semiconductor units face-to-back, or a combination thereof. Here, after dividing the memory block, each semiconductor cell includes a top surface and a bottom surface, the face-to-face stacking may include contacting and stacking of a top surface of a semiconductor unit and a top surface of another semiconductor unit, or contacting and stacking of a bottom surface of a semiconductor unit and a bottom surface of another semiconductor unit, and a face-to-back stacking may include contacting and stacking of a top surface of a semiconductor unit and a bottom surface of another semiconductor unit.

In some implementations, the method of stacking between the semiconductor units includes, but is not limited to, hybrid bonding.

In some implementations, the formed memory device includes N first deck structures, each first deck structure includes 1 gate layer WL, the number of bit lines BL corresponding to the deck structure is Q, the number of bit lines BL corresponding to each semiconductor unit is Q, and the number of bit lines BL of the memory device formed after stacking the semiconductor units is also Q.

An example of the present disclosure provides a manufacturing method of a memory device, and for the foregoing array Y-axis direction folding architecture, as shown in FIG. 3B, the manufacturing method of the memory device includes:
b1: providing a semiconductor structure including a deck structure, where the deck structure includes a plurality of semiconductor units arranged along an X-axis direction, the X direction is perpendicular to an extending direction of the bit line BL;
b2: dividing the deck structure along the X direction, so that the plurality of semiconductor units are separated from each other;
b3: stacking all the semiconductor units along the Z-axis direction to form a memory device.

In some implementations, there are a variety of methods of stacking all the semiconductor units, including but not limited to, stacking all the semiconductor units face-to-face, stacking all the semiconductor units face-to-back, or a combination thereof.

In some implementations, the method of stacking between the semiconductor units includes, but is not limited to, hybrid bonding.

In some implementations, the formed memory device includes N first deck structures, each first deck structure includes 1 gate layer WL, the number of bit lines BL corresponding to the deck structure is Q, the number of bit lines BL corresponding to each semiconductor unit is Q/N, and the number of bit lines BL of the memory device formed after stacking the semiconductor units is also Q/N.

An example of the present disclosure provides a method of manufacturing a memory device, and for the foregoing array Y-axis direction folding architecture, as shown in FIG. 3C, the manufacturing method of the memory device includes:
c1: providing a semiconductor structure including a deck structure, where the deck structure includes a plurality of semiconductor units arranged along an X-axis direction and a Y-axis direction, the X-axis direction is perpendicular to an extending direction of the bit line BL, and the Y-axis direction is parallel to an extending direction of the bit line BL;
c2: dividing the initial memory device along the X direction, so that the plurality of unit structures are separated from each other;
c3: dividing the unit structure along the Y direction, so that all the semiconductor units are separated from each other;
c4: stacking all the semiconductor units along the Z-axis direction to form a memory device.

In some implementations, there are a variety of methods of stacking all the semiconductor units, including but not limited to, stacking all the semiconductor units face-to-face, stacking all the semiconductor units face-to-back, or a combination thereof.

In some implementations, the method of stacking between the semiconductor units includes, but is not limited to, hybrid bonding.

In other examples, the process implementation of the semiconductor structure may also include other methods, such as dividing along the Y-axis direction, then dividing along the X-axis direction to form a memory device, or other methods that can stack different semiconductor units.

In other examples, the arrangement method of stacking all the semiconductor units may also have various methods, which may be arranged according to a Model, and the same Fingers corresponding to all the unit structures may be stacked together to form a semiconductor unit including a plurality of deck structures, and then the plurality of semiconductor units are stacked together to form a memory device. All of the semiconductor units may also be stacked together in sequence, so that the same Models corresponding to all the unit structures are stacked together, or other methods may be implemented. For example, the deck structure arranged in sequence from top to bottom may be the semiconductor unit 1 to the semiconductor unit N in the first row corresponding to the Model1, and the semiconductor unit 1 to the semiconductor unit N in the second row corresponding to the Model 2. For example, the deck structure arranged in sequence from left to right may be the semiconductor unit 1 to the semiconductor unit N in the first column corresponding to the Model1, and the semiconductor unit 1 to the semiconductor unit N in the second column corresponding to the Model 2.

In an example, the formed memory device includes M memory modules, each memory module includes N deck structures, each deck structure includes 1 gate layer WL, the number of bit lines BL corresponding to the deck structure is Q, the number of bit lines BL corresponding to each semiconductor unit is Q/N, and the number of bit lines BL of the memory device formed after the semiconductor units are stacked is also Q/N.

An example of the present disclosure further provides a memory system, including: the memory device in the foregoing examples of the present disclosure.

In some examples, the memory device includes a three-dimensional NAND memory.

The memory array in the example of the present disclosure may include a plurality of memory cells, the memory cell may be configured to store at least one bit of data, and for example, the memory cell in this example of the present disclosure may be an SLC configured to store one bit of data, or an MLC configured to store two bits of data, or a TLC configured to store three bits of data, or a QLC configured to store four bits of data, or may even be configured to store more bits of data.

In some examples, the memory system further includes a memory controller connected with the memory device and configured to control the memory device.

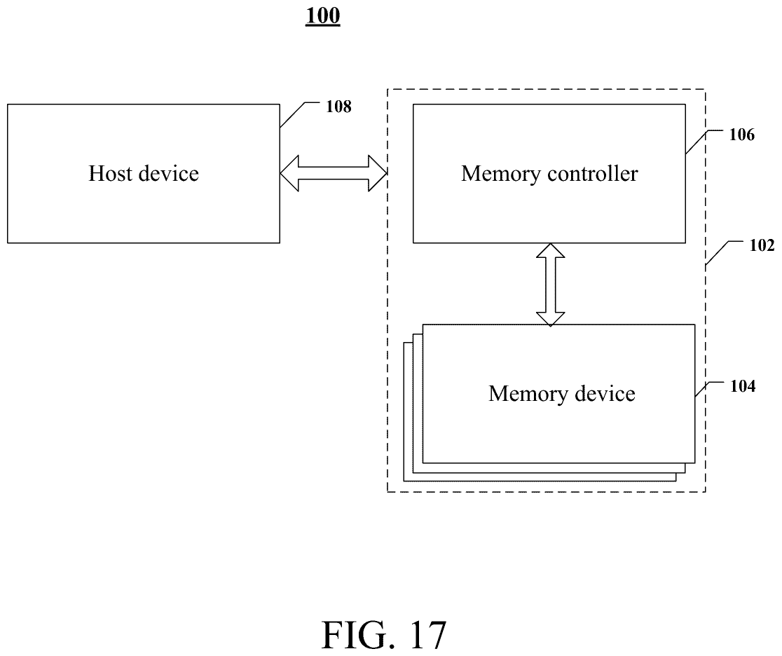

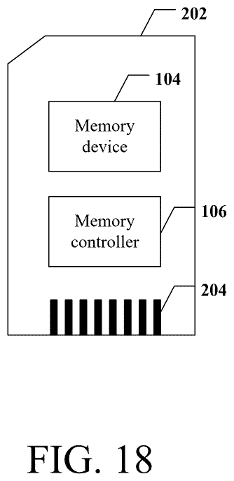

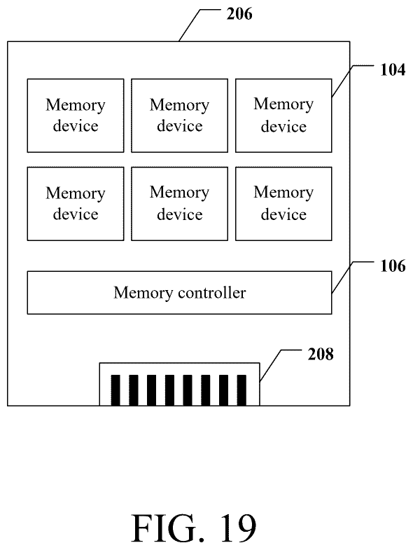

In some examples, the system in the foregoing example may be the memory system 102 shown in FIG. 17, the memory system 102 includes a memory controller 106 and a memory device 104 coupled with the memory controller 106, and the controller in the foregoing examples may be the memory controller 106 shown in FIG. 17, FIG. 18, and FIG. 19. In some other examples, the system in the foregoing example may be the system 100 shown in FIG. 17, the system 100 includes a host device 108 and a memory system 102 coupled with the host device 108, and the controller in the foregoing examples may be a control part separated from the memory controller 106, for example, may be a CPU in the host device. The input data here includes a vector or matrix.

According to some examples, as shown in FIG. 17, the memory controller 106 is coupled to the memory device 104 and the host device 108 and is configured to control operations of the memory device 104, such as read, erase, program, compute operations. The memory controller 106 may manage data stored in the memory device 104 and communicate with the host device 108. In some implementations, the memory controller 106 is designed to operate in a low duty cycle environment, such as a secure digital card, compact flash memory card, universal serial bus flash drive, or other medium for use in electronic devices such as personal computers, digital cameras, mobile phones, and the like. In some implementations, the memory controller 106 is designed to operate in a high duty cycle environment SSD or embedded multimedia card that serves as a data store for mobile devices such as smartphones, tablet computers, laptop computers, and the like, as well as enterprise memory arrays.

The memory controller 106 and one or more memory devices 104 may be integrated into various types of memory devices, for example, included in the same package (e.g., a Universal Flash Memory (UFS) package or an embedded multimedia card package). That is, the memory system 102 may be implemented and packaged into different types of end electronic products. In one example as shown in FIG. 18, the memory controller 106 and a single memory device 104 may be integrated into the memory card 202. The memory card 202 may include compact flash memory cards, smart media cards, memory sticks, multimedia cards, secure digital cards, UFS, and the like. The memory card 202 may also include a memory card connector 204 that couples the memory card 202 with a host device (e.g., the host device 108 in FIG. 17). In another example as shown in FIG. 19, the memory controller 106 and the plurality of memory devices 104 may be integrated into SSD206. SSD206 may also include an SSD connector 208 that couples SSD206 with a host device (e.g., host device 108 in FIG. 17). In some implementations, the memory capacity and/or operating speed of SSD206 is greater than that of memory card 202.

An example of the present disclosure further provides a manufacturing method of a memory system, including:

Forming a memory device. In some examples, the memory device may include a three-dimensional NAND memory; and in some examples, the memory device may be a memory device in the foregoing example of the present disclosure;

Forming a memory controller connected with the memory device and configured to control the memory device.

It should be noted that the technical solutions described in the example of the present disclosure may be arbitrarily combined without conflict.

The above descriptions provide some implementations of the present disclosure, but the protection scope of the present disclosure is not limited thereto, and changes or replacements that may be easily conceived by any person skilled in the art within the technical scope of the present disclosure should be encompassed within the protection scope of the present disclosure. Therefore, the protection scope of the present disclosure should be subject to the protection scope of the claim.

What is claimed is:

1. A memory device, comprising:
a plurality of first deck structures stacked together, wherein the first deck structures each comprise first conductive layers and first dielectric layers arranged alternately along a first direction;
a first conductive structure extending along the first direction and connected with one first conductive layer of each of at least two first deck structures of the plurality of first deck structures;
a plurality of channel structures extending through the plurality of first deck structures; and
at least one semiconductor layer, wherein one semiconductor layer of the at least one semiconductor layer is connected with the channel structure in at least one of the plurality of first deck structures.

2. The memory device of claim 1, wherein a cross-sectional shape of the plurality of first deck structures along the first direction comprises a step-like shape; each step in the step-like shape corresponds to the first conductive layer and the first dielectric layer adjacent to each other; and
the first conductive structure extends along the first direction in the first deck structure and is connected with at least two steps where one first conductive layer of the at least two first deck structures is located.

3. The memory device of claim 1, further comprising a second deck structure comprising isolation layers and second dielectric layers arranged alternately along the first direction, wherein
the first conductive structure comprises a first lead-out portion and a plurality of first connection portions; the first lead-out portion extends along the first direction in the second deck structure and is connected with each of the plurality of first connection portions; and each of the plurality of first connection portions is located in the isolation layer and is connected to one first conductive layer of a corresponding one of the at least two first deck structures.

4. The memory device of claim 1, wherein the first conductive structure is connected with one first conductive layer of each of the plurality of first deck structures.

5. The memory device of claim 4, wherein each of the first conductive layers connected with a same first conductive structure in different ones of the first deck structures has a same distance from the semiconductor layer connected with the channel structure in a corresponding one of the first deck structures.

6. The memory device of claim 4, wherein the first conductive layers connected with a same first conductive structure in two different ones of the first deck structures have different distances from the semiconductor layer connected with the channel structure in a corresponding one of the first deck structures.

7. The memory device of claim 1, further comprising a peripheral circuit comprising a string driver, wherein
the first conductive layers of the at least two first deck structures are connected with each other through the first conductive structure and are connected with a same string driver.

8. The memory device of claim 7, wherein along the first direction, a region where the string driver is arranged is aligned with a region where the first conductive structure is arranged.

9. The memory device of claim 7, wherein the memory device has a first number of first deck structures, the first deck structure has a second number of first conductive layers, the memory device has a third number of string drivers, and the third number is less than or equal to a product of the first number and the second number.

10. The memory device of claim 1, further comprising a third conductive structure, wherein the first conductive layers in the first deck structure comprise a top select gate layer and a gate layer; the top select gate layer is located at one end of two ends of a corresponding first deck structure along the first direction away from the semiconductor layer connected with the channel structure in the corresponding first deck structure;
the third conductive structure extends along the first direction in the first deck structure and is connected with the top select gate layer comprised in at least one of the plurality of first deck structures; and
the first conductive structure is connected with one gate layer of each of at least two first deck structures of the plurality of first deck structures.

11. The memory device of claim 10, wherein the plurality of first deck structures are arranged in a first region, the first conductive structures are all arranged in a second region, the third conductive structures are all arranged in a fourth region, and
the fourth region is located between the first region and the second region.

12. The memory device of claim 10, wherein the third conductive structure comprises a second lead-out portion, a second connection portion and a contact portion; the second lead-out portion extends along the first direction and is connected with the second connection portion; the second connection portion extends along a second direction and is connected with the contact portion; the contact portion extends along the first direction and is connected with the top select gate layer; and the second direction is perpendicular to the first direction.

13. A memory system, comprising:
a memory device, comprising:
a plurality of first deck structures stacked together, wherein the first deck structures each comprise first conductive layers and first dielectric layers arranged alternately along a first direction;
a first conductive structure extending along the first direction and connected with one first conductive layer of each of at least two first deck structures of the plurality of first deck structures;
a plurality of channel structures extending through the plurality of first deck structures; and
at least one semiconductor layer, wherein one semiconductor layer of the at least one semiconductor layer is connected with the channel structure in at least one of the plurality of first deck structures.

14. A method of manufacturing a memory device, comprising:
forming a plurality of first deck structures stacked together, wherein the first deck structures each comprise first conductive layers and first dielectric layers arranged alternately along a first direction;
forming a first conductive structure, wherein the first conductive structure extends along the first direction and is connected with one first conductive layer of each of at least two first deck structures of the plurality of first deck structures;
forming a plurality of channel structures extending through the plurality of first deck structures; and
forming at least one semiconductor layer, wherein one semiconductor layer of the at least one semiconductor layer is connected with the channel structure in at least one of the plurality of first deck structures.

15. The method of claim 14, wherein forming the plurality of first deck structures stacked together comprises:
providing a semiconductor structure, wherein the semiconductor structure comprises a plurality of semiconductor units each comprising at least a deck layer, and the deck layer comprises isolation material layers and dielectric layers arranged alternately along the first direction;
dividing the semiconductor structure along at least one of a second direction or a third direction to form a plurality of semiconductor units separated from each other, wherein the second direction and the third direction intersect with each other and are both perpendicular to the first direction;
stacking the plurality of semiconductor units along the first direction to form the plurality of semiconductor units stacked together; and
replacing the isolation material layers in the plurality of semiconductor units stacked together with the first conductive layers to form the plurality of first deck structures stacked together.

16. The method of claim 15, wherein the semiconductor unit further comprises a semiconductor layer located on a first side and a second conductive layer located on a second side; the first side and the second side are located on two opposite sides of the deck layer respectively along the first direction; the second conductive layer comprises a plurality of bit lines spaced apart along the second direction and extending along the third direction; and
stacking the plurality of semiconductor units along the first direction comprises:
stacking every two semiconductor units of the plurality of semiconductor units to form a plurality of semiconductor unit groups, wherein the two semiconductor units in each semiconductor unit group are stacked in a direction toward respective first sides; and
stacking the plurality of semiconductor unit groups along the first direction.

17. The method of claim 16, further comprising:
before stacking every two semiconductor units of the plurality of semiconductor units, removing the semiconductor layer corresponding to one of the two semiconductor units, wherein a remaining semiconductor layer forms the semiconductor layer connected with both of the two semiconductor units.

18. The method of claim 15, further comprising:
forming a semiconductor layer and a second conductive layer on two opposite sides of each semiconductor unit respectively along the first direction, wherein the second conductive layer comprises a plurality of bit lines spaced apart along the second direction and extending along the third direction, and wherein
stacking the plurality of semiconductor units along the first direction comprises:
stacking the plurality of semiconductor units formed with the semiconductor layer and the second conductive layer along the first direction.

19. The method of claim 15, wherein the semiconductor unit further comprises a semiconductor layer located on a first side and a second conductive layer located on a second side; the first side and the second side are located on two opposite sides of the deck layer respectively along the first direction; the second conductive layer comprises a plurality of bit lines spaced apart along the second direction and extending along the third direction; and
stacking the plurality of semiconductor units along the first direction comprises:
stacking two semiconductor units adjacent to each other along the first direction in the plurality of semiconductor units in a direction toward different sides of respective semiconductor units.

20. The method of claim 16, wherein stacking the plurality of semiconductor units along the first direction comprises:
stacking the plurality of semiconductor units along the first direction by using a bonding process.
